(19) United States
(12) Patent Application Publication
(10) Pub. No.: US 2022/0294237 A1
(43) Pub. Date: Sep. 15, 2022

(54) POWER STORAGE APPARATUS, CONTROL APPARATUS, AND POWER STORAGE SYSTEM

(71) Applicants: Masami TAKAI, Tokyo (JP); Kazuhito KISHI, Kanagawa (JP); Atsushi OHSHIMA, Osaka (JP); Takahiro IMAI, Tokyo (JP)

(72) Inventors: Masami TAKAI, Tokyo (JP); Kazuhito KISHI, Kanagawa (JP); Atsushi OHSHIMA, Osaka (JP); Takahiro IMAI, Tokyo (JP)

(73) Assignee: Ricoh Company, Ltd., Ohta-ku, Tokyo (JP)

(21) Appl. No.: 17/634,122

(22) PCT Filed: Aug. 12, 2020
(86) PCT No.: PCT/JP2020/030735

§ 371 Date: Feb. 9, 2022

(30) Foreign Application Priority Data
Aug. 13, 2019 (JP) 2019-148392
Sep. 10, 2019 (JP) 2019-164759
Jan. 28, 2020 (JP) 2020-011864

(51) Int. Cl. H02J 7/00; H02J 7/34

(52) U.S. Cl. CPC H02J 7/0024; H02J 7/00714; H02J 7/007182; H02J 7/342; H02J 7/345; H02J 2207/50

(57) ABSTRACT

A power storage apparatus includes a power storage unit including a plurality of power storage devices (C1, C2) storing electric power, a series-and-parallel switching unit configured to switch connection of the plurality of power storage devices into a series connection or a parallel connection, and a series-and-parallel switching control unit configured to control the series-and-parallel switching unit, wherein the series-and-parallel switching control unit controls timing of the switching with hysteresis.

### TECHNICAL FIELD

The present invention relates to a power storage apparatus, a control apparatus, and a power storage system.

### BACKGROUND ART

With the advancement of IoT (Internet of Things) technology, efforts have been made to make batteryless edge devices with energy harvesting technology. For example, the energy harvesting technology has been applied to LEDs (Light Emitting Diodes) and the like energized by electric generated with piezoelectric elements, power generation rubber, triboelectric charging, electrostatic induction by electrets, or the like.

However, the voltage of the electric power generated by piezoelectric elements, triboelectric charging, or electrostatic induction is high, and accordingly, the current of such electric power is low. Therefore, such electric power is suitable for momentarily lighting LEDs connected in series, but cannot satisfy the requirement for the voltage and current for energizing a CPU (Central Processing Unit), sensors, or wireless transmitters used with IoT edge devices. Accordingly, it is desired to develop technology for efficiently utilizing even a high-voltage and low-current electric power.

In general, when the generated electric power is very small, the generated electric power is stored in a capacitor, and the stored electric power is converted by a DC-to-DC (Direct Current to Direct Current) converter into a voltage for driving an edge device. However, power generation devices based on piezoelectric elements and electrostatic induction have high output impedances, and therefore, when the electric power generated by such power generation devices is directly stored in a capacitor of a low impedance, the electric power is stored in a low voltage state during power storing operation, which may reduce the power storage efficiency.

PTL 1 and the like discloses a power supply circuit generating operation electric power of an electric circuit by using very small electric power generated by a power generation device outputting a low current with a high output impedance.

### SUMMARY OF INVENTION

### Technical Problem

However, with respect to a power supply circuit of PTL 1, scope of improvement is associated with a power storage efficiency or power supply efficiency of electric power.

It is an object of the present disclosure to improve the power storage efficiency and the power supply efficiency of the electric power.

### Solution to Problem

According to an aspect of the present disclosure, a power storage apparatus comprising:

a power storage unit including a plurality of power storage devices storing electric power;

a series-and-parallel switching unit configured to switch connection of the plurality of power storage devices into a series connection or a parallel connection; and

a series-and-parallel switching control unit configured to control the switching performed by the series-and-parallel switching unit,

wherein the series-and-parallel switching control unit controls timing of the switching with hysteresis.

### Advantageous Effects of Invention

According to the present disclosure, the power storage efficiency and the power supply efficiency of the electric power can be improved.

### BRIEF DESCRIPTION OF DRAWINGS

FIG. 1 is a block diagram illustrating an example of configuration of a power storage system according to a first embodiment.

FIG. 2 is a block diagram illustrating a configuration of a power storage system according to a comparative example.

FIG. 3 is a drawing illustrating an example of operation of a power generation device provided in the power storage system.

FIG. 4A is a circuit diagram illustrating an equivalent circuit including a capacitor connected to the power generation device when the capacitor stores electric power generated by the power generation device.

FIG. 4B is a graph illustrating an example of power storage efficiency according to a condition for storing electric power to the capacitor.

FIG. 5A a circuit diagram illustrating an equivalent circuit of a load resistance connected to the power generation device when the power generation device supplies electric power to the load resistance.

FIG. 5B is a graph illustrating an example of power storage efficiency according to a condition for storing electric power to the load resistance.

FIG. 6 is a circuit diagram illustrating an example of two capacitors connected in series.

FIG. 7 is a circuit diagram illustrating an example of two capacitors connected in parallel.

FIG. 8 is a circuit diagram illustrating a first configuration example of a series-and-parallel switching control unit.

FIG. 9 is a circuit diagram illustrating a second configuration example of a series-and-parallel switching control unit.

FIG. 10 is a circuit diagram illustrating an example of circuit configuration of the power storage apparatus according to the first embodiment.

FIG. 11A is a circuit diagram illustrating an example of flow of a current in the power storage apparatus according to the first embodiment, when the power storage apparatus stores electric power.

FIG. 11B is a circuit diagram illustrating an example of flow of a current in the power storage apparatus according to the first embodiment, when the power storage apparatus supplies electric power.

FIG. 12 is a circuit diagram illustrating an example of circuit configuration of the power storage system according to the first embodiment.

FIG. 13 is a circuit diagram illustrating an example of configuration of a power storage system made into an IC including a control circuit with a communication module.

FIG. 14 is a timing chart illustrating an example of operation of the power storage apparatus according to the first embodiment.

FIG. 15A is a circuit diagram illustrating a transition of a current with respect to a capacitor with a fixed capacitance according to a comparative example, when the capacitor stores electric power or supplies electric power.

FIG. 15B is a graph illustrating a transition of a charge current and a voltage of the capacitor with the fixed capacitance according to the comparative example, when the capacitor stores electric power and supplies electric power.

FIG. 16A is a circuit diagram illustrating a transition of a current with respect to the capacitors according to the first embodiment, when the capacitors are switched from series connection for storing electric power to parallel connection for supplying electric power.

FIG. 16B is a graph illustrating a transition of a charge current and a voltage of the capacitors according to the first embodiment, when the capacitor stores electric power and supplies electric power.

FIG. 17 is a circuit diagram illustrating a configuration example of a circuit in which four capacitors are connected in series.

FIG. 18 is a circuit diagram illustrating a configuration example of a circuit in which capacitors are connected in multiple stages.

FIG. 19 is a block diagram illustrating an example of configuration of a power storage system according to a second embodiment.

FIG. 20 is a circuit diagram illustrating an example of circuit configuration of a power storage apparatus according to the second embodiment.

FIG. 21A is a circuit diagram illustrating a flow of a current in the power storage apparatus according to the second embodiment, when the power storage apparatus stores electric power.

FIG. 21B is a circuit diagram illustrating a flow of a current in the power storage apparatus according to the second embodiment, when the power storage apparatus supplies electric power.

FIG. 22 is a timing chart illustrating an example of operation of the power storage apparatus according to the second embodiment.

FIG. 23 is a circuit diagram illustrating an example of circuit configuration of a power storage apparatus according to a first modified embodiment of the second embodiment.

FIG. 24 is a block diagram illustrating an example of configuration of a power storage system according to a second modified embodiment of the second embodiment.

FIG. 25 is a timing chart illustrating an example of operation of the power storage apparatus according to the second modified embodiment.

FIG. 26 is a block diagram illustrating an example of configuration of a power storage system according to a third modified embodiment of the second embodiment.

FIG. 27A is a block diagram illustrating an example of configuration of a power storage system.

FIG. 27B is a block diagram illustrating a configuration example of a power storage system having a load driving power storage apparatus.

FIG. 28 is a block diagram illustrating an example of configuration of a power storage system according to a third embodiment.

FIG. 29 is a circuit diagram illustrating an example of circuit configuration of a power storage apparatus according to the third embodiment.

FIG. 30 is a timing chart illustrating an example of operation of the power storage apparatus of FIG. 29.

FIG. 31 is a block diagram illustrating an example of configuration of a power storage system according to a first modified embodiment of the third embodiment.

FIG. 32 is a circuit diagram illustrating an example of circuit configuration of a power storage apparatus according to a second modified embodiment of the third embodiment.

FIG. 33 is a circuit diagram illustrating an example of circuit configuration of a power storage apparatus according to a third modified embodiment of the third embodiment.

FIG. 34 is a timing chart illustrating an example of operation of the power storage apparatus of FIG. 33.

FIG. 35 is a circuit diagram illustrating an example of circuit configuration of a power storage apparatus provided with a stabilized circuit.

FIG. 36 is a circuit diagram illustrating an example of circuit configuration of a power storage apparatus with more capacitors.

FIG. 37 is a block diagram illustrating an example of configuration of a power storage system according to a fifth modified embodiment of the third embodiment.

FIG. 38 is a block diagram illustrating an example of configuration of a power storage system according to a sixth modified embodiment of the third embodiment.

FIG. 39 is a block diagram illustrating an example of configuration of a power storage system according to a fourth embodiment.

FIG. 40 is a circuit diagram illustrating an example of circuit configuration of a power storage apparatus according to the fourth embodiment.

FIG. 41 is a graph illustrating an example of change of a capacitance, a voltage, and a current according to a charge time of a secondary battery.

FIG. 42 is a graph illustrating an example of a voltage and a current occurring in response to a single external stimulus to a power generation device.

FIG. 43 is a graph illustrating an example of a voltage output characteristic of a secondary battery.

FIG. 44 is a block diagram illustrating an example of configuration of a power storage system according to a first modified embodiment of the fourth embodiment.

FIG. 45 is a circuit diagram illustrating an example of circuit configuration of a power storage apparatus according to the first modified embodiment.

FIG. 46 is a block diagram illustrating an example of configuration of a power storage system according to a second modified embodiment of the fourth embodiment.

FIG. 47 is a circuit diagram illustrating an example of circuit configuration of a power storage apparatus and a load circuit according to the second modified embodiment.

FIG. 48 is a circuit diagram illustrating an example of circuit configuration capable of adjusting resistance values by trimming.

### DESCRIPTION OF EMBODIMENTS

Hereinafter, embodiments for carrying out the present invention are described with reference to the drawings. In the drawings, the same constituent elements may be denoted by the same reference numerals, and duplicate description thereabout may be omitted.

In the following embodiments, “electric power” is assumed to be synonymous with “electric energy”. Also, “use electric power”, “provide electric power”, “supply power”, and “discharge” are assumed to be synonymous with each other.

In the following embodiments, “switch series-and-parallel connection” means to switch any given electric circuit from series connection to parallel connection, or to switch the electric circuit from parallel connection to series connection.

<Configuration Example of Power Storage System 100 According to First Embodiment>

A power supply circuit described in PTL 1 assumes a power generation device which is an electret device outputting very small electric power and having a high output impedance of 15 MΩ and having a maximum output of 92.5 Vp-p and 3.1 μA.

However, if the power supply circuit described in PTL 1 is applied to power generation rubber having a maximum output of 400 V and 1μA, the power generation rubber outputs a higher voltage than the electret device, and accordingly, the electric power consumed by an internal resistance of the power generation rubber increases, which reduces the efficiency.

In view of the above circumstances, the power storage system 100 according to the first embodiment is configured to be able to improve the energy storage efficiency and the usage efficiency even with electric power provided by such power generation device for high voltage and low current power generation.

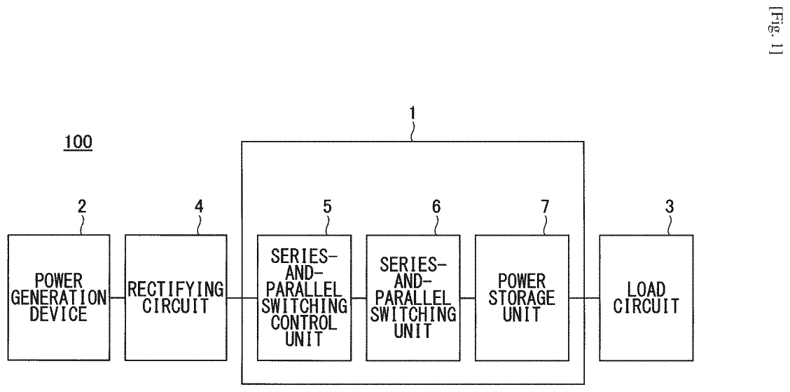

First, the power storage system 100 is explained with reference to FIG. 1. FIG. 1 is a block diagram illustrating an example of configuration of a power storage system (i.e., an energy storage system) 100 according to a first embodiment. As illustrated in FIG. 1, the power storage system 100 includes a power storage apparatus 1, a power generation device 2, a load circuit 3, and a rectifying circuit 4.

Among them, the power storage apparatus 1 includes a series-and-parallel switching control unit 5, a series-and-parallel switching unit 6, and a power storage unit 7. The power storage unit 7 includes capacitors C1, C2, which are an example of a plurality of power storage devices. Under the control of the series-and-parallel switching control unit 5, the series-and-parallel switching unit 6 can switch the connection of the capacitors C1, C2 to any one of series connection and parallel connection.

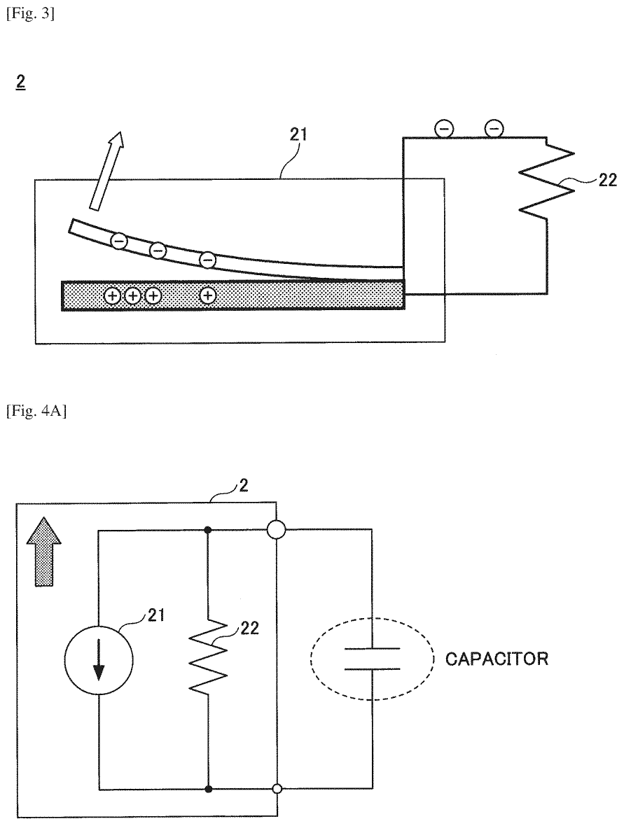

The power generation device 2 is a device that generates power with power generation rubber, a piezoelectric element, or electrostatic induction, and generates high-voltage and low-current electric power. Power generation by the power generation device 2 is explained later in detail with reference to FIG. 3.

The load circuit 3 is, for example, a load including an LED (Light Emitting Diode), an IC (Integrated Circuit) having a function of a CPU (Central Processing Unit), a sensor, a wireless transmission IC, and the like. The load circuit 3 is, for example, an IoT device.

In the power storage system 100, the rectifying circuit 4 rectifies the electric power generated by the power generation device 2, and the capacitors C1, C2 connected in series in the power storage unit 7 store the rectified electric power. The capacitors C1, C2 switched to parallel connection by the series-and-parallel switching unit 6 supply the stored electric power to the load circuit 3.

Specifically, the rectifying circuit (an example of a rectifying unit) 4 rectifies the electric power of the alternating current generated by the power generation device 2. Under the control of the series-and-parallel switching control unit 5, the series-and-parallel switching unit 6 causes the capacitors C1 and C2 in the power storage unit 7 to be connected in series, and the capacitors C1, C2 store the electric power (voltage of the stored electric power) received from the rectifying circuit 4.

Thereafter, when the voltage of the stored electric power attains a predetermined or given voltage value (i.e., the first voltage value), the series-and-parallel switching unit 6 operates under the control of the series-and-parallel switching control unit 5 to switch the capacitors C1, C2 to the parallel connection. The capacitors C1, C2 connected in parallel supply the electric power to the load circuit 3.

Thereafter, in a case where a voltage supplied from the capacitors C1, C2 attains a predetermined or given voltage (i.e., a second voltage value) or less, the series-and-parallel switching unit 6 operates under the control of the series-and-parallel switching control unit 5 to switch the capacitors C1, C2 to the series connection. With the capacitors C1, C2 being connected in series, the capacitors C1, C2 resume to store the electric power generated by the power generation device 2.

<Configuration Example of Power Storage System 100X According to Comparative Example>

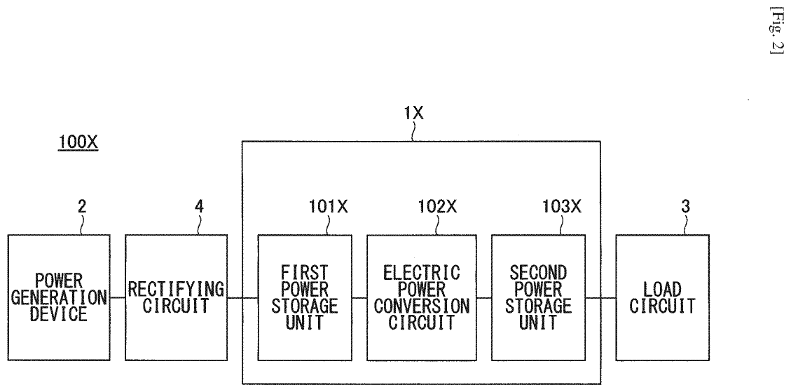

Hereinafter, as a comparative example, a system that stores electric power generated by an environment power generation device and supplies the generated power to a load circuit is explained. FIG. 2 is a block diagram illustrating a configuration of a power storage system 100X according to a comparative example. In FIG. 2, constituent elements having functions corresponding to the respective functions of the power storage system 100 as illustrated in FIG. 1 are denoted with the same reference numerals for the sake of convenience.

The power storage system 100X is a generally-available energy harvest system. In the power storage system 100X, the electric power generated by the environment power generation device is stored in a power storage apparatus 1X via a rectifying circuit 4, and the stored electric power is supplied to a load circuit 3.

As illustrated in FIG. 2, the power storage apparatus 1X includes a first power storage unit 101X which is a power generation side power storage unit, an electric power conversion circuit 102X, and a second power storage unit 103X which is a power supply side power storage unit.

The voltage stored in the first power storage unit 101X is converted into an operating voltage of the load circuit 3 by the electric power conversion circuit 102X such as DC-to-DC converter, and then stored in the second power storage unit 103X. Thereafter, the electric power stored in the second power storage unit 103X is supplied to the load circuit 3.

The power storage apparatus 1X explained above may have the following problems:

(A) Loss due to a current consumed by the electric power conversion circuit 102X;

(B) Loss due to conversion efficiency; and

(C) Increase of components such as an inductor.

Specifically, in the power storage system 100X, it is necessary to boost or step-down the voltage depending on the relationship between the voltage stored in the first power storage unit 101X and the voltage stored in the second power storage unit 103X. For example, when the voltage of the electric power stored in the second power storage unit 103X is higher than the voltage of the electric power stored in the first power storage unit 101X, the electric power is stored at a low voltage, and accordingly, the boost conversion is needed before supplying the electric power to the load circuit 3. In this case, it is necessary to increase the capacitance of the first power storage unit 101X of the power storage apparatus 1X because of the reason explained below based on the following expression (1).

$$\begin{matrix}Math 1 & \\ W = \frac{1}{2} C {V}^{2} & ( 1 )\end{matrix}$$

In the above Expression, W denotes the energy stored in the capacitor, C denotes the capacitance of the capacitor, and V denotes the voltage of the stored electric power.

The stored energy is proportional to a square of the voltage of the stored electric power. Therefore, when the voltage of the electric power stored in the capacitor of the first power storage unit 101X of the power storage apparatus 1X is low, the capacitor needs to have a relatively larger capacitance to store a desired amount of energy. In addition, because there is a difference between the voltage of the electric power stored in the first power storage unit 101X and the voltage of the electric power stored in the second power storage unit 103X, the electric power is wasted in the voltage conversion in the electric power conversion circuit 102X (i.e., the problems (A) and (B) described above), and the size of the electric power conversion circuit 102X increases (i.e., the problem (C) described above). As a result, the power storage efficiency of the power storage system 100X becomes low.

When the voltage of the electric power stored in the first power storage unit 101X is higher than the voltage of the electric power stored in the second power storage unit 103X, for example, when the first power storage unit 101X stores high-voltage and low-current electric power generated by a piezoelectric element, power generation rubber, or electrostatic induction in the power generation device 2, the step-down conversion is needed. In this case, according to the expression (1) explained above, the power can be stored in the first power storage unit 101X at a high voltage. Therefore, the first power storage unit 101X of the power storage apparatus 1X can store a desired amount of energy at a high voltage with a capacitor of a relatively smaller capacitance. However, because there is a difference between the voltage of the electric power stored in the first power storage unit 101X and the voltage of the electric power stored in the second power storage unit 103X, the electric power is wasted in the voltage conversion in the electric power conversion circuit 102X (i.e., the problems (A) and (B) described above), and the size of the electric power conversion circuit 102X increases (i.e., the problem (C) described above). As a result, the power storage efficiency of the power storage system 100X becomes low.

Therefore, in the power storage system 100X, the loss increases due to the current consumed by the electric power conversion circuit 102X (i.e., the problem (A) described above), and the loss increases due to conversion efficiency (i.e., the problem (B) described above). In addition, the size of the power storage apparatus 1X may increase because of the increase of components (i.e., the problem (C) described above).

In contrast, the power storage system 100 according to the first embodiment uses the same power storage unit 7 including multiple capacitors not only when storing electric power but also when supplying electric power, so that the loss of the electric power during voltage conversion can be alleviated.

<Example of Power Generation Device>

Subsequently, the operation of the power generation device 2 provided in the power storage system 100 is explained. FIG. 3 is a drawing illustrating an example of operation of the power generation device 2.

The power generation device 2 is constituted by power generation rubber and the like, and generates power by generating charge in response to separating force, frictional force, vibration force, or deformation force being applied to the power generation device 2. Alternatively, the power generation device 2 may generate power in response to pressure.

The power generation device 2 generates power having a voltage of 10 to 1000 V (for example, 40 V) and a current of 50 nA to 100 μA (for example, 6μA).

As illustrated in FIG. 3, the power generation device 2 constituted by power generation rubber or a piezoelectric element outputs a current with a predetermined or given charge. Therefore, the power generation device 2 can be approximated by a current source 21 and an internal resistance 22. The resistance value of the internal re-sistance 22 is 1 to 100 MΩ (mega ohm) (for example, 10 MΩ).

Hereinafter, a capacitor and a load resistance connected to the power generation device 2 are explained with reference to FIGS. 4A, 4B, and FIG. 5.

FIG. 4A is a circuit diagram illustrating an equivalent circuit including the capacitor connected to the power generation device 2 when the capacitor stores electric power generated by the power generation device 2. FIG. 4B is a graph illustrating an example of power storage efficiency according to a condition for storing electric power to the capacitor.

In FIG. 4B, a solid line represents a change in a rate (%) of the energy, which is generated by the power generation device 2 and stored in the capacitor, according to the capacitance of the capacitor with respect to the maximum stored energy being defined as 100%.

In a case where the capacitance of the capacitor is set to a capacitance indicated by a white arrow in FIG. 4B, the impedance match is attained between the capacitor and the power generation device 2 (output side) including the constant current source and the internal resistance, and accordingly, the power can be stored with the highest efficiency.

FIG. 5A a circuit diagram illustrating an equivalent circuit of a load resistance (i.e., the load circuit 3) connected to the power generation device 2 when the power generation device 2 supplies electric power to the load resistance. FIG. 5B is a graph illustrating an example of power storage efficiency according to a condition for storing electric power to the load resistance.

In FIG. 5B, a solid line represents a change in a rate (%) of the electric power, which is generated by the power generation device 2 and stored in the capacitor, according to the resistance value of the load resistance with respect to the maximum supplied electric power being defined as 100%.

When the resistance value of the load resistance is set to a resistance value indicated by a white arrow in FIG. 5B, the load resistance and the internal resistance of the power generation device 2 are the same as each other. Specifically, when the internal resistance is equal to the resistance value of the load resistance, the impedance match with the load circuit 3 (output side) is attained, so that the power can be stored with the highest efficiency.

<Example of Connection of Capacitors>

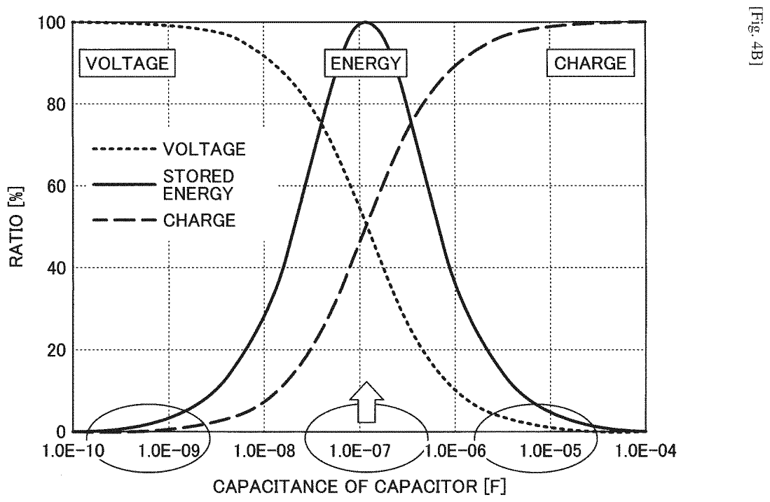

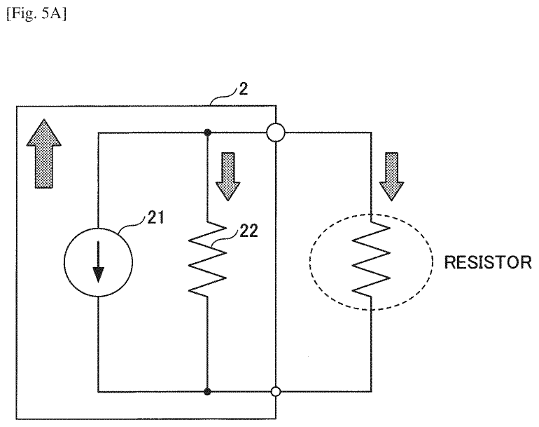

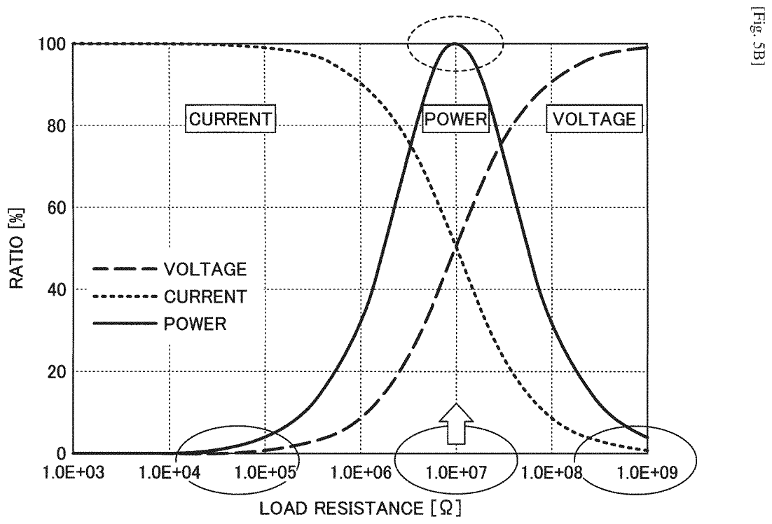

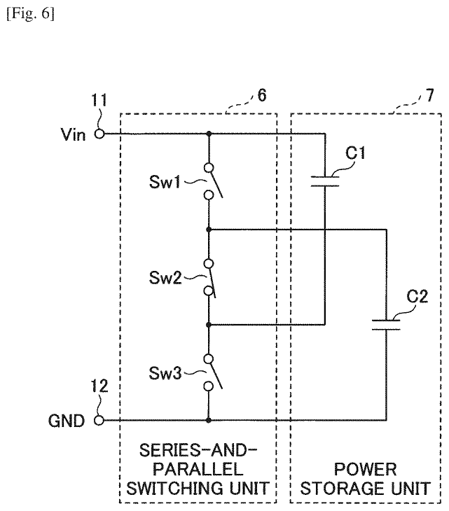

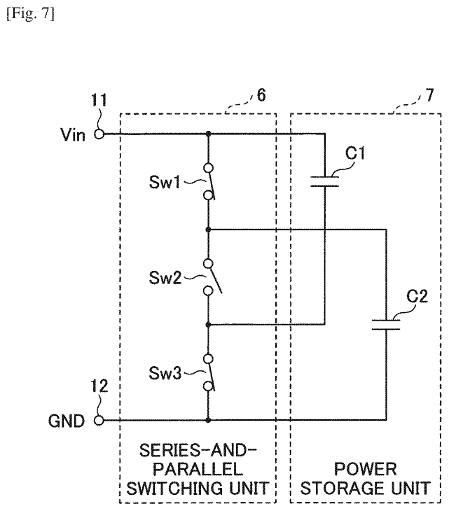

Subsequently, an example of the connection of the capacitors C1, C2 in the power storage unit 7 is explained with reference to FIGS. 6 and 7. FIG. 6 is a circuit diagram illustrating an example of the capacitors C1, C2 connected in series. FIG. 7 is a circuit diagram illustrating an example of capacitors C1, C2 connected in parallel.

As illustrated in FIG. 6, the series-and-parallel switching unit 6 includes three switches Sw1, Sw2, Sw3. The power storage unit 7 includes two capacitors C1, C2. The capacitors are an example of a power storage device. Examples of capacitors include electric double layer capacitors, lithium ion capacitors, and the like. Alternatively, the power storage unit 7 may be constituted by various power storage devices such as lithium-ion batteries, lead-acid batteries, and the like.

As illustrated in FIG. 6, when the switch Sw2 of the series-and-parallel switching unit 6 is in the ON state (i.e., connected state), and the switches Sw1 and Sw3 are in the OFF state (i.e., disconnected state), the capacitors C1, C2 of the power storage unit 7 are connected in series.

As illustrated in FIG. 7, when the switches Swl and Sw3 of the series-and-parallel switching unit 6 are in the ON state, and the switch Sw2 is in the OFF state, the capacitors C1, C2 of the power storage unit 7 are in the parallel connection state.

<Configuration Example of Series-and-Parallel Switching Control Unit 5>

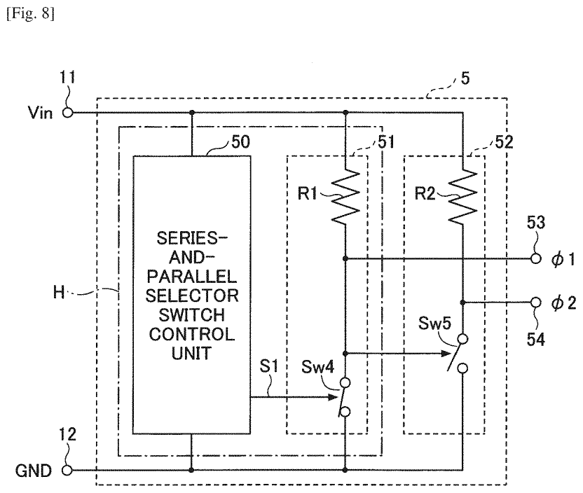

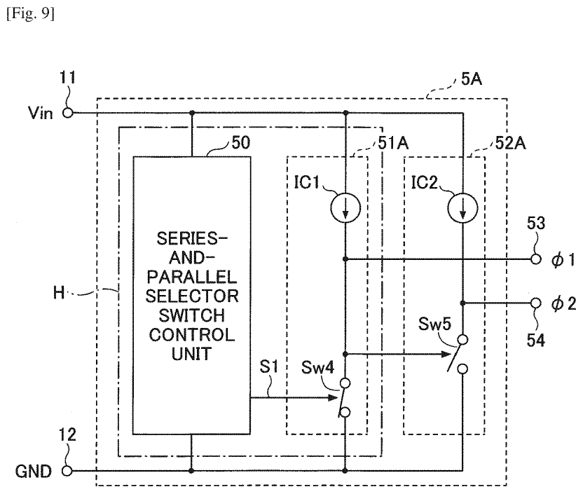

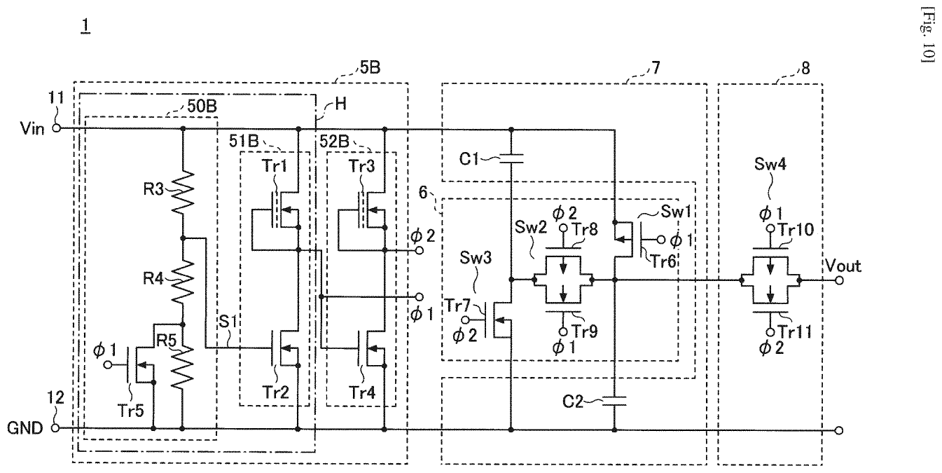

Subsequently, the configuration of the series-and-parallel switching control unit 5 is explained with reference to FIGS. 8 and 9. FIG. 8 is a circuit diagram illustrating a first configuration example of the series-and-parallel switching control unit 5. As illustrated in FIG. 8, the series-and-parallel switching control unit 5 includes a series-and-parallel selector switch control unit 50, two resistances R1, R2, and two switches Sw4, Sw5.

The series-and-parallel selector switch control unit 50 functions as a voltage monitoring circuit (an example of a voltage monitoring unit) for monitoring an input voltage Vin which is a reference for switching series or parallel connection, and outputting a control signal 51. Specifically, the series-and-parallel selector switch control unit 50 generates the control signal S1 in accordance with a detection result of the input voltage Vin to the terminal 11, and controls the switch Sw4 and the switch Sw5 with the generated control signal S1.

In the series-and-parallel switching control unit 5, the resistance R1 and the switch Sw4 constitute an inverter 51 driven with a high impedance, and the resistance R2 and the switch Sw5 constitute an inverter 52 driven with a high impedance. For example, the switches Sw4, Sw5 may be N-ch (N channel) transistors such as an FET (Field Effect Transistor).

The series-and-parallel switching control unit 5 generates the control signal φ1 for controlling the series-and-parallel switching unit 6, and outputs the control signal φ1 through a terminal 53. Also, the series-and-parallel switching control unit 5 generates the control signal φ2 for controlling the series-and-parallel switching unit 6, and outputs the control signal φ2 through a terminal 54.

In the series-and-parallel switching control unit 5, the series-and-parallel selector switch control unit 50 and the inverter 51 function as a hysteresis generation circuit H. The hysteresis generation circuit H has a hysteresis (difference) in a switching threshold value so as to quickly detect a change in the input voltage Vin and prevent a signal once switched from low level to high level (alternatively, from high level to low level) from unstably switching again. In the first embodiment, when the input voltage Vin rises to a predetermined or given first voltage value, the hysteresis generation circuit H switches the control signal φ1 from high level to low level. When the input voltage Vin drops from the first voltage value to a predetermined or given second voltage value, the hysteresis generation circuit H switches the control signal φ1 from low level to high level. Specifically, this is hereinafter explained with reference to FIG. 14.

In the first embodiment, the inverter 51 has the resistance R1 of a high impedance, and the inverter 52 has the resistance R2 of a high impedance, so that even the power generation device 2 of high impedance output that generates high-voltage and low-current electric power with a piezoelectric element or electrostatic induction can drive the circuit of the power storage apparatus 1. For example, the resistance value of each of the resistances R1, R2 is 1 MΩ to 500 MΩ.

Subsequently, FIG. 9 is a circuit diagram illustrating a second configuration example of a series-and-parallel switching control unit 5A. The series-and-parallel switching control unit 5A as illustrated in FIG. 9 includes a series-and-parallel selector switch control unit 50, two constant current sources IC1, IC2, and two switches Sw4, Sw5.

In the series-and-parallel switching control unit 5A, the constant current source IC1 and the switch Sw4 constitute an inverter 51A driven with a high impedance, and the constant current source IC2 and the switch Sw5 constitute an inverter 52A driven with a high impedance. For example, the switches Sw4, Sw5 may be N-ch (N channel) transistors and the like.

The switches Sw4 and Sw5 are controlled by the control signal S1 generated by the series-and-parallel selector switch control unit 50. Based on the control signal S1, the series-and-parallel switching control unit 5A generates a control signal φ1 for controlling the series-and-parallel switching unit 6, and outputs the generated control signal φ1 through a terminal 53. Also, the series-and-parallel switching control unit 5A generates a control signal φ2 for controlling the series-and-parallel switching unit 6, and outputs the generated control signal φ2 through a terminal 54. In the series-and-parallel switching control unit 5A, the series-and-parallel selector switch control unit 50 and the inverter 51A function as the hysteresis generation circuit H. The hysteresis generation circuit H of the series-and-parallel switching control unit 5A is similar to the hysteresis generation circuit H explained with reference to FIG. 8, and detailed explanation thereabout is omitted here.

In the first embodiment, the inverter 51A has the constant current source IC1 of the high impedance, and the inverter 52A has the constant current source IC2 of the high impedance, so that even the power generation device 2 of high impedance output that generates high-voltage and low-current electric power with a piezoelectric element or electrostatic induction can drive the circuit of the power storage apparatus 1. For example, the current value of the current generated by each of the constant current sources IC1, IC2 is 10 nA to 100 μA.

<Example of Circuit Configuration of Power Storage Apparatus 1>

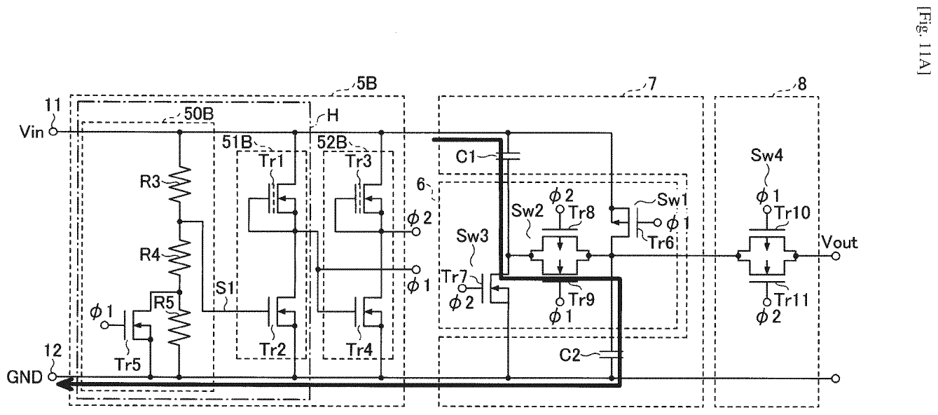

Subsequently, a circuit configuration of the power storage apparatus 1 (see FIG. 10) is hereinafter explained. FIG. 10 is a circuit diagram illustrating an example of circuit configuration of the power storage apparatus 1 according to the first embodiment.

As illustrated in FIG. 10, the power storage apparatus 1 includes a series-and-parallel switching control unit 5B, a series-and-parallel switching unit 6, a power storage unit 7, and an output switching unit 8 (an example of an output unit). It should be noted that the power storage apparatus 1 may be configured as a single power storage IC in which the functions of multiple ICs are integrated.

The series-and-parallel switching control unit 5B includes a series-and-parallel selector switch control unit 50B, two depletion transistors Tr1, Tr3, and two N-ch transistors Tr2, Tr4.

In the first embodiment, the series-and-parallel selector switch control unit 50B includes an N-ch transistor Tr5 and three resistances R3, R4, R5. The three resistances R3, R4, R5 are resistors of high impedance having high resistance values (high impedances). The N-ch transistor Tr5 is a hysteresis generation switch, which may receive a signal representing the state of the load circuit 3.

The series-and-parallel selector switch control unit 50B monitors the input voltage Vin for switching the series connection to the parallel connection, and outputs the control signal S1.

The series-and-parallel switching control unit 5B have two inverters 51B, 52B, which are controlled by a control signal (S1) generated by the series-and-parallel selector switch control unit 50B.

The inverter 51B includes the depletion transistor Tr1 and the N-ch transistor Tr2. The control signal φ1 from the inverter 51B is retrieved through the terminal 53.

The series-and-parallel selector switch control unit 50B and the inverter 51B constitute the hysteresis generation circuit H. The inverter 52B includes the depletion transistor Tr3 and the N-ch transistor Tr4. The control signal φ2 from the inverter 52B is retrieved through the terminal 54. Alternatively, each of the inverters 51B, 52B may be configured to include an N-ch transistor and a resistor.

It should be noted that the depletion transistors Tr1, Tr3 function as the constant current sources IC1, IC2, respectively, of FIG. 9. The N-ch transistor Tr2, Tr4 function as the switches Sw4, Sw5, respectively, of FIG. 9.

While the electric power is stored to the capacitors C1, C2, the series-and-parallel switching control unit 5B outputs the control signal φ1 of the high level and the control signal φ2 of the low level to connect the multiple capacitors C1, C2 in series. Then, when the input voltage Vin attains a predetermined or given first voltage value, the series-and-parallel switching control unit 5B outputs the control signal φ1 of the low level and the control signal φ2 of the high level so as to connect the capacitors C1, C2 in parallel.

Thereafter, when the load circuit consumes electric power, and accordingly, the voltage Vin drops to less than a predetermined or given second voltage value, the series-and-parallel switching control unit 5B outputs the control signal φ1 of the high level and the control signal γ2 of the low level to connect the capacitors C1, C2 in series.

The series-and-parallel switching unit 6 includes a P-ch (P channel) transistor Tr6, an N-ch transistor Tr7, and analog switches Tr8, Tr9.

In the series-and-parallel switching unit 6, the P-ch transistor Tr6 corresponds to the switch Sw1 of FIG. 6, FIG. 7, and the N-ch transistor Tr7 corresponds to the switch Sw3 of FIG. 6, FIG. 7. The switch Sw2 is constituted by an analog switch including two transistors Tr8, Tr9.

When the series-and-parallel switching unit 6 and the output switching unit 8 are constituted by transistors which are analog switches, voltage loss (potential difference) does not occur. In contrast, if the switch is constituted by a diode, voltage loss occurs. Because the series-and-parallel switching unit 6 and the output switching unit 8 are constituted by transistors which are analog switches, the switches can be operated without any potential difference.

In the series-and-parallel switching unit 6, the P-ch transistor Tr6 and the N-ch transistor Tr7 may be replaced with diodes. Specifically, to replace the P-ch transistor Tr6 with a diode, the cathode of the diode is connected to Vin line, and the anode of the diode is connected is to a terminal of the analog switch. To replace the N-ch transistor Tr7 with a diode, the cathode of the diode is connected to a terminal of the analog switch, and the anode of the diode is connected to the GND line.

Also, in the series-and-parallel switching unit 6, diodes may be connected in parallel with the P-ch transistor Tr6 and the N-ch transistor Tr7. Specifically, in parallel with the P-ch transistor Tr6, the cathode of the diode is connected to Vin line, and the anode of the diode is connected to a terminal of the analog switch. In parallel with the N-ch transistor Tr7, the cathode of the diode is connected to a terminal of the analog switch, and the anode of the diode is connected to the GND line.

Although not illustrated in FIG. 1 explained above, the power storage apparatus 1 may have, as illustrated in FIG. 10, the output switching unit 8 for supplying electric power to the load circuit 3 only when the capacitors C1, C2 are connected in parallel. The output switching unit 8 is constituted by an analog switch including a P-ch transistor Tr10 and an N-ch transistor Tr11.

In the power storage apparatus 1, the output switching unit 8 for supplying electric power to the load circuit 3 only when the capacitors C1, C2 are connected in parallel may be constituted by only the P-ch transistor Tr10.

In the power storage apparatus 1, the resistors having high resistances and the constant current transistors have high resistances, and therefore, the series-and-parallel switching control unit 5B has a high resistance value (high impedance). Therefore, the power storage apparatus 1 can be driven by a current (for example, 60 nA) that is lower than the high-voltage and low-current electric power (for example, 400 V, 6μA) generated by the power generation device 2.

In the configuration of FIG. 10, the summation of the impedances of the devices constituting the series-and-parallel switching control unit 5B, the series-and-parallel switching unit 6, and the output switching unit 8 can be set to an impedance equal to or more than the internal impedance of the power generation device 2. Therefore, the electric power consumed to drive series-and-parallel switching operation of the power storage apparatus 1 can be reduced, and the power storage efficiency can be increased.

The devices constituting the series-and-parallel switching unit 6 and the output switching unit 8 are MOS (Metal Oxide semiconductor) transistors, and therefore, the series-and-parallel switching unit 6 and the output switching unit 8 controlled by the series-and-parallel switching control unit 5B consume only the electric power for driving the gates of the MOS transistors when turning on or off the switching units. Therefore, the power storage efficiency can be increased.

Furthermore, the impedance of the power storage apparatus 1 for storing electric power is higher than the impedance of the power storage apparatus 1 for supplying electric power. Therefore, the power storage apparatus 1 can store high-voltage and low-current electric power, so that the power storage efficiency can be increased. For example, the voltage of the electric power supplied by the power storage apparatus 1 is 3 V, and therefore, the power storage apparatus 1 can drive an electric device such as a CPU that consumes a current of several milliamperes.

In FIG. 10, the inverters 51B, 52B constituted by the depletion transistors and the N-ch transistors have two-stage configuration, but the number of stages of inverters may be increased in a similar manner when a higher gain is desired. In that case, it is preferable that the timing of change of the control signal φ1 output from the inverter 51B and the timing of change of the control signal γ2 output from the inverter 52B are adjusted in line with the switching timing of the series-and-parallel switching unit 6.

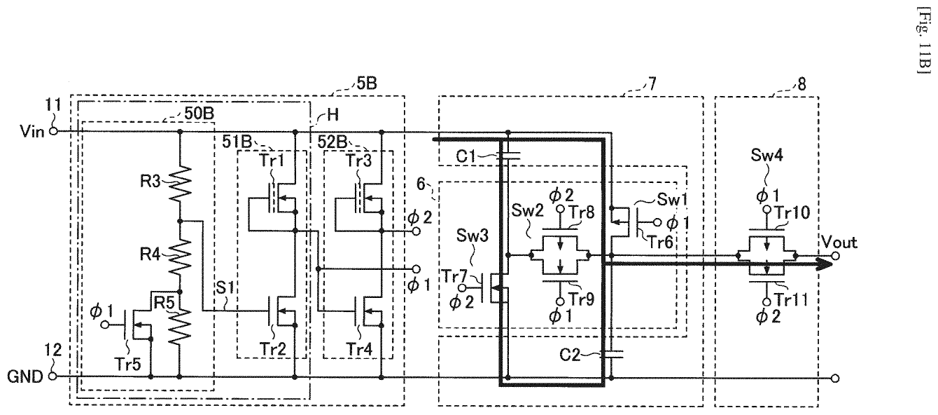

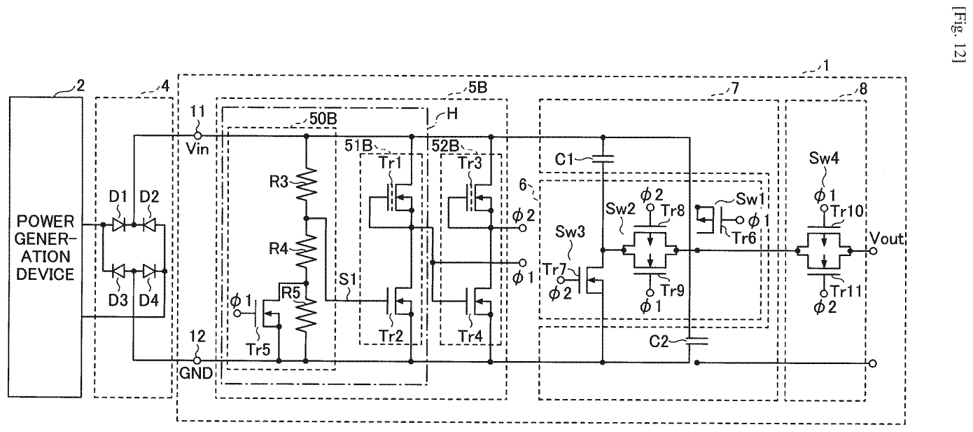

Hereinafter, the flow of the current in the power storage apparatus 1 of FIG. 10 is explained with reference to FIG. 11. FIG. 11A is a circuit diagram illustrating an example of flow of the current in the power storage apparatus 1 according to the first embodiment, when the power storage apparatus 1 stores electric power (i.e., the capacitors C1, C2 are connected in series). FIG. 11B is a circuit diagram illustrating an example of flow of a current in the power storage apparatus 1 according to the first embodiment, when the power storage apparatus 1 supplies electric power (i.e., the capacitors C1, C2 are connected in parallel).

The gate of the P-ch transistor Tr6 constituting the switch Swl receives the control signal φ1, and accordingly, the P-ch transistor Tr6 turns on when the control signal φ1 attains the low level, i.e., when the power storage apparatus 1 supplies electric power.

The gate of the N-ch transistor Tr7 constituting the switch Sw3 receives the control signal γ2, and accordingly, the N-ch transistor Tr7 turns on when the control signal γ2 attains the high level, i.e., when the power storage apparatus 1 supplies electric power.

The gate of the P-ch transistor Tr8 constituting the switch Sw2 receives the control signal γ2, and the gate of the N-ch transistor Tr9 constituting the switch Sw2 receives the control signal γ2. Accordingly, the switch Sw2 turns on when the control signal γ2 attains the low level and the control signal φ1 attains the high level, i.e., when the power storage apparatus 1 stores electric power.

In the switch Sw4 of the output switching unit 8, the gate of the P-ch transistor Tr10 receives the control signal φ1, and the gate of the N-ch transistor Tr11 receives the control signal γ2. Accordingly, the switch Sw4 turns on when the control signal φ1 attains the low level and the control signal γ2 attains the high level, i.e., when the power storage apparatus 1 supplies electric power to the load circuit 3.

The currents flow through the switches Sw1, Sw2, Sw3 included in the series-and-parallel switching unit 6 and through the switch Sw4 of the output switching unit 8 in order to change the states of these switches only when connection is switched between the series connection and the parallel connection. Therefore, the currents consumed to switch between storing of electric power and supplying of electric power can be reduced.

<Example of Circuit Configuration of Power Storage System 100>

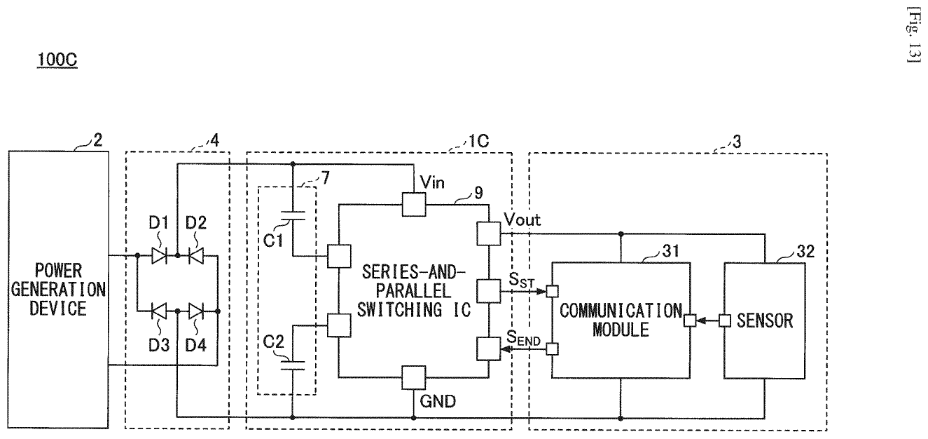

Subsequently, the circuit configuration of the power storage system 100 is explained with reference to FIG. 12. FIG. 12 is a circuit diagram illustrating an example of circuit configuration of the power storage system 100 according to the first embodiment.

The rectifying circuit 4 is constituted by a diode bridge including four diodes D1, D2, D3, D4. The rectifying circuit 4 performs full-wave rectification to rectify the alternating-current electric power output from the power generation device 2.

When rectified electric power is stored to the capacitors C1, C2 connected in series in the power storage apparatus 1, and the capacitors C1, C2 attain the first voltage value, the capacitors C1, C2 are switched to the parallel connection as illustrated in FIG. 11B, and the electric power stored in the capacitors C1, C2 is supplied to the load circuit 3.

<Example of Making Power Storage System Into IC>

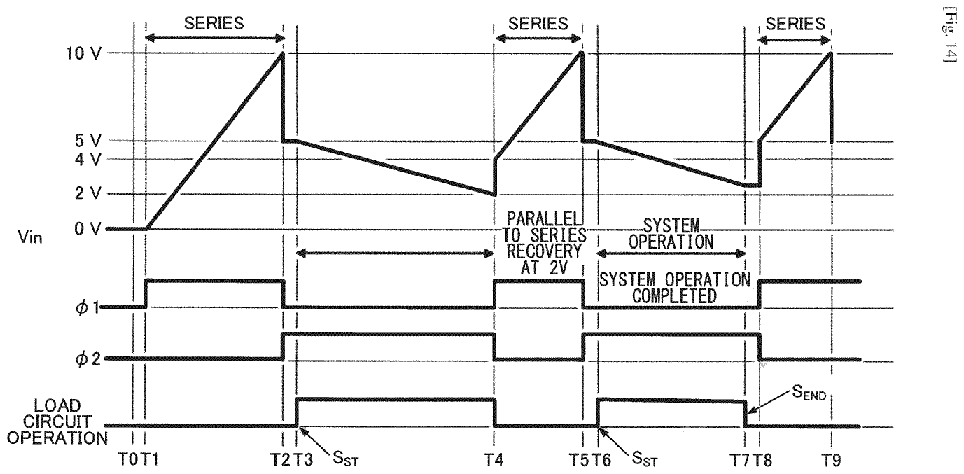

Subsequently, an example of making the power storage system 100 into an IC is explained with reference to FIG. 13. FIG. 13 is a circuit diagram illustrating an example of configuration of a power storage system 100C made into an IC including a control circuit with a communication module 31.

As illustrated in FIG. 13, the load circuit 3 of the power storage system 100C includes the communication module 31 and a sensor 32. Also, the power storage apparatus 1C includes a series-and-parallel switching IC 9 in which the series-and-parallel switching control unit 5, the series-and-parallel switching unit 6, and the output switching unit 8 are integrated.

The series-and-parallel switching IC 9 has a function of controlling the timing of series-and-parallel switching in cooperation with the communication module 31 implemented with a microcomputer. The power storage system 100C supplies the output voltage Vout of the series-and-parallel switching IC 9 to the communication module 31 and the sensor 32.

When the capacitors C1, C2 are connected in parallel, the series-and-parallel switching IC 9 outputs a signal S_{ST} indicating parallel state to the microcomputer provided in the communication module 31 to notify the communication module 31 that the power storage system 100C is ready to supply power.

At a predetermined or given timing after the system operation of the communication module 31 is completed, the communication module 31 outputs, to the series-and-parallel switching IC 9, a signal S_{END} notifying that it is no longer needed to supply electric power to the microcomputer, to instruct the series-and-parallel switching IC 9 to transition to storing of electric power. The power storage apparatus 1C having received the instruction switches the capacitors C1, C2 to the series connection state to start charging. In this case, the signal S_{END} is a signal for changing the connection of the capacitors C1, C2 from parallel connection to series connection by controlling the gate of the N-ch transistor Tr5 of the series-and-parallel switching control unit 5 of FIG. 11 to control the voltage.

With the configuration of the power storage system 100C, the power storage apparatus 1C can improve the power storage efficiency by cooperating with the load-side CPU.

In addition, the power storage system 100C can use, as an IoT edge terminal via communication means such as radio, a result which the microcomputer provided in the communication module 31 produces by performing signal processing of the signal from the sensor 32.

<Operation of Power Storage Apparatus 1>

Subsequently, operation of the power storage apparatus 1 is explained with reference to FIG. 14. FIG. 14 is a timing chart illustrating an example of series-and-parallel switching operation of the power storage apparatus 1.

The electric power generated by the power generation device 2 is rectified by the rectifying circuit 4 and input to the power storage apparatus 1.

At a time T0, the capacitors C1, C2 are in a state not storing electric power.

At a time T1, the rectified electric power starts to be input into the power storage apparatus 1. Because the series-and-parallel switching control unit 5B has the high impedance configuration, the electric power that is output from the power generation device 2 with a high impedance activates and causes the series-and-parallel switching control unit 5B to generate the control signal φ1 and φ2.

When the power starts to be stored, the control signal φ1 attains the high level, and the control signal γ2 attains the low level. Accordingly, the series-and-parallel switching unit 6 is activated to turn off the switches Sw1, Sw3 and turn on the switch Sw2. As a result, the capacitors C1, C2 of the power storage unit 7 are connected in series.

When the input voltage Vin, i.e., the electric power from the power generation device 2, attains 10 V (i.e., the first voltage value) while the capacitors C1, C2 are connected in series, the series-and-parallel selector switch control unit 50B operates to switch the control signal φ1 to the low level and the control signal γ2 to the high level at a time T2. In response, the series-and-parallel switching unit 6 is activated to turn off the switch Sw2 and turn on the switches Sw1, Sw3. As a result, the capacitors C1, C2 in the power storage unit 7 are connected in parallel. When the capacitors C1, C2 are switched from the series connection to the parallel connection, the voltage changes from (Vin=V_{C1}+V_{C2}) to (Vin=V_{C1}=V_{C2}). Accordingly, the voltage of the stored electric power (i.e., the input voltage Vin) decreases by half (10 V to 5 V). In this case, V_{C1} is the voltage of the electric power stored in the capacitor C1, and V_{C2} is the voltage of the electric power stored in the capacitor C2.

At a time T3, when the load circuit 3 is activated, the electric power (i.e., the output voltage Vout) is supplied to the load circuit 3, and accordingly, the input voltage Vin decreases.

In this case, from the times T2 to T4, no electric power is assumed to be received from the power generation device 2.

When the input voltage Vin decreases to 2 V (second voltage value), the control signal φ1 attains the high level, and the control signal γ2 attains the low level at the time T4. Accordingly, the switches Sw1, Sw3 are turned off, and the switch Sw2 is turned on. As a result, the capacitors C1, C2 of the power storage unit 7 are connected in series, and the electric power from the power generation device 2 is stored in the power storage unit 7.

Thereafter, when the input voltage Vin increases to 10 V, the capacitors C1, C2 are switched to the parallel connection.

The above operation is performed continuously.

In this case, FIG. 14 illustrates an example in which the timing at which the input voltage Vin attains 10 V is assumed to be the time T2, and the timing at which the input voltage Vin attains 2 V is assumed to be the time T4. The first voltage value and the second voltage value corresponding to the times T2 and T4, respectively, are not limited thereto. The first voltage value and the second voltage value can be set to any given respective voltages by changing the resistance values of the resistances R3, R4, R5 of the series-and-parallel selector switch control unit 50B.

The power storage apparatus 1 may continue to receive the electric power from the power generation device 2 in the parallel state. In this case, the input voltage Vin from the times T3 to T4 may decrease gently, and in some cases, may increase.

Subsequently, an example of operation of the power storage system 100C (see FIG. 13) is explained with reference to the right-hand side of FIG. 14. The power storage system 100C also performs operation from the times T0 to T5 in a similar manner.

At a time T6, the series-and-parallel switching IC 9 outputs a signal S_{ST} indicating parallel state to the microcomputer provided in the communication module 31 to notify the communication module 31 that the power storage system 100C is ready to supply power. In FIG. 14, periods from the times T3 to T4 and from the times T6 to T7 correspond to a load circuit operation period (i.e., a power supply period and a system operation period) in which the power storage apparatus 1 supplies electric power to the communication module 31 in synchronization with the communication module 31.

At a time T7, the system operation of the communication module 31 is completed. Thereafter, when the communication module 31 starts to output the signal S_{END} to the series-and-parallel switching IC 9 at a time T8, the capacitors C1, C2 are switched to the series connection to start to be charged.

In a case where the power storage apparatus 1 operates in synchronization with the communication module 31, the power storage apparatus 1 stops supplying of electric power in response to a voltage drop to 2 V or the output of the signal S_{END}, whichever is earlier, during the power supply period. In the example of FIG. 14, the signal S_{END} is output before the voltage drops to 2 V. Therefore, at that point in time, i.e., the point in time when the signal S_{END} is output, the power storage apparatus 1 stops supplying of electric power, and switches the connection of the capacitors C1, C2 to the series connection to transition to the power storage operation.

<Example of Stored Electric Power>

Hereinafter, the electric power stored in a capacitor is explained.

The amount of energy W (J) that can be stored in a capacitor is expressed by the above expression (1).

When n capacitors are connected in series, a capacitance Csn is expressed by the following expression (2).

Math 2

Csn=C/n (2)

When n capacitors are connected in parallel, a capacitance Cpn is expressed by the following expression (3).

Math 3

Cpn=n×C (3)

The amount of energy Ws that can be stored by the n capacitors connected in series is expressed by the following expression (4).

$$\begin{matrix}Math 4 & \\ Ws = \frac{1}{2} \times \frac{C}{n} \times {( n \times V )}^{2} = \frac{1}{2} nc {V}^{2} & ( 4 )\end{matrix}$$

The amount of energy Wp that can be stored by the n capacitors connected in parallel is expressed by the following expression (5).

$$\begin{matrix}Math 5 & \\ Wp = \frac{1}{2} \times n \times C \times {V}^{2} = \frac{1}{2} n c {V}^{2} & ( 5 )\end{matrix}$$

For example, specifically, where n=2, C=1 (μF (microfarad)), and V =5 (V (volt)), the amount of energy Ws that can be stored in the two capacitors connected in series can be calculated by the following expression (6).

$$\begin{matrix}Math 6 & \\ Ws = \frac{1}{2} \times \frac{1 ( μ F )}{n} \times {( 2 \times 5 )}^{2} ( V ) = 25 ( μ J ) & ( 6 )\end{matrix}$$

The amount of energy Wp that can be stored in the two capacitors connected in parallel can be calculated by the following expression (7).

$$\begin{matrix}Math 7 & \\ Wp = \frac{1}{2} \times 2 \times 1 ( μ F ) \times {5}^{2} ( V ) = 25 ( μ J ) & ( 7 )\end{matrix}$$

In this manner, the amount of energy Ws is the same as the amount of energy Wp. This means that regardless of whether n capacitors of the same capacitance are connected in series or connected in parallel to store the power, the same amount of energy can be stored in the capacitors. In order to store the electric power to the n capacitors connected in series, the electric power is to be stored at a high voltage n×V (V).

In a system such as IoT, the stored electric power is expected to drive the CPU and supply the electric power to the electric device that connects the sensor and the like. These devices are to be driven with 1 to 3 lithium-ion batteries, for example, at a voltage of about 3 to 10 V and a current of about several microamperes to several milliamperes.

In this case, the electric power is stored with a high impedance state in which n capacitors of the same capacitance C are connected in series, and these capacitors are switched from the series connection to the parallel connection, so that the IoT system and the like can be drive in a low impedance state with a low voltage while the electric power is stored in the capacitors.

Where the resistance value of the resistance provided in the circuit is denoted as R, the impedance Z is defined by the following expression (8).

$$\begin{matrix}Math 8 & \\ Z = R + \frac{1}{j ω C} & ( 8 )\end{matrix}$$

When n capacitors are connected in series, the impedance Zsn of the circuit is expressed by the following expression (9) in which the capacitance Csn is replaced according to the expression (2).

$$\begin{matrix}Math 9 & \\ Zsn = R + \frac{1}{j ω Csn} = R + n \times \frac{1}{j ω C} & ( 9 )\end{matrix}$$

When n capacitors are connected in parallel, the impedance Zpn of the circuit can be expressed by the expression (10) in which the capacitance Cpn is replaced according to the expression (3).

$$\begin{matrix}Math 10 & \\ Zpn = R + \frac{1}{j ω nC} = R + \frac{1}{n} \times \frac{1}{j ω C} & ( 10 )\end{matrix}$$

In this case, when the resistance value R of the resistance provided in the circuit is reduced, the impedance Zns in the series connection (the expression (9)) is high, and the impedance Zns in the parallel connection (the expression (10)) is low.

In this manner, the series and parallel connections of the capacitors are switched. Accordingly, the power can be stored at a high voltage nxV (V) with a high impedance according to the expression (4) and the expression (9). Also, the power can be efficiently supplied at a low voltage V (V) to the load circuit according to the expression (5) and the expression (10).

In the power generation with a piezoelectric element or power generation rubber, a high voltage of several dozen volts to several hundreds volts is generated. Also, with such power generation, the generated power has a low current in units of nA and μA, and such power generation can be deemed as a constant current power source of a high output impedance. Therefore, it is desired to provide a circuit for converting, with a high efficiency, electric power stored in capacitors at a high voltage with a piezo-electric element and electrostatic induction into electric power of a power supply for a load current operating at a voltage of about 3 to 10 volts with a current of several microamperes to several milliamperes.

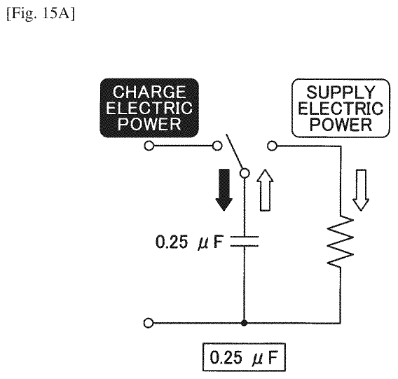

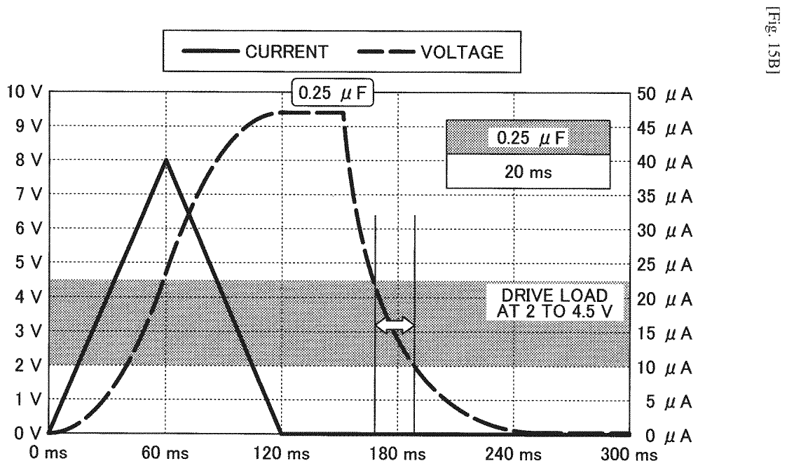

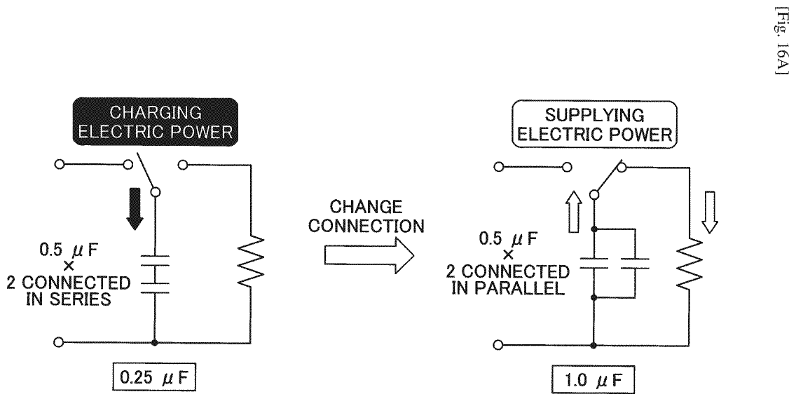

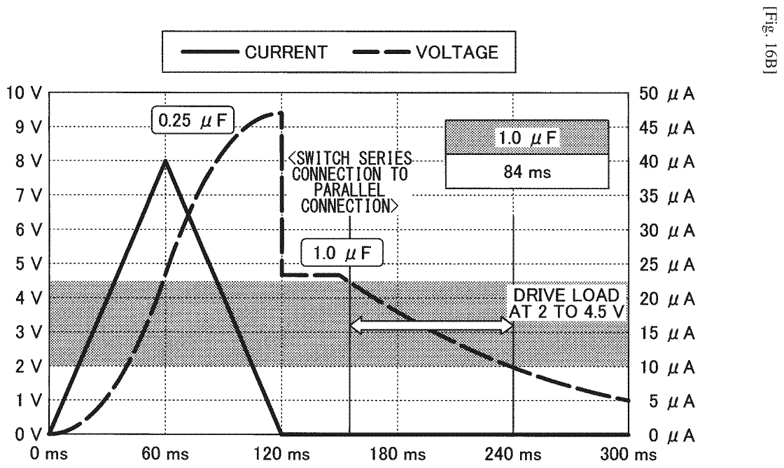

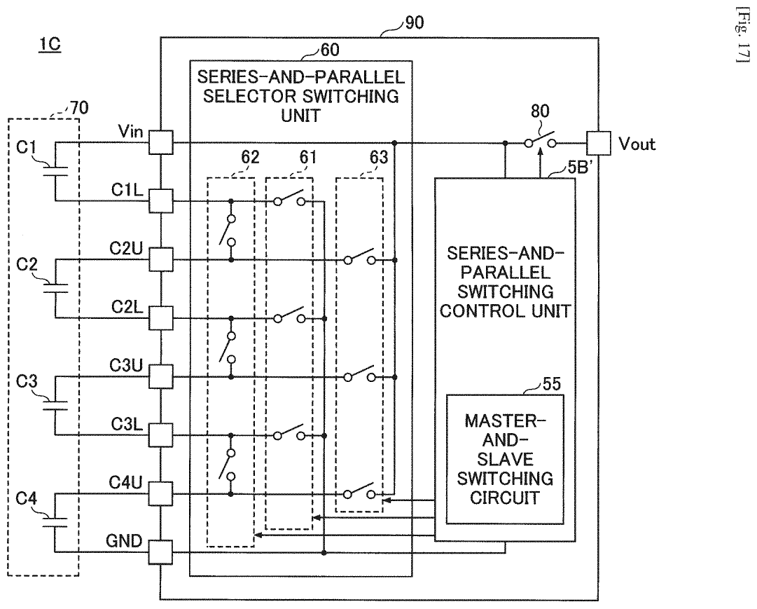

In this case, as a comparative example, FIGS. 15A and 15B illustrate transition of a current when power is stored and when power is supplied with respect to a capacitor having a fixed capacitance. FIGS. 16A and 16B illustrate transition of a current when power is stored and when power is supplied with respect to capacitors of which capacitance is switched between series connection and parallel connection just like the first embodiment.

Specifically, FIG. 15A is a circuit diagram illustrating a transition of a current with respect to a capacitor with a fixed capacitance according to a comparative example, when the capacitor stores electric power or supplies electric power. FIG. 15B is a graph illustrating a transition of a charge current and a voltage of the capacitor with the fixed capacitance according to the comparative example, when the capacitor stores electric power and supplies electric power.

FIGS. 15A and 15B illustrate an example of operation using a single capacitor having a capacitance of 0.25 μF to operate with a capacitance of 0.25 μF for both of charging and power supply.

In general, the voltage for energizing a CPU, sensors, or wireless transmitters is about 2 to 5 volts. As illustrated in FIG. 15B, in the comparative example, the capacitance stored in the capacitor is small, and accordingly, the voltage value drops sharply when supplying electric power, and the voltage value is in a range of 2 to 4.5 volts for 20 milliseconds. Therefore, the electric power can be used only for 20 milliseconds.

In contrast, FIG. 16A is a circuit diagram illustrating a transition of a current with respect to the capacitors according to the first embodiment, when the capacitors are switched from series connection for storing electric power to parallel connection for supplying electric power. FIG. 16B is a graph illustrating a transition of a charge current and a voltage of the capacitors according to the first embodiment, when the capacitor stores electric power and supplies electric power.

FIG. 16 illustrates an example of operation using two capacitors each having a capacitance of 0.5 μF to operate with a capacitance of 0.25 μF in the series connection for charging and to operate with a capacitance of 1.0 μF in the parallel connection for supplying electric power.

As illustrated in FIG. 16B, in the first embodiment, the capacitors are switched from the series connection to the parallel connection for supplying electric power, so that the voltage value is reduced by half by this switching, but the voltage value thereafter decreases gently due to the power supply from the capacitors having a large capacitance. Therefore, the voltage value is in a range of 2 to 4.5 volts for 84 milliseconds. As compared to FIG. 15B, the capacitance of the capacitors during charging is the same, but because of the switching from the series connection to the parallel connection, the length of time the electric power can be used during power supply increases by four times or more.

As illustrated in FIGS. 16A and 16B, in the power storage system according to the first embodiment, the capacitors are switched to the series connection and the parallel connection, so that during storing of electric power, the power storage system can store the power at a high voltage by making an impedance match with a high impedance. In contrast, during supplying of electric power, the power storage system according to the first embodiment can supply power of a voltage required by an IoT system and the like by making an impedance match with a low impedance.

<Example where Many Capacitors are Provided in Power Storage Apparatus>

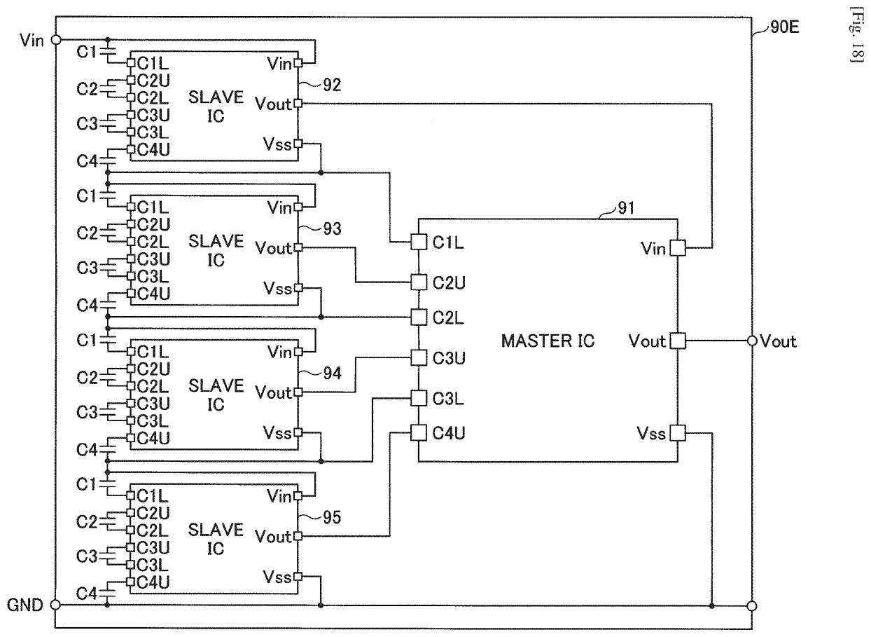

The configuration including two capacitors in the power storage apparatus 1 has been explained, but the number of multiple capacitors is not limited to two. FIG. 17 is a circuit diagram illustrating a configuration example of a circuit in which four capacitors are connected in series. FIG. 17 illustrates internal blocks of a power storage unit 70 including four capacitors and a four-series-and-parallel switching IC 90 for switching the connection of the four capacitors.

The series-and-parallel selector switching unit 60 corresponds to the series-and-parallel switching unit 6 of FIG. 10 and includes switch groups 61, 62, 63. When the capacitors C1, C2, C3, C4 are connected in parallel, the switch groups 61, 63 are turned on, and when the capacitors C1, C2, C3, C4 are connected in series, the switch groups 61, 63 are turned off. When the capacitors C1, C2, C3, C4 are connected in series, the switch group 62 is turned on, and when the capacitors C1, C2, C3, C4 are connected in parallel, the switch group 62 is turned off. The switch 80 corresponds to the output switching unit 8 of FIG. 10.

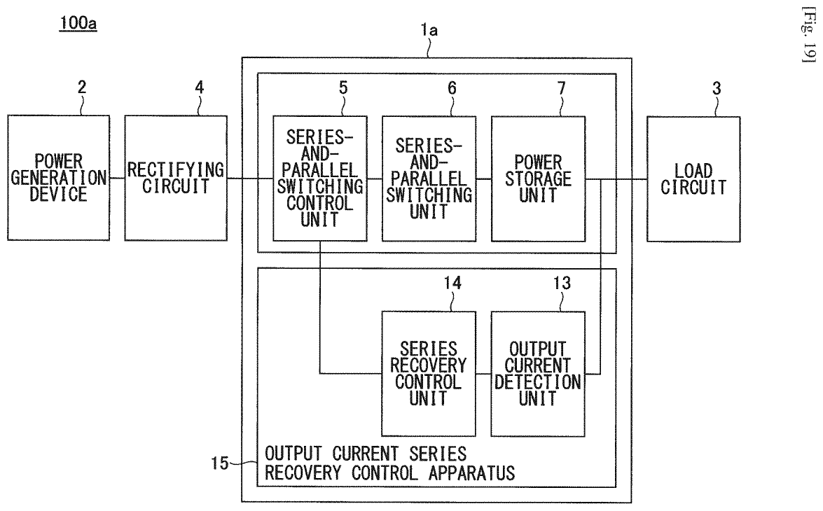

A series-and-parallel switching control unit 5B′ corresponds to the series-and-parallel switching control unit 5B for switching two capacitors illustrated in FIG. 10, but when multiple capacitors are cascode-connected in series in multiple stages as illustrated in FIG. 18, the series-and-parallel switching control unit 5B′ includes a master-and-slave switching circuit 55 for switching the master-side and the slave-side.

Subsequently, FIG. 18 is a circuit diagram illustrating a configuration example of a circuit in which capacitors are connected in multiple stages. In FIG. 18, a multi-stage capacitor connection circuit 90E includes a four-series-and-parallel switching master IC 91 and four-series-and-parallel switching slave ICs 92, 93, 94, 95.

With the master-and-slave switching circuit 55 of FIG. 17 being in the master IC 91, the four ICs 92, 93, 94, 95 are configured to be cascode-connected as slave ICs, and the output voltage Vout output of each of the four ICs 92, 93, 94, 95 is configured to be connected to the four-series-and-parallel switching master IC 91 so as to achieve the multi-stage connection.

When the multi-stage connection is made in this manner, the multi-stage connection is controlled by controlling the four ICs 92, 93, 94, 95 according to the master/slave scheme. Accordingly, capacitors can be connected in a larger number of stages, and a still higher efficiency can be achieved.

In a manner as described above, the power storage apparatus according to the first embodiment can detect a switching voltage even when a high-voltage and low-current power is generated, and the power storage apparatus can operate with the high-voltage and low-current power to switch the series connection and the parallel connection with a high efficiency.

In the first embodiment explained above, the series-and-parallel switching control unit 5 includes the hysteresis generation circuit H to provide hysteresis for the control signal pi, but as long as the series-and-parallel switching control unit 5 can provide the hysteresis, the hysteresis generation circuit may be provided in a unit other than the series-and-parallel switching control unit 5.

### Second Embodiment

Subsequently, the power storage system 100a according to the second embodiment is explained.

In the power storage system 100 according to the first embodiment explained above, the capacitors C1, C2 switched to the parallel connection for supplying electric power maintain the parallel connection until the voltage of the stored electric power attains a second voltage value or less. Therefore, when power is stored after the power storage system 100 has finished supplying electric power to the load circuit, the power storage system 100 cannot switch the capacitors C1, C2 to the series connection until the voltage of the stored electric power becomes the second voltage value or less, and therefore, a high power storage efficiency may not be attained.

For example, in the power storage apparatus 1 (see FIG. 1), when the load circuit 3 stops operation and accordingly the output current becomes 0 A (amperes) while the capacitors C1, C2 connected in parallel to supply electric power to the load circuit 3, the capacitors C1, C2 are maintained in the parallel connection until the voltage of the stored electric power attains the second voltage value or less. When the power storage apparatus 1 receives the electric power from the power generation device 2, the capacitors C1, C2 store the power in the parallel connection state, and therefore, a high power storage efficiency cannot be achieved.

In contrast, in the second embodiment, the connection of multiple power storage devices is switched from the parallel connection to the series connection, on the basis of the output current of the power storage unit having multiple power storage devices. For example, when the output current attains a first current value or less while multiple power storage devices are connected in parallel, the connection of the multiple power storage devices is switched from the parallel connection to the series connection. Therefore, multiple power storage devices connected in series can store power without waiting for the voltage of the stored electric power to attain the second voltage value or less, so that the power storage efficiency can be improved.

<Configuration Example of Power Storage System 100a>

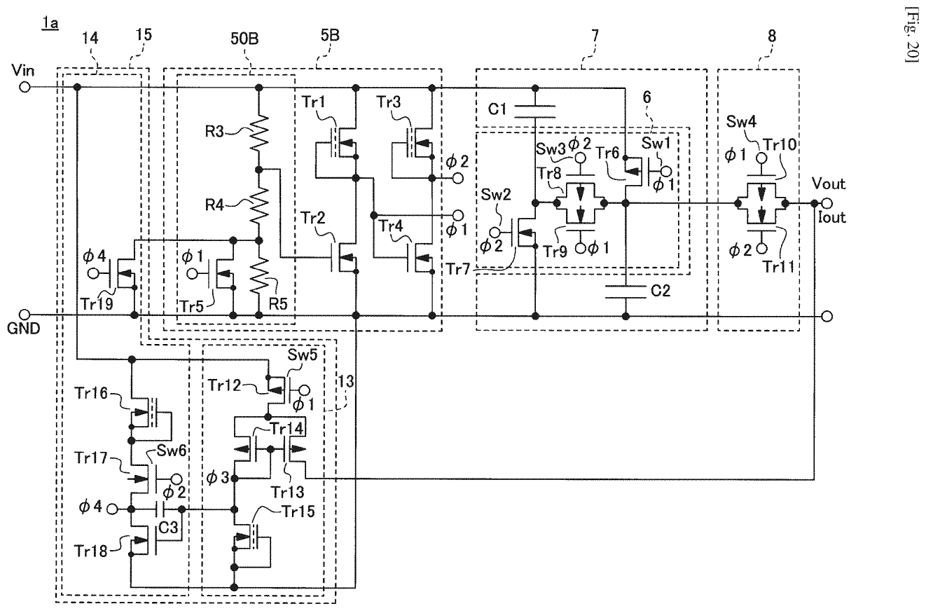

Hereinafter, the configuration of the power storage system 100a is explained with reference to FIG. 19. FIG. 19 is a block diagram illustrating an example of configuration of a power storage system 100a according to the second embodiment.

As illustrated in FIG. 19, the power storage system 100a includes a power storage apparatus 1a. The power storage apparatus 1a includes an output current series recovery control apparatus 15 including an output current detection unit 13 and a series recovery control unit 14.

Like the power storage system 100 explained above, in the power storage system 100a, the rectifying circuit 4 rectifies the electric power generated by the power generation device 2, and the capacitors C1, C2 connected in series in the power storage unit 7 store the rectified electric power. Thereafter, when the voltage of the stored electric power attains the first voltage value, the series-and-parallel switching unit 6 operates under the control of the series-and-parallel switching control unit 5 to switch the capacitors C1, C2 to the parallel connection. The capacitors C1, C2 connected in parallel supply the electric power to the load circuit 3.

Also, the output current detection unit 13 detects the current that is output from the power storage apparatus 1a to the load circuit 3, and outputs the detection result to the series recovery control unit 14. When the output current detected by the output current detection unit 13 attains a predetermined or given current value (i.e., a first current value) or less, the series recovery control unit 14 causes the series-and-parallel switching control unit 5 to switch the connection of the capacitors C1, C2 from the parallel connection to the series connection. The series-and-parallel switching unit 6 operates under the control of the series-and-parallel switching control unit 5 to switch the connection of the capacitors C1, C2 from the parallel connection to the series connection. The capacitors C1, C2 connected in series store the electric power generated by the power generation device 2.

<Configuration Example of Power Storage Apparatus 1a>

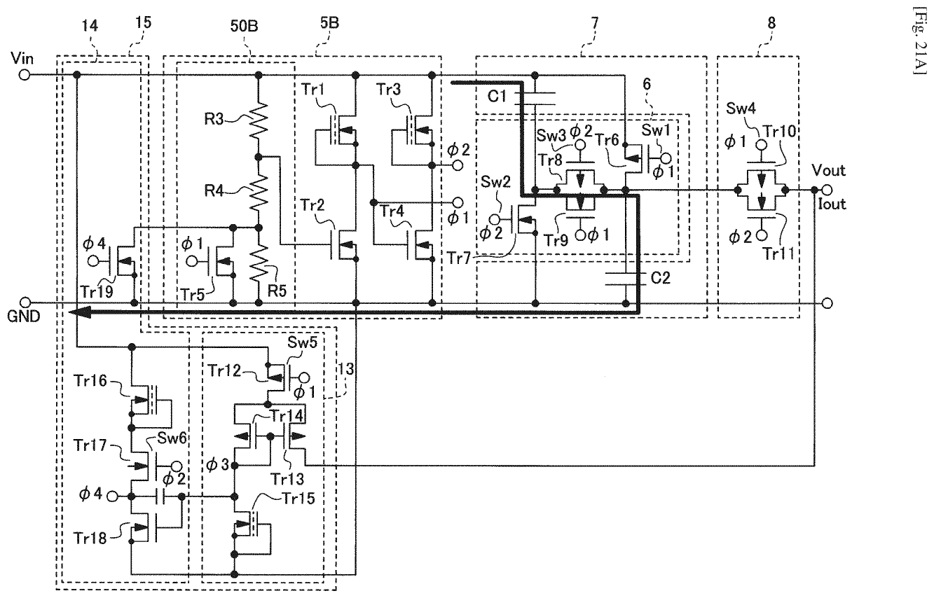

Subsequently, an example of circuit configuration of the power storage apparatus 1a is explained with reference to FIG. 20. FIG. 20 is a circuit diagram illustrating an example of circuit configuration of the power storage apparatus 1a according to the second embodiment.

As illustrated in FIG. 20, the power storage apparatus 1a includes a series-and-parallel switching control unit 5B, a series-and-parallel switching unit 6, a power storage unit 7, an output switching unit 8, an output current detection unit 13, and a series recovery control unit 14. It should be noted that the power storage apparatus 1a may be configured as a single power storage IC that integrates the series-and-parallel switching control unit 5B, the series-and-parallel switching unit 6, the power storage unit 7, the output switching unit 8, the output current detection unit 13, and the series recovery control unit 14.

The output current detection unit 13 includes a P-ch transistor Tr12 includes: a P-ch transistor Tr12 which is a switch Sw5 turned on while an output current lout is output; a P-ch transistor Tr13 detecting the output current lout, a P-ch transistor Tr14 constituting a current comparator; and a depletion transistor Tr15. In this case, the P-ch transistor Tr13 is an example of “monitor transistor”. Also, the output current detection unit 13 may have a resistor instead of the depletion transistor Tr15.

In this case, a current flowing through the depletion transistor Tr15 is a constant current Itr15, and the P-ch transistor Tr14 and the depletion transistor Tr15 operate as a current comparator, and therefore, when the current Itr14 of the P-ch transistor Tr14 is larger than the constant current Itr15, the output signal φ3 attains the high level. In contrast, when the current Itr14 is less than the constant current Itr15, the output signal φ3 attains the low level. According to a transistor size ratio between the P-ch transistor Tr14 and the depletion transistor Tr15, the first current value can be set.

Furthermore, the output current of the power storage apparatus 1a depends on the size of the P-ch transistor Tr10, which is a switch Sw4, and therefore, the first current value can be set by adjusting the size ratio of P-ch transistor Tr10 and P-ch transistor Tr13. However, because the P-ch transistor Tr13 and P-ch transistor Tr14 are constituted by a current mirror circuit, the size ratio of the P-ch transistor Tr13 and the P-ch transistor Tr14 may be adjusted.

The series recovery control unit 14 includes: an N-ch transistor Tr17, which is a switch Sw6 turned on while the output current lout is output; a depletion transistor Tr16 constituting an inverter generating a series recovery signal φ4; an N-ch transistor Tr18; a capacitor C3; and an N-ch transistor Tr19 controlling the series-and-parallel switching control unit 5B. The series recovery control unit 14 may have a resistor instead of the depletion transistor Tr16.

In this case, when the output current lout is larger than the first current value, the output signal φ3 is at the high level, and the series recovery signal φ4 is at the low level, but when the output current lout becomes smaller than the first current value, the series recovery signal φ4 attains the high level, and accordingly, the N-ch transistor Tr19 is turned on. Accordingly, the control signal φ1 of the high level and the control signal γ2 of the low level for connecting the capacitors C1, C2 in series are output to the series-and-parallel switching control unit 5B.

Also, the series-and-parallel switching unit 6 includes a P-ch transistor Tr6, an N-ch transistor Tr7, and analog switches Tr8 and Tr9.

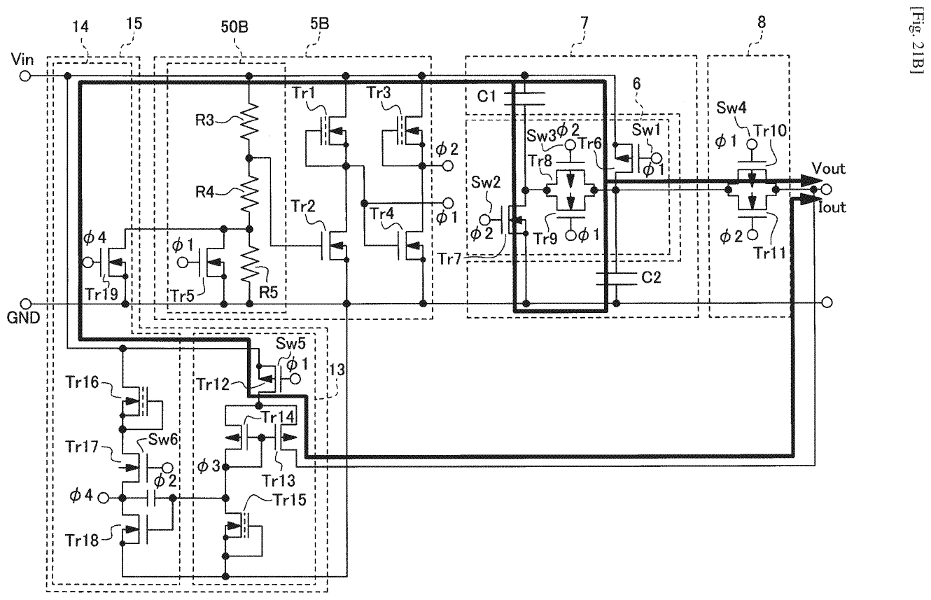

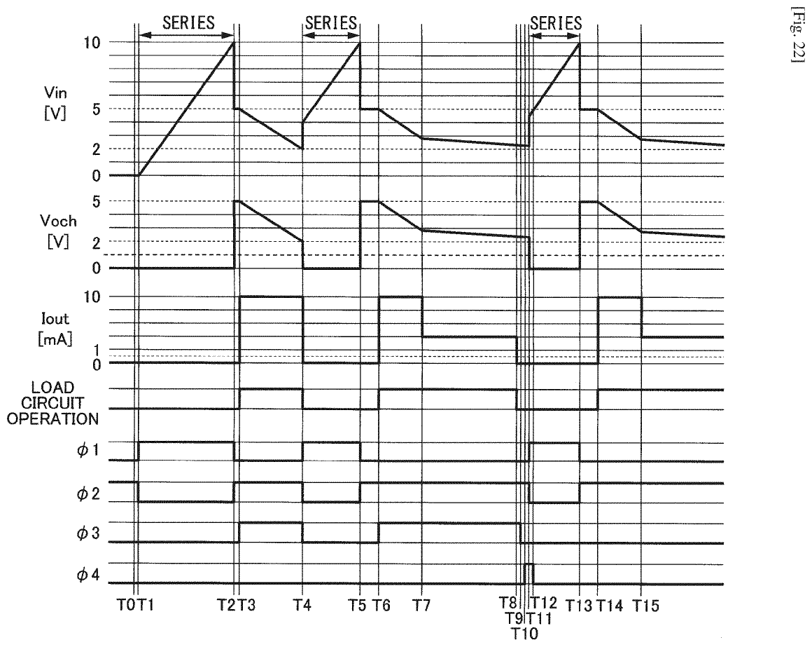

In this case, FIG. 21A to FIG. 21B illustrate a flow of current in the power storage apparatus 1A of FIG. 20. FIG. 21A is a circuit diagram illustrating a flow of a current in the power storage apparatus 1A according to the second embodiment, when the power storage apparatus 1A stores electric power. FIG. 21B is a circuit diagram illustrating a flow of a current in the power storage apparatus 1A according to the second embodiment, when the power storage apparatus 1A supplies electric power.

The gate of the P-ch transistor Tr6 constituting the switch Swl receives the control signal φ1. Accordingly, the P-ch transistor Tr6 is turned on when the control signal φ1 is at the low level, i.e., when the power storage apparatus 1A supplies electric power.

The gate of the N-ch transistor Tr7 constituting the switch Sw2 receives the control signal γ2. Accordingly, the N-ch transistor Tr7 is turned on when the control signal γ2 is at the high level, i.e., when the power storage apparatus 1A supplies electric power.

The gate of the P-ch transistor Tr8 constituting the switch Sw3 receives the control signal γ2, and the gate of the N-ch transistor Tr9 receives the control signal φ1. Accordingly, when the control signal γ2 is at the low level and the control signal φ1 is at the high level, i.e., when the power storage apparatus 1A stores electric power, the switch Sw3 is turned on.

In the switch Sw4 of the output switching unit 8, the gate of the P-ch transistor Tr10 receives the control signal φ1, and the gate of the N-ch transistor Tr11 receives the control signal γ2. Therefore, when the control signal φ1 is at the low level and the control signal γ2 is at the high level, i.e., when the power storage apparatus 1A supplies electric power to the load circuit 3, the switch Sw4 is turned on.

The gate of the P-ch transistor Tr12 constituting the switch Sw5 receives the control signal φ1. The switch Sw5 is turned on when the control signal φ1 is at the low level, i.e., when the power storage apparatus 1A supplies electric power to the load circuit 3.

The gate of the N-ch transistor Tr17 constituting the switch Sw6 receives the control signal γ2. When the control signal γ2 is at the high level, i.e., when the power storage apparatus 1A supplies electric power to the load circuit 3, the switch Sw6 is turned on.

Currents flow through the switches Sw1, Sw2, Sw3 included in the series-and-parallel switching unit 6, the switch Sw4 of the output switching unit 8, the switch Sw5 of the output current detection unit 13, and the switch Sw6 of the series recovery control unit to switch the state of the switches only when connection is switched between the series connection and the parallel connection. Therefore, the currents consumed to switch between storing of electric power and supplying of electric power can be reduced.

<Example of Operation of Power Storage Apparatus 1a According to Second Embodiment>

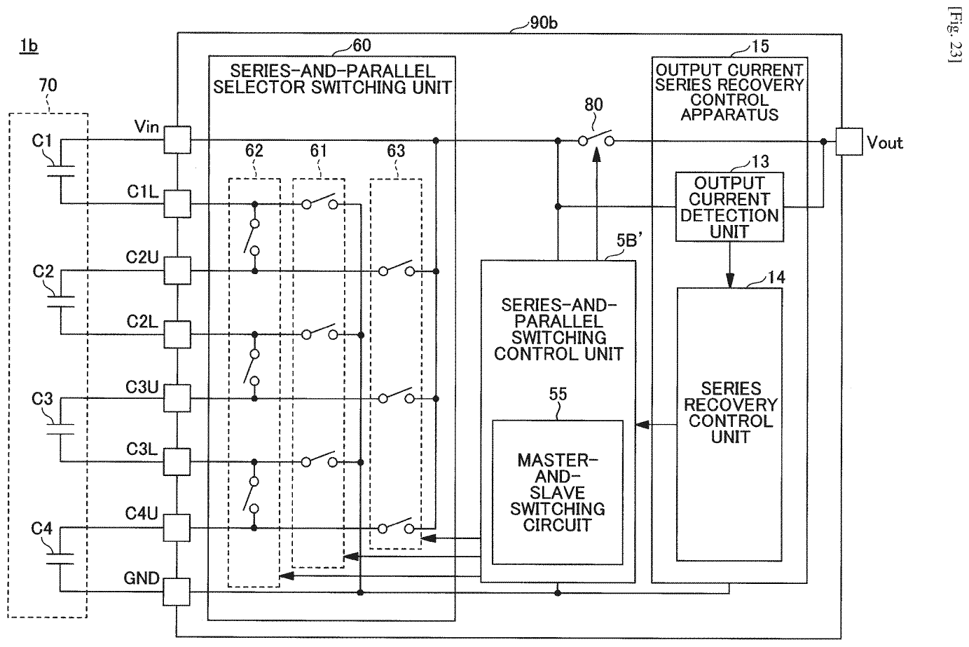

Subsequently, operation of the power storage apparatus 1a is explained with reference to FIG. 22. FIG. 22 is a timing chart illustrating an example of operation of the power storage apparatus according 1a to the second embodiment.

The rectifying circuit 4 rectifies the electric power generated by the power generation device 2, and the rectified electric power is supplied to the rectified power to the power storage apparatus 1a.

At a time T0, the capacitors C1, C2 are not in a state for storing electric power.

At a time T1, the rectified electric power starts to be input into the power storage apparatus 1a. Because the series-and-parallel switching control unit 5B has the high impedance configuration, the electric power that is output from the power generation device 2 with a high impedance activates and causes the series-and-parallel switching control unit 5B to generate the control signal φ1 and φ2.

When the power starts to be stored, the control signal φ1 attains the high level, and the control signal γ2 attains the low level. Accordingly, the series-and-parallel switching unit 6 is activated to turn off the switches Sw1, Sw3 and turn on the switch Sw2. As a result, the capacitors C1, C2 of the power storage unit 7 are connected in series. Also, the output signal φ3 from the output current detection unit 13 attains the low level, and the series recovery signal φ4 of the series recovery control unit 14 attains the low level.

When the input voltage Vin, i.e., the electric power from the power generation device 2, attains 10 V (becomes equal to or more than a first voltage value) while the capacitors C1, C2 are in the series state, the series-and-parallel selector switch control unit 50B operates, at the time T2, to switch the control signal φ1 to the low level and switch the control signal γ2 to the high level. In response, the series-and-parallel switching unit 6 operates to turn off the switch Sw2 and turn on the switches Sw1, Sw3. As a result, the capacitors C1, C2 are connected in parallel. When the capacitors C1, C2 are switched from the series connection to the parallel connection, the voltage changes from (Vin=V_{C1}+V_{C2}) to (Vin=V_{C1}=V_{C2}). Accordingly, the voltage of the stored electric power (i.e., the input voltage Vin) decreases by half (10 V to 5 V).

At a time T3, when the load circuit 3 is activated, the electric power (i.e., the output voltage Vout) is supplied to the load circuit 3, and accordingly, the input voltage Vin decreases. Also, the output signal φ3 from the output current detection unit 13 attains the high level, and the series recovery signal φ4 of the series recovery control unit 14 attains the low level. Also, the input voltage Vin decreases.

In this case, from the times T2 to T4, no electric power is assumed to be received from the power generation device 2.

When the input voltage Vin decreases to 2 V (second voltage value), the control signal φ1 attains the high level, and the control signal γ2 attains the low level at the time T4. Accordingly, the switches Sw1, Sw3 are turned off, and the switch Sw2 is turned on. As a result, the capacitors C1, C2 of the power storage unit 7 are connected in series, and the electric power from the power generation device 2 is stored in the power storage unit 7. Also, the output current Tout to the load circuit 3 is stopped. Accordingly, the output signal φ3 attains the low level, and the series recovery signal φ4 attains the low level.

When input voltage Vin attains 10 V, i.e., the electric power from the power generation device 2, while the capacitors C1, C2 are connected in series, the series-and-parallel selector switch control unit 50B operates to switch the control signal φ1 to the low level and switch the control signal γ2 to the high level at a time T5. In response, the series-and-parallel switching unit 6 operates to turn off the switch Sw2 and turn on the switches Sw1, Sw3, so that the capacitors C1, C2 are connected in parallel. When the capacitors C1, C2 of the power storage unit 7 are switched from the series connection to the parallel connection, the voltage changes from (Vin=V_{C1}+V_{C2}) to (Vin=V_{C1}=V_{C2}). Accordingly, the voltage of the stored electric power (i.e., the input voltage Vin) decreases by half (10 V to 5 V).

Thereafter, at a time T6, when the load circuit 3 is activated, the electric power (i.e., the output voltage Vout) is supplied to the load circuit 3, the output signal φ3 of the output current detection unit 13 attains the high level, and the series recovery signal φ4 of the series recovery control unit 14 attains the low level. Also, the input voltage Vin decreases.

Thereafter, at a time T7, when the current of the load circuit 3 changes, the input voltage Vin decreases according to the magnitude of the output current Tout.

In this case, from the times T5 to T11, no electric power is assumed to be received from the power generation device 2.

Thereafter, at a time T8, when the load circuit 3 stops operation and the output current Tout attains 0 A, or when the current of the load circuit 3 attains 0.5 mA or less (i.e., attains the first current value or less), the output current detection unit 13 detects the current flowing through the P-ch transistor Tr13, and the output signal φ3 of the output current detection unit 13 attains the low level at the time T9.

Thereafter, at the time T10, the series recovery signal φ4 of the series recovery control unit 14 attains the high level.

Thereafter, at the time T11, the series-and-parallel selector switch control unit 50B operates to switch the control signal φ1 to the high level and switch the control signal φ2 to the low level. In response, the series-and-parallel switching unit 6 operates to turn on the switch Sw2 and turn off the switches Sw1, Sw3. Then, the capacitors C1, C2 are connected in series to store the electric power from the power generation device 2.

Thereafter, at the time T12, the output signal φ3 of the output current detection unit 13 attains the low level, and the series recovery signal φ4 of the series recovery control unit 14 attains the low level.

In this manner, in the power storage apparatus 1a, the electric power generated by the power generation device 2 is stored by the capacitors C1, C2 connected in series, and when the voltage of the stored electric power attains the first voltage value, the capacitors C1, C2 can be switched to the parallel connection. When the output current detected by the output current detection unit 13 attains the first current value or less, the power storage apparatus 1a can switch the connection of the capacitors C1, C2 from the parallel connection to the series connection.

<Actions and Effects of Power Storage System 100a>

As described above, in the second embodiment, the connection of the capacitors C1, C2 is switched from the parallel connection to the series connection, on the basis of the output current of the power storage unit 7 having the capacitors C1, C2. For example, when the output current attains the first current value or less while the capacitors C1, C2 are connected in parallel to supply the power from the power storage apparatus 1a, the connection of the capacitors C1, C2 is switched from the parallel connection to the series connection. Therefore, the capacitors C1, C2 connected in series can store the electric power generated by the power generation device 2 without waiting for the voltage of the stored electric power to attain the second voltage value or less, so that the power can be stored more efficiently.

The embodiments are particularly suitable for storing and supplying electric power generated by a low-frequency power generation device such as power generation rubber, but the embodiments are not limited thereto. The embodiments can also be applied to storing and supplying of electric power generated by a high-frequency power generation device such as energy harvesting.

In the above embodiments, the first current value of the output current detection unit 13 is assumed to be 0.5 mA, but the embodiments are not limited thereto, and the first current value of the output current detection unit 13 can be changed as necessary.

FIG. 20 illustrates the power storage apparatus 1a having the two capacitors C1, C2, but the number of capacitors is not limited thereto, and may be further increased. Hereinafter, as a first modified embodiment of the second embodiment, a power storage apparatus 1b having four capacitors is explained.

### First Modified Embodiment

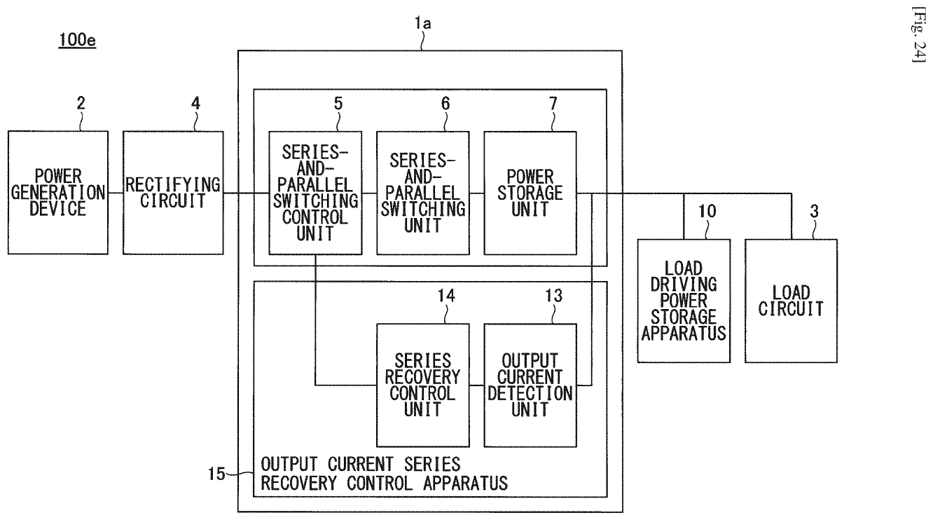

FIG. 23 is a circuit diagram illustrating an example of circuit configuration of the power storage apparatus 1b according to the first modified embodiment of the second embodiment.

FIG. 23 illustrates internal blocks of a power storage unit 70 including four capacitors and a four-series-and-parallel switching IC 90b switching connection of the four capacitors.

The series-and-parallel selector switching unit 60 corresponds to the series-and-parallel switching unit 6 of FIG. 20 and includes switch groups 61, 62, 62, 63. When the capacitors C1, C2, C3, C4 are in the parallel connection, each of the switch groups 61, 62, 63 is turned on, and when the capacitors C1, C2, C3, C4 are in the series connection, each of the switch groups 61, 62, 63 is turned off. When the capacitors C1, C2, C3, C4 are in the series connection, the switch group 62 is turned on, and when the capacitors C1, C2, C3, C4 are in the parallel connection, the switch group 62 is turned off. The switch 80 corresponds to the output switching unit 8 of FIG. 20.

The series-and-parallel switching control unit 5B′ are similar to the series-and-parallel switching control unit 5 for switching the two capacitors as illustrated in FIG. 20. The output current detection unit 13 and the series recovery control unit 14 are similar to FIG. 22. When multiple capacitors are cascode-connected in series in multiple stages as illustrated in FIG. 18, the series-and-parallel switching control unit 5W includes a master-and-slave switching circuit 55 for switching the master-side and the slave-side.

With the master-and-slave switching circuit 55 being provided, multiple ICs are configured to be cascode-connected as slave ICs, and the output voltage Vout output of each of the multiple ICs is configured to be connected to the four-series-and-parallel switching master IC, so that the multi-stage connection can be achieved.

When the multi-stage connection is made in this manner, the multi-stage connection is controlled by controlling the multiple ICs according to the master/slave scheme. Accordingly, capacitors can be connected in a larger number of stages, and a still higher efficiency can be achieved.

### Second Modified Embodiment

Subsequently, a power storage system 100e according to the second modified embodiment is explained.

A load driving power storage apparatus capable of storing and supplying electric power and a power storage apparatus 1 may be connected in the power storage system 100 according to the second embodiment explained above. In this case, when the electric power stored in the power storage apparatus 1 is stored to the load driving power storage apparatus, the power storage apparatus 1 maintains the multiple capacitors connected in parallel until the voltage of the electric power stored in the load driving power storage apparatus attains the second voltage value or less. Therefore, the power storage apparatus 1 cannot switch the multiple capacitors to the series connection until the voltage of the electric power stored in the load driving power storage apparatus attains the second voltage value or less, a high power storage efficiency may not be attained.

In the power storage system 100, when the multiple capacitors are connected in series, the power cannot be supplied to the load circuit, and a high power storage efficiency may not be attained.

In contrast, in the second modified embodiment, the connection of the multiple power storage devices is switched from the parallel connection to the series connection, on the basis of the output current of the power storage unit including multiple power storage devices, like the second embodiment. For example, when the output current attains the first current value or less while multiple power storage devices are connected in parallel, the connection of the multiple power storage devices is switched from the parallel connection to the series connection. Even when the load driving power storage apparatus and the power storage apparatus 1 are connected, the multiple power storage devices connected in series can store power without waiting for the voltage of the electric power stored in the load driving power storage apparatus to attain the second voltage value or less, and the power storage efficiency can be improved. In addition, the power can be supplied to the load circuit while the multiple capacitors are connected in series, the power supply efficiency can be improved.

<Configuration Example of Power Storage System 100e>

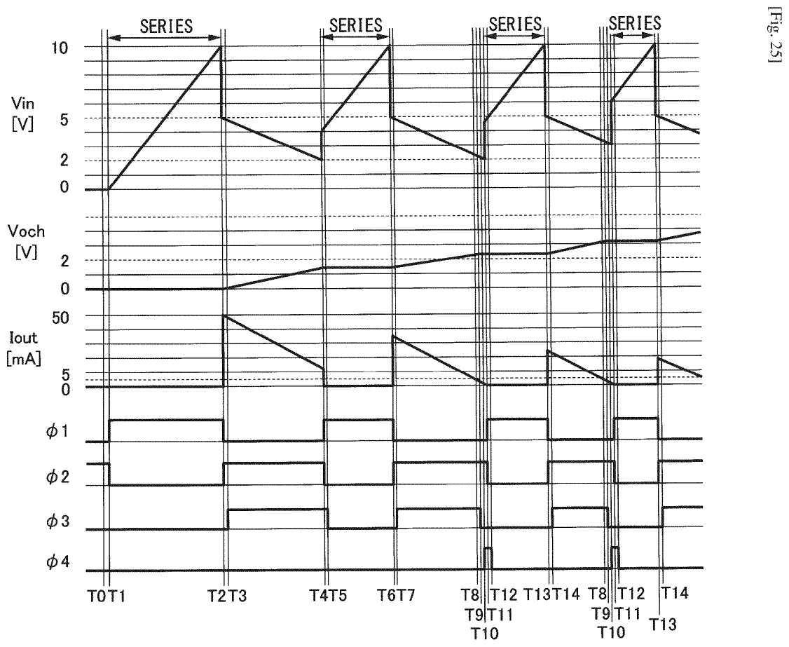

The configuration of the power storage system 100e is explained with reference to FIG. 24. FIG. 24 is a block diagram illustrating an example of configuration of the power storage system 100e according to the second modified embodiment of the second embodiment. As illustrated in FIG. 24, the power storage system 100e includes a power storage apparatus 1a and a load driving power storage apparatus 10. The configuration of the power storage apparatus 1a is similar to the configuration explained in the first embodiment.

In the power storage system 100e, the rectifying circuit 4 rectifies the electric power generated by the power generation device 2, and the capacitors C1, C2 connected in series in the power storage unit 7 store the electric power. Thereafter, while the capacitors C1, C2 are connected in parallel, i.e., in the ON state, the power storage apparatus 1a supplies electric power in parallel to both of the load driving power storage apparatus 10 and the load circuit 3.

The power storage apparatus 1a supplies the electric power stored in the power storage unit 7 to not only the load circuit 3 but also the load driving power storage apparatus 10.

The load driving power storage apparatus 10 includes electric double layer capacitors, lithium ion capacitors, and the like. Alternatively, the load driving power storage apparatus 10 may be constituted by various power storage devices such as lithium-ion batteries, lead-acid batteries, and the like. The load driving power storage apparatus 10 is an apparatus capable of storing electric power and supplying electric power. The load driving power storage apparatus 10 supplies the electric power for energizing the load circuit 3 to the load circuit 3.

The method of controlling the power supply to the load circuit 3 by the load driving power storage apparatus 10 is not particularly limited. For example, the control may be performed based on a control signal given from an external apparatus. Alternatively, for example, the load driving power storage apparatus 10 may be provided with a timer, and may perform control to supply the electric power to the load circuit 3 with a predetermined or given time interval based on the time measured by the timer.

In the manner as described above, the voltage of the electric power stored in the capacitors C1, C2 connected in series attains the first voltage value, the series-and-parallel switching unit 6 is activated to connect the capacitors C1, C2 in parallel. Then, the electric power stored in the capacitors C1, C2 is supplied to and stored in the load driving power storage apparatus 10, so that Vin=V_{C1}=V_{C2}=V_{och} is satisfied, and in addition, the electric power stored in the capacitors C1, C2 is supplied to the load circuit 3. In this case, V_{och} denotes the voltage of the electric power stored in the load driving power storage apparatus 10.

However, in a case where an activation voltage of the load circuit 3 is set, the electric power is supplied to only the load driving power storage apparatus 10 when the voltage of the stored electric power V_{och} is less than the activation voltage of the load circuit 3, and the electric power is supplied to both of the load driving power storage apparatus 10 and the load circuit 3 when the voltage of the stored electric power V_{och} is equal to or more than the activation voltage of the load circuit 3.

Thereafter, when the voltage of the electric power stored in the power storage unit 7 attains the second voltage value or less, the series-and-parallel switching unit 6 operates under the control of the series-and-parallel switching control unit 5 to switch the capacitors C1, C2 to the series connection. The capacitors C1, C2 connected in series store the electric power generated by the power generation device 2.

The output current detection unit 13 detects a current that is output from the power storage apparatus 1a to the load circuit 3 and the load driving power storage apparatus 10, and outputs the detection result to the series recovery control unit 14. When the output current detected by the output current detection unit 13 attains the first current value or less, the series recovery control unit 14 causes the series-and-parallel switching control unit 5 to switch the connection of the capacitors C1, C2 from the parallel connection to the series connection. The series-and-parallel switching unit 6 operates under the control of the series-and-parallel switching control unit 5 to switch the connection of the capacitors C1, C2 from the parallel connection to the series connection. The capacitors C1, C2 connected in series store the electric power generated by the power generation device 2.

The power storage apparatus 1a supplies the electric power to the load circuit 3 and the load driving power storage apparatus 10, and in any one of the case where the voltage of the electric power stored in the power storage unit 7 attains the first voltage or less and the case where the output current attains the first current value or less, the capacitors C1, C2 are switched to the series connection to store the electric power generated by the power generation device 2. Therefore, the capacitors C1, C2 can be charged efficiently.

Even when the power storage system 100e cannot supply electric power to the load circuit 3 because the power storage system 100e is storing electric power, the electric power stored in the load driving power storage apparatus 10 can be supplied to the load circuit 3. Therefore, the load circuit 3 can operate continuously.

<Operation of power Storage Apparatus 1a According to the Second Modified Embodiment>

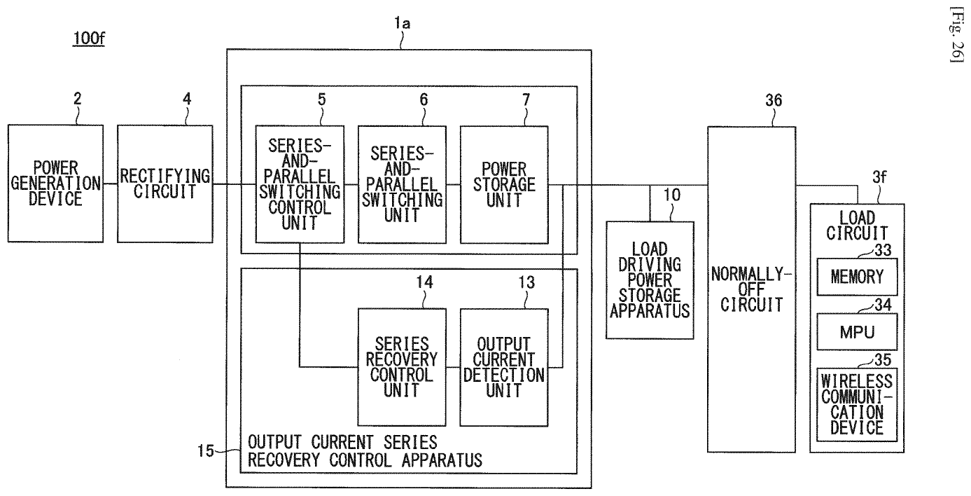

Subsequently, operation of the power storage apparatus 1a according to the second modified embodiment is explained with reference to FIG. 25. FIG. 25 is a timing chart illustrating an example of operation of the power storage apparatus 1a according to the second modified embodiment. The operation up to a time T1 is similar to the operation explained with reference to FIG. 22, and explanation thereabout is omitted.

When the input voltage Vin, i.e., the electric power from the power generation device 2, attains 10 V (i.e., the first voltage) while the capacitors C1, C2 are connected in series, the series-and-parallel selector switch control unit 50 operates to switch the control signal φ1 to the low level and switch the control signal γ2 to the high level at a time T2. In response, the series-and-parallel switching unit 6 is activated to turn off the switch Sw2 and turn on the switches Sw1, Sw3. As a result, the capacitors C1, C2 of the power storage unit 7 are connected in parallel. When the capacitors C1, C2 of the power storage unit 7 are switched from the series connection to the parallel connection, the voltage changes from (Vin=V_{C1}+V_{C2}) to (Vin=V_{C1}=V_{C2}). Accordingly, the voltage of the stored electric power (i.e., the input voltage Vin) decreases by half (10 V to 5 V), and at the same time, the electric power stored in the capacitors C1, C2 of the power storage unit 7 is supplied to the load circuit 3 and the load driving power storage apparatus 10, and accordingly the potential of the load driving power storage apparatus 10 increases.

At a time T2, the output current lout of the power storage apparatus 1a starts to flow, and at a time T3, the output signal φ3 of the output current detection unit 13 attains the high level, and the series recovery signal φ4 of the series recovery control unit 14 attains the low level. Also, the input voltage Vin decreases.

In this case, from the times T2 to T4, no electric power is assumed to be received from the power generation device 2. Also, no power is supplied to the load circuit 3.

When the input voltage Vin decreases, and attains 2 V at a time T4, the control signal φ1 attains the high level, and the control signal γ2 attains the low level. Accordingly, the switches Sw1, Sw3 are turned off, and the switch Sw2 is turned on. As a result, the capacitors C1, C2 of the power storage unit 7 are connected in series to store the electric power from the power generation device 2.

Also, at the time T4, the output current lout to the load circuit 3 and the load driving power storage apparatus 10 is stopped, and at a time T5, the output signal φ3 attains the low level, and the series recovery signal φ4 attains the low level.

When the input voltage Vin, i.e., the electric power from the power generation device 2 attains 10 V, series-and-parallel selector switch control unit 50B operates to switch the control signal φ1 to the low level and switch the control signal γ2 to the high level at a time T6. In response, the series-and-parallel switching unit 6 operates to turn off the switch Sw2 and turn on the switches Sw1, Sw3. As a result, the capacitors C1, C2 of the power storage unit 7 are connected in parallel. When the capacitors C1, C2 of the power storage unit 7 are switched from the series connection to the parallel connection, the voltage changes from (Vin=V_{C1}+V_{C2}) to (Vin=_{C1}=V_{C2}). Accordingly, the voltage of the stored electric power (i.e., the input voltage Vin) decreases by half (10 V to 5 V), and at the same time, the electric power stored in the capacitors C1, C2 of the power storage unit 7 is supplied to the load circuit 3 and the load driving power storage apparatus 10, and accordingly the potential of the load driving power storage apparatus 10 increases.

According to the increase in the potential of the voltage V_{och} of the load driving power storage apparatus 10, the input voltage Vin increases to 2 V or more at a time T8. Thereafter, the output current Tout of the power storage apparatus 1a decreases to 5 mA or less. At a time T9, the output signal φ3 of the output current detection unit 13 attains the low level, and at a time T10, the series recovery signal φ4 of the series recovery control unit 14 attains the high level.

Thereafter, at a time T11, the control signal φ1 attains the high level, and the control signal γ2 attains the low level. Accordingly, the switches Sw1, Sw3 are turned off, and the switch Sw2 is turned on. As a result, the capacitors C1, C2 are connected in series to store the electric power from the power generation device 2.

Thereafter, at a time T12, the series recovery signal φ4 of the series recovery control unit 14 attains the high level.

In this case, from the times T6 to T11, no electric power is assumed to be received from the power generation device 2. Also, the power supplied to the load circuit 3 is assumed to be less than 5 mA.

The operation explained above is performed continuously.

In the manner as described above, even when the load driving power storage apparatus and the power storage apparatus 1a are connected, the power storage apparatus 1a can store electric power in the multiple power storage devices connected in series without waiting for the voltage of the electric power stored in the load driving power storage apparatus to attain the second voltage value or less. Also, the multiple capacitors connected in series can supply electric power to the load circuit.

<Actions and Effects of Power Storage System 100e>

As hereinabove explained, in the second modified embodiment, even when the load driving power storage apparatus and the power storage apparatus 1 are connected, the multiple power storage devices connected in series can store electric power without waiting for the voltage of the electric power stored in the load driving power storage apparatus to attain the second voltage value or less, and the power storage efficiency can be improved. In addition, the multiple capacitors connected in series can supply electric power to the load circuit, and the power supply efficiency can be improved.

In the example explained above, the first current detection value of the output current detection unit 13 is set to 5 mA, but may be changed to any value. According to the current consumed by the load circuit 3, the capacitance values of the capacitors C1, C2 of the power storage unit 7, the first voltage value, the second voltage value, and the voltage of the electric power stored in the load driving power storage apparatus 10 may be adjusted to be set in an operation voltage range of the load circuit 3. Accordingly, the load circuit 3 can operate continuously without depending on the timing of power generation by the power generation device 2.

### Third Modified Embodiment

In the example as explained above, as the power supply control for supplying electric power to the load circuit 3 by the load driving power storage apparatus 10, the method based on a control signal from an external apparatus and the method based on time measurement with a timer have been explained, but the power supply control can be performed with a normally-off circuit.

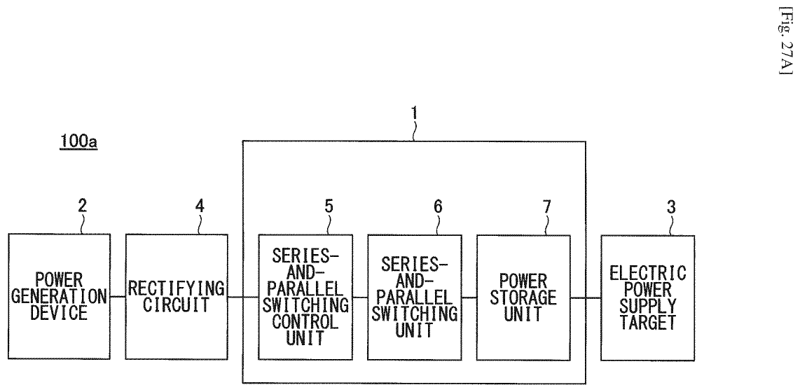

FIG. 26 is a block diagram illustrating an example of configuration of a power storage system 100f according to a third modified embodiment of the second embodiment, including such a normally-off circuit. As illustrated in FIG. 26, the power storage system 100f includes a load circuit 3f and a normally-off circuit 36. The load circuit 3f includes memory 33, an MPU (Micro Processing Unit) 34, and a wireless communication device 35. An example of the load circuit 3f includes an IoT device and the like.

The memory 33 stores various information such as various programs and data, measurement data acquired by an IoT device, images, and the like. The memory 33 is constituted by a storage device such as volatile or non-volatile semiconductor memory. It should be noted that the memory 33 includes ROM (Read Only Memory) and/or RAM (Random Access Memory).

The MPU 34 is constituted by a processor and the like, and controls operation of each unit and the entire operation of the load circuit 3.

The wireless communication device 35 is connected to another device or device and functions as an interface for transmitting and receiving information. The wireless communication device 35 may include a USB connector or the like.

The normally-off circuit 36 is an electric circuit that shuts off the power supply from the power storage apparatus 1a and the load driving power storage apparatus 10 to the load circuit 3f in normal circumstances, and causes the power storage apparatus 1a and the load driving power storage apparatus 10 to supply electric power to the load circuit 3f at any given timing when the load circuit 3f requires power. The normally-off circuit 36 is configured to include a MOSFET and the like.

With the configuration of the power storage system 100f, the supply of the electric power is shut off in normal circumstances, and the electric power is supplied at any given timing when the load circuit 3f requires power, so that the electric power consumption can be reduced. The power storage system 100f according to a third modified embodiment is particularly suitable for IoT devices and the like that often shut off the power supply in normal circumstances and perform data acquisition and data transmission only with a predetermined or given cycle or under a predetermined or given condition.

The embodiments also include a control apparatus. For example, the control apparatus is a control apparatus for controlling a power storage apparatus including a power storage unit including a plurality of power storage devices storing electric power, a series-and-parallel switching unit configured to switch connection of the plurality of power storage devices into a series connection or a parallel connection, and a series-and-parallel switching control unit configured to control the switching performed by the series-and-parallel switching unit, the control apparatus including a series recovery control unit configured to cause the power storage apparatus to switch the connection of the multiple power storage devices from the parallel connection to the series connection, on the basis of an output current of the power storage apparatus. According to such a control apparatus, effects similar to the effects of the power storage apparatus explained above can be obtained.

### Third Embodiment

With respect to the power supply circuit of PTL 1, scope of improvement is associated with a power storage efficiency or power supply efficiency of electric power with the improvement in the safety.

It is an object of the present embodiment to improve the power storage efficiency and the power supply efficiency of the electric power with the improvement in the safety. Also, a threshold voltage value for switching the connection of the multiple power storage devices from series connection to parallel connection is referred to as a series-to-parallel switching threshold voltage value, and a threshold voltage value for switching the connection of the multiple power storage devices from parallel connection to series connection is referred to as a parallel-to-series switching threshold voltage value.

In the following embodiments, a target to which electric power is supplied from a power storage apparatus even momentarily is referred to as an “electric power supply target”.

<Configuration Example of Power Storage Systems 100a and 100b>

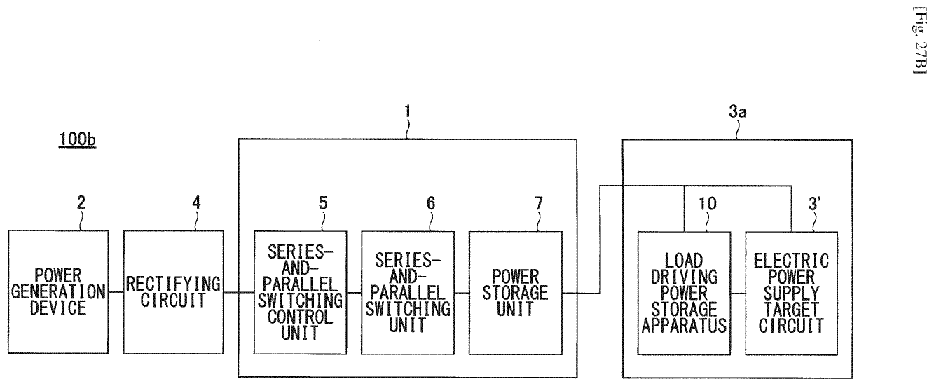

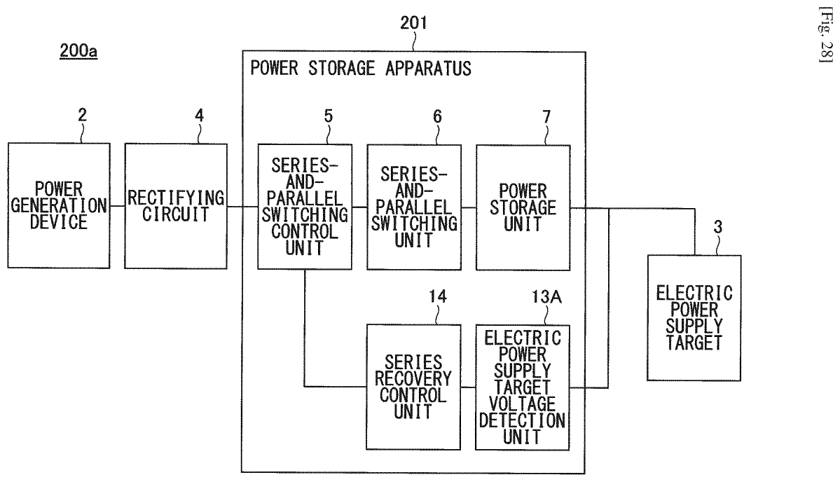

FIG. 27A is a block diagram illustrating an example of configuration of a power storage system 100a. FIG. 27B is a block diagram illustrating a configuration example of a power storage system 100b having a load driving power storage apparatus 10. The power storage systems 100a and 100b as illustrated in FIGS. 27A and 27B, respectively, are configured in a manner similar to the power storage system 100a according to the second embodiment explained above. Accordingly, corresponding constituent elements are denoted with the same reference numerals as the reference numerals of the power storage system 100a according to the second embodiment, and detailed explanation about the power storage systems 100a and 100b as illustrated in FIGS. 27A and 27B, respectively, is omitted here. Only the difference of the power storage systems 100a and 100b as illustrated in FIGS. 27A and 27B, respectively, is hereinafter explained. Electric power supply targets 3, 3′ as illustrated in FIG. 27A and FIG. 27B, respectively, correspond to the load circuit 3 according to the second embodiment.

As illustrated in FIG. 27B, the power storage system 100b includes a power storage apparatus 1 and an electric power supply target 3a. Also, the electric power supply target 3a includes a load driving power storage apparatus 10 and an electric power supply target circuit 3′.

In the power storage system 100b, the rectifying circuit 4 rectifies the electric power generated by the power generation device 2, and the capacitors C1, C2 connected in series in the power storage unit 7 store the electric power. Thereafter, when the voltage of the electric power stored in the power storage unit 7 attains the first voltage value, the connection of the capacitors C1, C2 is switched to the parallel connection. In the parallel connection state, the power storage unit 7 supplies electric power in parallel to both of the load driving power storage apparatus 10 and the electric power supply target circuit 3′.

The load driving power storage apparatus 10 includes electric double layer capacitors, lithium ion capacitors, and the like. Alternatively, the load driving power storage apparatus 10 may be constituted by various power storage devices such as lithium-ion batteries, lead-acid batteries, and the like. The load driving power storage apparatus 10 is an apparatus capable of storing electric power and supplying electric power. The load driving power storage apparatus 10 supplies the electric power for energizing the electric power supply target circuit 3′ to the electric power supply target circuit 3′.

The method of controlling the power supply to the electric power supply target circuit 3′ by the load driving power storage apparatus 10 is not particularly limited. For example, the control may be performed based on a control signal given from an external apparatus. Alternatively, for example, the load driving power storage apparatus 10 may be provided with a timer, and may perform control to supply the electric power to the electric power supply target circuit 3′ with a predetermined or given time interval based on the time measured by the timer.

Subsequently, a power storage system 200 according to the third embodiment is explained.

In this case, in the power storage system 100a (see FIG. 27A) explained above, the capacitors C1, C2 switched to the parallel connection for supplying electric power returns back to the series connection when the voltage of the stored electric power attains the second voltage value or less. Then, the capacitors C1, C2 connected in series start to be charged. Thereafter, when the voltage of the stored electric power attains the first voltage value, the capacitors C1, C2 are switched to the parallel connection, and the capacitors C1, C2 connected in parallel supply the electric power to the electric power supply target 3.

The power supply performance for supplying electric power to the electric power supply target 3 corresponds to the electric power stored in the capacitors C1, C2, and therefore, in the power storage system 100a, the first voltage value and the second voltage value are set in advance so that the timing of the series-and-parallel switching is determined by the amount of electric power stored to the power storage unit 7 and the amount of electric power consumed by the electric power supply target 3.

However, when the electric power consumption of the electric power supply target 3 is small, the capacitors C1, C2 cannot be switched to the series connection until the voltage of the stored electric power attains the second voltage value or less, and the capacitors C1, C2 store the electric connected in parallel continue to store electric power. Therefore, the power storage unit 7 continues to store electric power without returning back to the series connection, and the voltage of the stored electric power may increase. Due to the increase in the voltage of the stored electric power, the operation of the electric power supply target 3 may become unstable, and the electric power supply target 3 may be degraded.

Therefore, in the power storage system 200 according to the third embodiment, a parallel-to-series switching threshold voltage value is changed when the voltage supplied to the electric power supply target 3 or the voltage of the electric power stored in the power storage unit 7 attains a predetermined or given threshold voltage value or more. For example, the timing of charging in the series connection by the power generation device 2 is delayed by changing the second voltage value, which is set as the parallel-to-series switching threshold voltage value, to a fourth voltage value lower than the second voltage value.

Then, when the voltage supplied to the electric power supply target 3 attains the threshold voltage value or less, the power storage system 200 returns back to the series-and-parallel switching control in which the first voltage value is used as the series-to-parallel switching threshold voltage value and the second voltage value is used as the parallel-to-series switching threshold voltage value. Each of the first voltage value, the second voltage value, the fourth voltage value, and the threshold voltage value is determined in advance in accordance with the specification and the like of the consumption of electric power by the electric power supply target 3.

In the manner as described above, in accordance with the operation voltage range and the working voltage range of the electric power supply target 3, the voltage of the electric power stored in the power storage unit 7 and the voltage supplied to the electric power supply target 3 can be controlled to ensure safe operation and prevent degradation of the electric power supply target 3.

Hereinafter, the configuration and the operation of the power storage system 200 is explained in detail.

<Configuration Example of Power Storage System 200>

The configuration of the power storage system 200 is explained with reference to

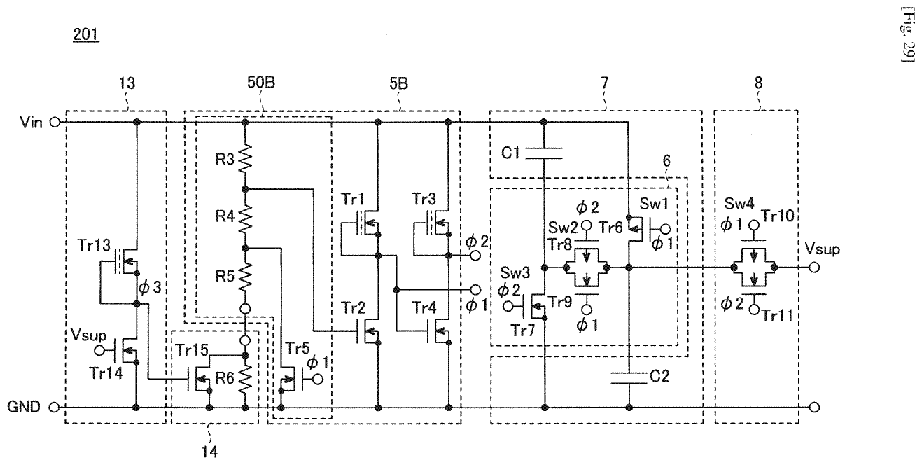

FIG. 28. FIG. 28 is a block diagram illustrating an example of configuration of the power storage system 200 according to the third embodiment.

As illustrated in FIG. 19, the power storage system 200 includes a power generation device 2, a rectifying circuit 4, a power storage apparatus 201, and an electric power supply target 3.

The rectifying circuit 4 rectifies the electric power generated by the power generation device 2, and the rectified electric power is input to the power storage apparatus 201. The power storage apparatus 201 stores the electric power received from the rectifying circuit 4 to the capacitors C1, C2 connected in series in the power storage unit 7. When the voltage of the electric power stored in the power storage unit 7 attains the first voltage value, the series-and-parallel switching control unit 5 activates the series-and-parallel switching unit 6 to switch the capacitors C1, C2 to the parallel connection. Thereafter, the capacitors C1, C2 connected in parallel supply the electric power to the electric power supply target 3.

Also, the power storage apparatus 201 includes an electric power supply target voltage detection unit 13A and a series recovery control unit 14, and can perform control for switching the connection of the capacitors C1, C2 from the parallel connection to the series connection.

The electric power supply target voltage detection unit 13A detects the voltage of the electric power supply target 3, and outputs the detection value to the series recovery control unit 14. When the detection value detected by the electric power supply target voltage detection unit 13A attains a threshold voltage value or more, the series recovery control unit 14 changes the parallel-to-series switching threshold voltage value from the second voltage value to the fourth voltage value.

When the voltage of the capacitors C1, C2 in parallel attains the fourth voltage value or less, the series-and-parallel switching control unit 5 activates the series-and-parallel switching unit 6 to switch the connection of the capacitors C1, C2 from the parallel connection to the series connection. The capacitors C1, C2 connected in series store the electric power generated by the power generation device 2.

<Configuration Example of Power Storage Apparatus 201>

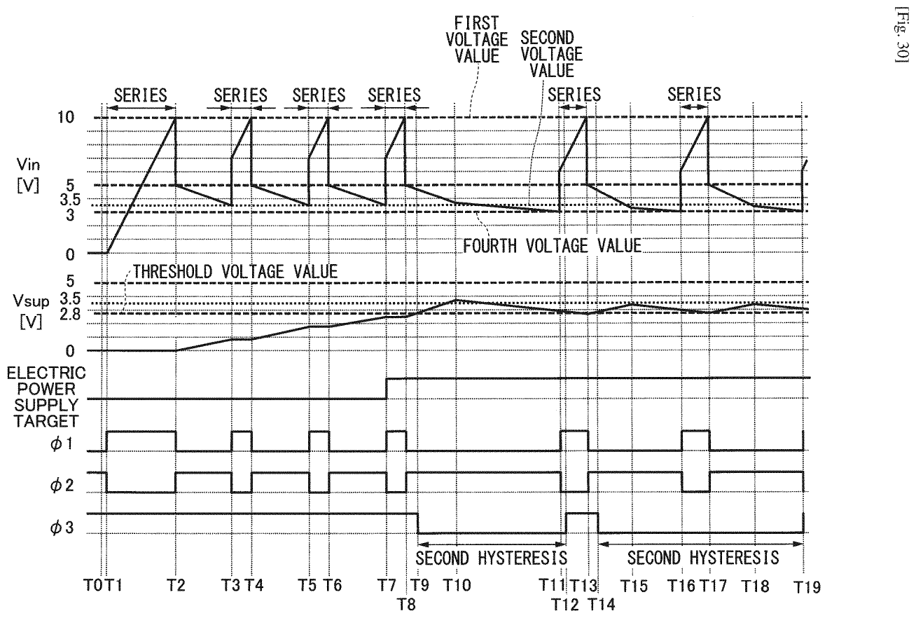

Subsequently, a configuration of the power storage apparatus 201 included in the power storage system 200 is explained with reference to FIG. 29. FIG. 29 is a circuit diagram illustrating an example of circuit configuration of the power storage apparatus 201 according to the third embodiment.

As illustrated in FIG. 29, the power storage apparatus 201 includes a series-and-parallel switching control unit 5B, a series-and-parallel switching unit 6, a power storage unit 7, an output switching unit 8, an electric power supply target voltage detection unit 13A, and a series recovery control unit 14. It should be noted that the power storage apparatus 201 may be configured as a single power storage IC that integrates the series-and-parallel switching control unit 5B, the series-and-parallel switching unit 6, the power storage unit 7, the output switching unit 8, the electric power supply target voltage detection unit 13A, and the series recovery control unit 14.

The electric power supply target voltage detection unit 13A includes a depletion transistor Tr13 constituting a current comparator for detecting a voltage Vsup supplied to the electric power supply target 3 (hereinafter referred to as a supplied voltage Vsup) and an N-ch transistor Tr14.

In this case, a current flowing through the depletion transistor Tr13 is a constant current Itr13. The N-ch transistor Tr14 and the depletion transistor Tr13 operate as a current comparator, and therefore, when the current Itr14 of the N-ch transistor Tr14 is larger than the constant current Itr13, the output signal φ3 attains the low level. In contrast, when the current Itr14 is smaller than the constant current Itr13, the output signal φ3 attains the high level. According to a transistor size ratio between the N-ch transistor Tr14 and the depletion transistor Tr13, the threshold voltage value can be set.

In the series recovery control unit 14, when the supplied voltage Vsup is equal to or more than the threshold voltage value, an N-ch transistor Tr15 is turned off. The N-ch transistor Tr15 is connected between a GND-side terminal of the resistor R5 in the series-and-parallel selector switch control unit 50B and a the GND terminal. When the N-ch transistor Tr15 is turned off, a voltage is applied across both terminals of a resistor R6 connected between the GND-side terminal of the resistor R5 in the series-and-parallel selector switch control unit 50B and the GND terminal.

When the N-ch transistor Tr5 is turned off while the capacitors C1, C2 are connected in parallel, the voltage applied to the gate of the N-ch transistor Tr2 is a divisional voltage obtained by multiplying the input voltage Vin by a resistance ratio of R4+R5+R6 to R3+R4+R5+R6. Accordingly, the parallel-to-series switching threshold voltage value decreases from the second voltage value to the fourth voltage value less than the second voltage value.

Then, when the input voltage Vin attains the fourth voltage value or less, the control signal φ1 of the high level and the control signal γ2 of the low level for connecting the capacitors C1, C2 in series are output to the series-and-parallel switching control unit 5B.

The series-and-parallel switching unit 6 includes a P-ch transistor Tr6, an N-ch transistor Tr7, and analog switches Tr8 and Tr9.

In the switch Sw4 of the output switching unit 8, the gate of the P-ch transistor Tr10 receives the control signal φ1, and the gate of the N-ch transistor Tr11 receives the control signal γ2. Therefore, when the control signal φ1 is at the low level and the control signal γ2 is at the high level, i.e., when electric power is supplied to the electric power supply target 3, the switch Sw4 is turned on.

When the supplied voltage Vsup is less than the threshold voltage value, the N-ch transistor Tr14 is turned off, and the output signal φ3 attains the high level. Accordingly, the N-ch transistor Tr15 is turned on, so that the voltage applied to the gate of the N-ch transistor Tr2 becomes the divisional voltage obtained by multiplying the input voltage Vin by the resistance ratio of R4+R5 to R3+R4+R5, and the parallel-to-series switching threshold voltage value is changed from the fourth voltage value to the second voltage value.

In the manner as described above, when the supplied voltage Vsup increases beyond the threshold voltage value, the parallel-to-series switching threshold voltage value is changed to a smaller value so as to reduce the charging in the series state. The amount of electric power stored to the power storage unit 7 and the amount of electric power consumed by the electric power supply target 3 are controlled by monitoring the supplied voltage Vsup, so that the supplied voltage Vsup falls within the operation voltage range of the electric power supply target 3 and/or the working voltage range based on safety and degradation.

<Example of Operation of Power Storage Apparatus 201>

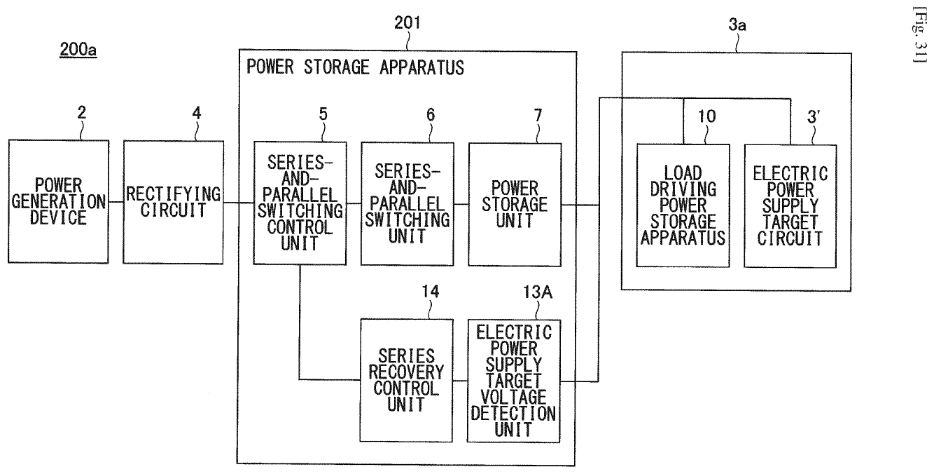

Subsequently, operation of the power storage apparatus 201 (see FIG. 29) is explained with reference to FIG. 30. FIG. 30 is a timing chart illustrating an example of operation of the power storage apparatus 201 of FIG. 29.

The rectifying circuit 4 rectifies the electric power generated by the power generation device 2, and the rectified electric power is input to the power storage apparatus 201.

At a time T0, the capacitors C1, C2 are not in a state for storing electric power.

At a time T1, the rectified electric power starts to be input into the power storage apparatus 201. Because the series-and-parallel switching control unit 5B has the high impedance configuration, the electric power that is output from the power generation device 2 with a high impedance activates and causes the series-and-parallel switching control unit 5B to generate the control signal φ1 and φ2.

When the power starts to be stored, the control signal φ1 attains the high level, and the control signal γ2 attains the low level. Accordingly, the series-and-parallel switching unit 6 is activated to turn off the switches Sw1, Sw3 and turn on the switch Sw2. As a result, the capacitors C1, C2 of the power storage unit 7 are connected in series. Also, the output signal φ3 from the electric power supply target voltage detection unit 13A attains the high level, and accordingly, the N-ch transistor Tr15 in the series recovery control unit 14 is turned on.

When the input voltage Vin, i.e., the electric power from the power generation device 2, attains 10 V (i.e., the first voltage) while the capacitors C1, C2 are connected in series, the series-and-parallel selector switch control unit 50B operates to switch the control signal φ1 to the low level and switch the control signal γ2 to the high level at a time T2.

In response, the series-and-parallel switching unit 6 is activated to turn off the switch Sw2 and turn on the switches Sw1, Sw3. As a result, the capacitors C1, C2 of the power storage unit 7 are connected in parallel. When the capacitors C1, C2 of the power storage unit 7 are switched from the series connection to the parallel connection, the voltage changes from (Vin=V_{C1}+V_{C2}) to (Vin=V_{C1}=V_{C2}). Accordingly, the voltage of the stored electric power (i.e., the input voltage Vin) decreases by half (10 V to 5 V), and at the same time, the electric power stored in the capacitors C1, C2 of the power storage unit 7 is supplied to the electric power supply target 3, and accordingly the voltage of the electric power supply target 3 increases.

Thereafter, at a time T2, the power storage apparatus 201 starts to supply the electric power to the electric power supply target 3. Then, at a time T3, when the input voltage Vin attains 3.5 V (an example of second voltage value) or less, the output signal φ3 attains a high level. The N-ch transistor Tr15 in the series recovery control unit 14 is kept turned on. Accordingly, the control signal φ1 is at the high level, and the control signal γ2 is at the low level. When the switches Sw1, Sw3 are turned off, and the switch Sw2 is turned on, the capacitors C1, C2 are connected in series, and the capacitors C1, C2 store the electric power generated by the power generation device 2.

From the times T2 to T3, no electric power is assumed to be received from the power generation device 2.

When the input voltage Vin, i.e., the electric power from the power generation device 2, attains 10 V (i.e., the first voltage value) while the capacitors C1, C2 are connected in series, the series-and-parallel selector switch control unit 50B operates to switch the control signal φ1 to the low level and the control signal γ2 to the high level at a time T4. In response, the series-and-parallel switching unit 6 operates to turn off the switch Sw2 and turn on the switches Sw1, Sw3. As a result, the capacitors C1, C2 are connected in parallel.

When the capacitors C1, C2 are switched from the series connection to the parallel connection, the voltage changes from (Vin=V_{C1}+V_{C2}) to (Vin=_{C1}=V_{C2}). Accordingly, the voltage of the stored electric power (i.e., the input voltage Vin) decreases by half (10 V to 5 V), and at the same time, the electric power stored in the capacitors C1, C2 of the power storage unit 7 is supplied to the electric power supply target 3, and accordingly, the voltage of the electric power supply target 3 increases.

When the voltage of the electric power supply target 3 increases, and the supplied voltage Vsup reaches 2.8 V (an example of the threshold voltage value) at a time T9, the output signal φ3 of the electric power supply target voltage detection unit 13A attains the low level, and the N-ch transistor Tr5 of the series recovery control unit 14 is turned off. The voltage applied to the gate of the N-ch transistor Tr2 becomes the divisional voltage obtained by multiplying the input voltage Vin by the resistance ratio of R4+R5+R6 to R3+R4+R5+R6, and the parallel-to-series switching threshold voltage value is changed from 3.5 V to 3.0 V (an example of the fourth voltage value).

Thereafter, at a time T11, because the supplied voltage Vsup is 2.8 V or more, the output signal φ3 attains the high level when the input voltage Vin becomes 3.0 V or less. The N-ch transistor Tr15 of the series recovery control unit 14 is kept turned on. Accordingly, the control signal φ1 attains the high level, and the control signal γ2 attains the low level. As a result, the switches Sw1, Sw3 are turned off, and the switch Sw2 is turned on. Therefore, the capacitors C1, C2 are connected in series, and the capacitors C1, C2 store the electric power generated by the power generation device 2.

In the manner as described above, the power storage system 200 can control the supplied voltage Vsup according to the detection value detected by the electric power supply target voltage detection unit 13A.

<Actions and Effects of Power Storage System 200>

As hereinabove explained, in the third embodiment, when the supplied voltage Vsup increases beyond the threshold voltage value, the parallel-to-series switching threshold voltage value is changed to a lower value so as to reduce the charging in the series state. By controlling the electric power received from the power generation device 2 in accordance with the supplied voltage Vsup, the power storage system 200 can operate within the operation voltage range of the electric power supply target 3 and/or the working voltage range based on safety and degradation. In addition, even when the supplied voltage Vsup decreases, the electric power received from the power generation device 2 can be controlled, and therefore, by efficiently making use of the electric power generated by the power generation device 2, the electric power supply target 3 can be operated safely, and the degradation of the electric power supply target 3 can be prevented.

The third embodiment is particularly suitable for storing and supplying electric power generated by a low-frequency power generation device such as power generation rubber, but the third embodiment is not limited thereto. The third embodiment can also be applied to storing and supplying of electric power generated by a high-frequency power generation device such as energy harvesting.

The power storage system 200 and the power storage apparatus 201 according to the third embodiment can be changed in various manners. Hereinafter, mainly, difference of various modified embodiments from the power storage system 200 or the power storage apparatus 201 is explained.

### First Modified Embodiment

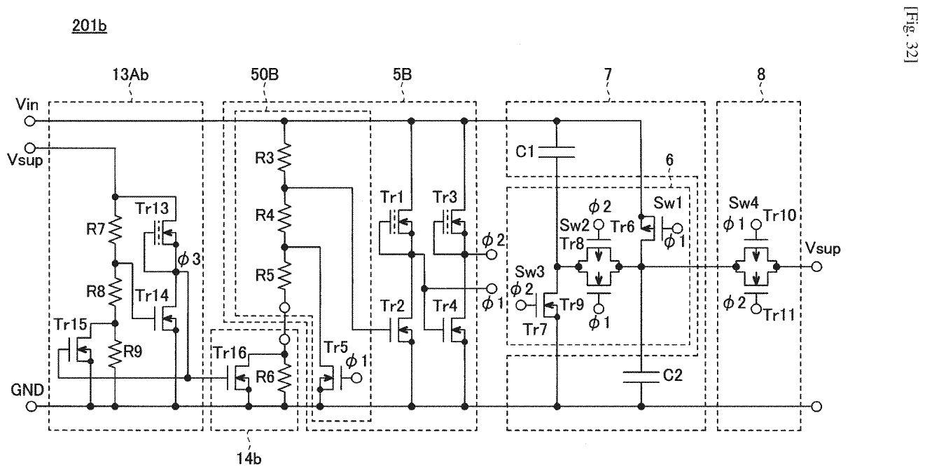

First, a power storage system 200a according to a first modified embodiment of the third embodiment is explained with reference to FIG. 31. FIG. 31 is a block diagram illustrating an example of configuration of the power storage system 200a according to the first modified embodiment of the third embodiment. As illustrated in FIG. 31, the power storage system 200a has an electric power supply target 3a including a load driving power storage apparatus 10.

In the power storage system 200a, the rectifying circuit 4 rectifies the electric power generated by the power generation device 2, and the capacitors C1, C2 connected in series in the power storage unit 7 store the rectified electric power. Thereafter, when the voltage of the stored electric power attains the first voltage value, the capacitors C1, C2 are switched to the parallel connection. Accordingly, the capacitors C1, C2 connected in parallel supply electric power in parallel to both of a load driving power storage apparatus 10 included in the electric power supply target 3a and an electric power supply target circuit 3′.

The load driving power storage apparatus 10 includes electric double layer capacitors, lithium ion capacitors, and the like. Alternatively, the load driving power storage apparatus 10 may be constituted by various power storage devices such as lithium-ion batteries, lead-acid batteries, and the like. The load driving power storage apparatus 10 is an apparatus capable of storing electric power and supplying electric power. The load driving power storage apparatus 10 supplies the electric power for energizing the electric power supply target circuit 3′ to the electric power supply target circuit 3′.

The method of controlling the power supply to the electric power supply target circuit 3′ by the load driving power storage apparatus 10 is not particularly limited. For example, the control may be performed based on a control signal given from an external apparatus. Alternatively, for example, the load driving power storage apparatus 10 may be provided with a timer, and may perform control to supply the electric power to the electric power supply target circuit 3′ with a predetermined or given time interval based on the time measured by the timer.

As described above, when the voltage of the electric power stored in the capacitors C1, C2 connected in series attains the first voltage value, the series-and-parallel switching unit 6 is activated to connect the capacitors C1, C2 in parallel. Then, the electric power stored in the capacitors C1, C2 is supplied to and stored in the load driving power storage apparatus 10, so that Vin=V_{C1}=V_{C2}=V_{och} is satisfied, and in addition, the electric power stored in the capacitors C1, C2 is supplied to the electric power supply target circuit 3′. In this case, V_{och} denotes the voltage of the electric power stored in the load driving power storage apparatus 10.

However, in a case where an activation voltage of the electric power supply target circuit 3′ is set, the electric power is supplied to only the load driving power storage apparatus 10 when the voltage of the stored electric power V_{och} is less than the activation voltage of the electric power supply target circuit 3′, and the electric power is supplied to both of the load driving power storage apparatus 10 and the electric power supply target circuit 3′ when the voltage of the stored electric power V_{och} is equal to or more than the activation voltage of the electric power supply target circuit 3′.

Thereafter, when the voltage of the electric power stored in the power storage unit 7 attains the second voltage value or less, the series-and-parallel switching unit 6 operates under the control of the series-and-parallel switching control unit 5 to switch the capacitors C1, C2 to the series connection. The capacitors C1, C2 connected in series store the electric power generated by the power generation device 2.

The power storage apparatus 201 supplies the electric power to the electric power supply target circuit 3′ and the load driving power storage apparatus 10, and when the voltage of the electric power stored in the power storage unit 7 attains the second voltage or less, the capacitors C1, C2 are switched to the series connection to store the electric power generated by the power generation device 2. Therefore, the capacitors C1, C2 can be charged efficiently.

Even when the power storage system 200a cannot supply electric power to the electric power supply target circuit 3′ because the power storage system 200a is storing electric power, the electric power stored in the load driving power storage apparatus 10 can be supplied to the electric power supply target circuit 3′. Therefore, the electric power supply target circuit 3′ can operate continuously.

In addition, by detecting the supplied voltage Vsup supplied to the electric power supply target 3a, the supplied voltage Vsup can be controlled within the operation voltage range of the electric power supply target 3a and/or the working voltage range based on safety and degradation.

### Second Modified Embodiment

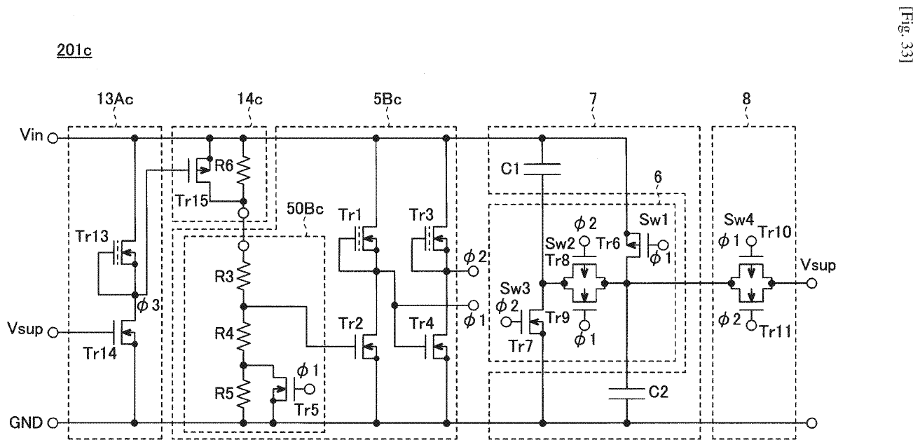

FIG. 32 is a circuit diagram illustrating an example of circuit configuration of a power storage apparatus 201b according to the second modified embodiment of the third embodiment. As illustrated in FIG. 32, the power storage apparatus 201b includes an electric power supply target voltage detection unit 13Ab.

The electric power supply target voltage detection unit 13Ab includes a stabilized circuit for preventing the operation of the power storage apparatus 201b from becoming unstable due to noises occurring in the electric power supply target 3 and/or noises occurring in the power generation device 2 when the supplied voltage Vsup is detected. With the electric power supply target voltage detection unit 13Ab, the operation of the power storage apparatus 201b can be stabilized. The configuration and the operation other than the above are similar to the power storage apparatus 201, and therefore, redundant explanation thereabout is omitted.

### Third Modified Embodiment

<Configuration Example>

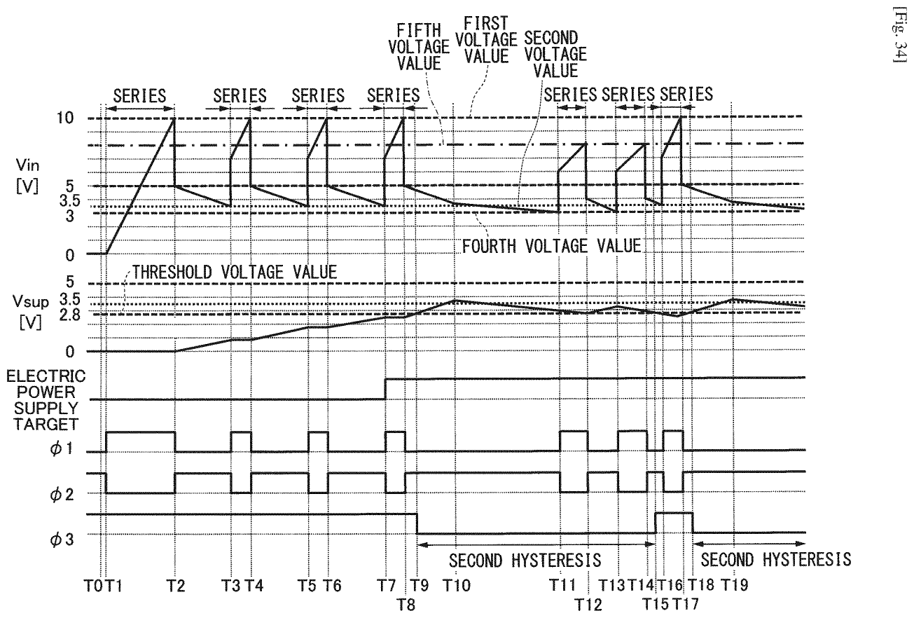

FIG. 33 is a circuit diagram illustrating an example of circuit configuration of the power storage apparatus 201c according to the third modified embodiment of the third embodiment. As illustrated in FIG. 33, the power storage apparatus 201c includes an electric power supply target voltage detection unit 13Ac and a series-and-parallel switching control unit 5Bc.

The electric power supply target voltage detection unit 13Ac includes a depletion transistor Tr13 constituting a current comparator for detecting the supplied voltage Vsup and an N-ch transistor Tr14. In this case, a current flowing through the depletion transistor Tr13 is a constant current Itr13. The N-ch transistor Tr14 and the depletion transistor Tr13 operate as a current comparator, and therefore, when the current Itr14 of the N-ch transistor Tr14 is larger than the constant current Itr13, the output signal φ3 attains the low level. In contrast, when the current Itr14 is smaller than the constant current Itr13, the output signal φ3 attains the high level. According to a transistor size ratio between the N-ch transistor Tr14 and the depletion transistor Tr13, the threshold voltage value can be set.

In the series recovery control unit 14c, when the supplied voltage Vsup is equal to or more than the threshold voltage value, a P-ch transistor Tr15 is turned on. The P-ch transistor Tr15 is connected between a Vin-side terminal of the resistor R3 of the series-and-parallel selector switch control unit 50Bc and a Vin terminal. Then, with the capacitors C1, C2 being connected in parallel, the N-ch transistor Tr5 is turned off. Accordingly, the voltage applied to the gate of the N-ch transistor Tr2 becomes the divisional voltage obtained by multiplying the input voltage Vin by the resistance ratio of R4+R5 to R3+R4+R5, and the parallel-to-series switching threshold voltage value is decreases and changed from the second voltage value to the fourth voltage value less than the second voltage value.

Then, when the input voltage Vin becomes the fourth voltage value or less, the control signal φ1 of the high level and the control signal γ2 of the low level for connecting the capacitors C1, C2 in series are output from the series-and-parallel switching control unit 5Bc.

Also, even when the capacitors C1, C2 are charged with the supplied voltage Vsup being the threshold voltage value or more while the capacitors C1, C2 are connected in series, the voltage applied to the gate of the N-ch transistor Tr2 becomes the divisional voltage obtained by multiplying the input voltage Vin by the resistance ratio of R4+R5 to R3+R4+R5, and the series-to-parallel switching threshold voltage value decreases and changed from the first voltage value to a fifth voltage value less than the first voltage value.

When the supplied voltage Vsup is less than the threshold voltage value, the N-ch transistor Tr14 is turned off, the output signal φ3 attains the high level, and the P-ch transistor Tr15 is turned off. The voltage applied to the gate of the N-ch transistor Tr2 becomes a divisional voltage obtained by multiplying the input voltage Vin by a resistance ratio of R4+R5 to R3+R6+R4+R5. The recovery voltage from the parallel connection to the series connection is changed from the fourth voltage value to the second voltage value. The recovery voltage from the series connection to the parallel connection is changed from the fifth voltage value to the first voltage value.

<Example of Operation>

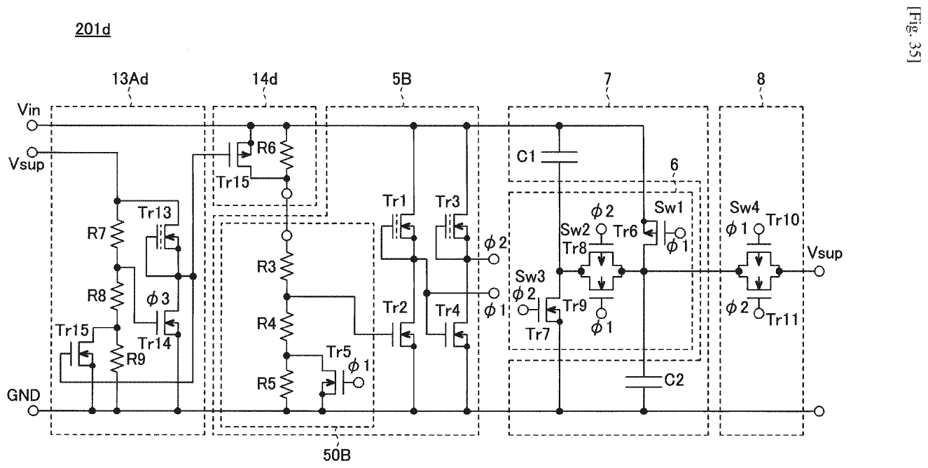

Subsequently, operation of the power storage apparatus 201c (see FIG. 33) is explained with reference to FIG. 34.

FIG. 34 is a timing chart illustrating an example of operation of the power storage apparatus 201c of FIG. 33. FIG. 34 illustrates an example of operation in a case where the power storage apparatus 201c is applied to the power storage system 200a in which the load driving power storage apparatus 10 is included in the electric power supply target 3a.

The rectifying circuit 4 rectifies the electric power generated by the power generation device 2, and the rectified electric power is input to the power storage apparatus 201c.

At a time T0, the capacitors C1, C2 are in a state not storing electric power.

At a time T1, the rectified electric power starts to be input into the power storage apparatus 201c. Because the series-and-parallel switching control unit 5B has the high impedance configuration, the electric power that is output from the power generation device 2 with a high impedance activates and causes the series-and-parallel switching control unit 5B to generate the control signal φ1 and φ2.

When the power starts to be stored, the control signal φ1 attains the high level, and the control signal γ2 attains the low level. Accordingly, the series-and-parallel switching unit 6 is activated to turn off the switches Sw1, Sw3 and turn on the switch Sw2. As a result, the capacitors C1, C2 of the power storage unit 7 are connected in series. Also, the output signal φ3 from the electric power supply target voltage detection unit 13A attains the high level, and accordingly, the N-ch transistor Tr15 in the series recovery control unit 14 is turned on.

When the input voltage Vin, i.e., the electric power from the power generation device 2, attains 10 V (i.e., the first voltage) while the capacitors C1, C2 are connected in series, the series-and-parallel selector switch control unit 5Bc operates to switch the control signal φ1 to the low level and switch the control signal γ2 to the high level at a time T2.

In response, the series-and-parallel switching unit 6 is activated to turn off the switch Sw2 and turn on the switches Sw1, Sw3. As a result, the capacitors C1, C2 of the power storage unit 7 are connected in parallel. When the capacitors C1, C2 of the power storage unit 7 are switched from the series connection to the parallel connection, the voltage changes from (Vin=V_{C1}+V_{C2}) to (Vin=V_{C1}=V_{C2}). Accordingly, the voltage of the stored electric power (i.e., the input voltage Vin) decreases by half (10 V to 5 V), and at the same time, the electric power stored in the capacitors C1, C2 of the power storage unit 7 is supplied to the electric power supply target 3a, and accordingly the voltage of the electric power supply target 3a increases.

Thereafter, at a time T2, the power storage apparatus 201c starts to supply the electric power to the electric power supply target 3a. Then, at a time T3, when the input voltage Vin attains 3.5 V (an example of second voltage value) or less, the output signal φ3 attains a high level. The N-ch transistor Tr15 in the series recovery control unit 14 is kept turned off. Accordingly, the control signal φ1 is at the high level, and the control signal γ2 is at the low level. When the switches Sw1, Sw3 are turned off, and the switch Sw2 is turned on, the capacitors C1, C2 are connected in series, and the capacitors C1, C2 store the electric power generated by the power generation device 2.

From the times T2 to T3, no electric power is assumed to be received from the power generation device 2.

When the input voltage Vin, i.e., the electric power from the power generation device 2, attains 10 V (i.e., the first voltage value) while the capacitors C1, C2 are connected in series, the series-and-parallel selector switch control unit 5Bc operates to switch the control signal φ1 to the low level and the control signal γ2 to the high level at a time T4. In response, the series-and-parallel switching unit 6 operates to turn off the switch Sw2 and turn on the switches Sw1, Sw3. As a result, the capacitors C1, C2 are connected in parallel.

When the capacitors C1, C2 are switched from the series connection to the parallel connection, the voltage changes from (Vin=V_{C1}+V_{C2}) to (Vin=_{C1}=V_{C2}). Accordingly, the voltage of the stored electric power (i.e., the input voltage Vin) decreases by half (10 V to 5 V), and at the same time, the electric power stored in the capacitors C1, C2 of the power storage unit 7 is supplied to the electric power supply target 3a, and accordingly, the voltage of the electric power supply target 3a increases.

When the voltage of the electric power supply target 3a increases, and the supplied voltage Vsup reaches 2.8 V (an example of the threshold voltage value) at a time T9, the output signal φ3 of the electric power supply target voltage detection unit 13A attains the low level, the N-ch transistor Tr5 of the series recovery control unit 14 is turned on. The voltage applied to the gate of the N-ch transistor Tr2 becomes the divisional voltage obtained by multiplying the input voltage Vin by the resistance ratio of R4+R5 to R3+R4+R5, and the parallel-to-series switching threshold voltage value is changed from 3.5 V (an example of the second voltage value) to 3.0 V (an example of the fourth voltage value). Because the divisional voltage obtained by multiplying the input voltage Vin by the resistance ratio of R4+R5 to R3+R4+R5 is maintained, the series-to-parallel switching threshold voltage value is switched from the first voltage value to 8 V (an example of the fifth voltage value) lower than 10 V (an example of the first voltage value).

Thereafter, at a time T11, because the supplied voltage Vsup is the threshold voltage value or more, the output signal φ3 attains the low level when the input voltage Vin becomes 3.0 V or less. The N-ch transistor Tr15 of the series recovery control unit 14 is kept turned on. Accordingly, the control signal φ1 attains the high level, and the control signal γ2 attains the low level. As a result, the switches Sw1, Sw3 are turned off, and the switch Sw2 is turned on. Therefore, the capacitors C1, C2 are connected in series, and the capacitors C1, C2 store the electric power generated by the power generation device 2.

When the input voltage Vin attains 8 V while the capacitors C1, C2 are connected in series, the series-and-parallel selector switch control unit 50Bc operates to switch the control signal φ1 to the low level and switch the control signal γ2 to the high level at a time T12. In response, the series-and-parallel switching unit 6 operates to turn off the switch Sw2 and turn on the switches Sw1, Sw3. As a result, the capacitors C1, C2 are connected in parallel.

When the capacitors C1, C2 of the power storage unit 7 are switched from the series connection to the parallel connection, the voltage changes from (Vin=V_{C1}+V_{C2}) to (Vin=V_{C1}=V_{C2}). Accordingly, the voltage of the stored electric power (i.e., the input voltage Vin) decreases by half (8 V to 4 V), and at the same time, the electric power stored in the capacitors C1, C2 of the power storage unit 7 is supplied to the electric power supply target 3a, and accordingly the voltage of the electric power supply target 3a increases.

At this occasion, the series-to-parallel switching threshold voltage value is the same as the fifth voltage value. Therefore, the voltage (Vin=VC1=VC2) during parallel connection is low, and the power supply performance for supplying electric power to the load driving power storage apparatus 10 decreases.

From a time T9 to a time T15, as long as the supplied voltage Vsup is more than the threshold voltage value, the connection of the capacitors C1, C2 is switched from the parallel connection to the series connection when the input voltage Vin attains the fourth voltage value, and the connection of the capacitors C1, C2 is switched from the series connection to the parallel connection when the input voltage Vin attains the fifth voltage value or more.

When the supplied voltage Vsup attains the threshold voltage value or less at a time T15, the connection of the capacitors C1, C2 is switched from the parallel connection to the series connection when the input voltage Vin attains the second voltage value at a time T16.

Subsequently, at a time T17, the connection of the capacitors C1, C2 is switched from the series connection to the parallel connection when the input voltage Vin attains the fourth voltage value.

In the manner as described above, when the electric power supply target 3a including the load driving power storage apparatus 10 is connected, the power storage apparatus 201c can control the supplied voltage Vsup according to the detection value detected by the electric power supply target voltage detection unit 13Ac.

In the example explained above, the operation in the case where the power storage apparatus 201c is applied to the power storage system 200a in which the load driving power storage apparatus 10 is included in the electric power supply target 3a has been explained. However, the power storage apparatus 201c can also operate in a similar manner even when the electric power supply target 3a does not include the load driving power storage apparatus 10. Specifically, when electric power is continuously supplied from the power generation device 2 with the power storage apparatus 201c being in the parallel connection state to increase the voltage of the electric power stored in the power storage unit 7, and the supplied voltage Vsup from the power storage apparatus 201c attains 2.8 V or more, the supplied voltage Vsup can be controlled.

With the power storage apparatus 201c, a stabilized circuit may be provided to prevent the operation of the power storage apparatus from becoming unstable due to noises occurring in the electric power supply target 3a and/or noises occurring in the power generation device 2 when the supplied voltage Vsup is detected.

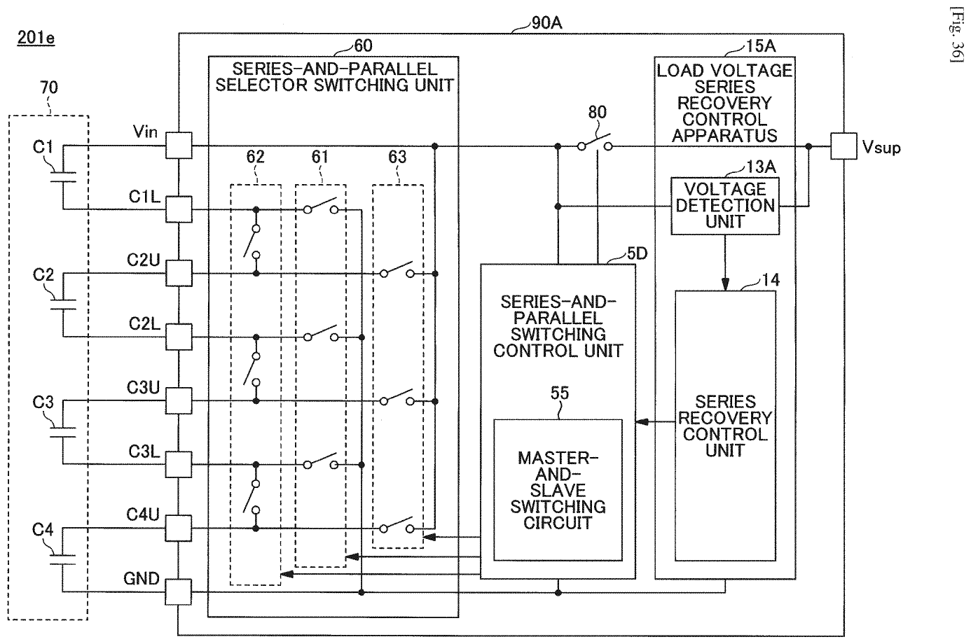

FIG. 35 is a circuit diagram illustrating an example of circuit configuration of a power storage apparatus 201d provided with a stabilized circuit. As illustrated in FIG. 35, the power storage apparatus 201d includes an electric power supply target voltage detection unit 13Ad.

The electric power supply target voltage detection unit 13Ad includes a stabilized circuit for preventing the operation of the power storage apparatus 201d from becoming unstable due to noises occurring in the electric power supply target 3a and/or noises occurring in the power generation device 2 when the supplied voltage Vsup is detected. With the electric power supply target voltage detection unit 13Ad, the operation of the power storage apparatus 201d can be stabilized. The configuration and the operation other than the above are similar to the power storage apparatus 201, and therefore, redundant explanation thereabout is omitted.

### Fourth Modified Embodiment

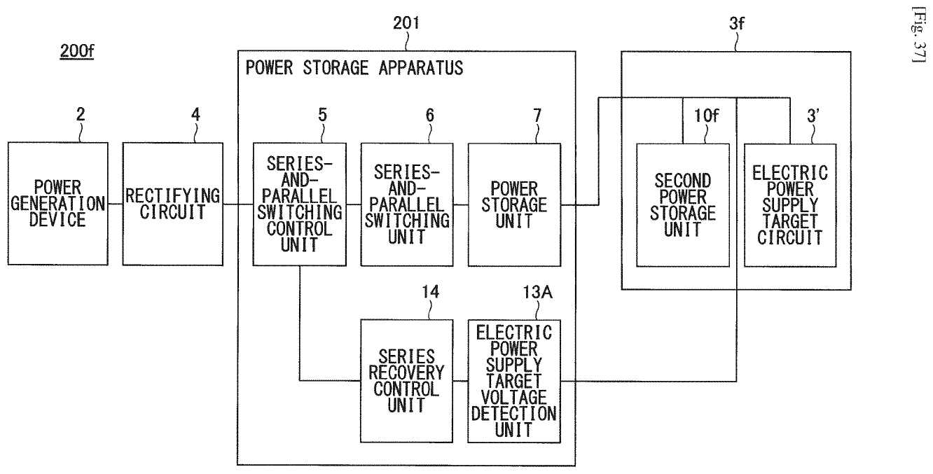

In the above example, the power storage apparatus including two capacitors C1, C2 has been explained, but the number of capacitors is not limited thereto. The number of capacitors may be further increased. FIG. 36 is a circuit diagram illustrating an example of circuit configuration of a power storage apparatus 201e with more capacitors. Specifically, FIG. 36 illustrates internal blocks of a power storage unit 70 including four capacitors and a four-series-and-parallel switching IC 90A for switching the connection of the four capacitors.

The series-and-parallel selector switching unit 60 corresponds to the series-and-parallel switching unit 6 of FIG. 29 and includes switch groups 61, 62, 62, 63. When the capacitors C1, C2, C3, C4 are in the parallel connection, each of the switch groups 61, 62, 63 is turned on, and when the capacitors C1, C2, C3, C4 are in the series connection, each of the switch groups 61, 62, 63 is turned off. When the capacitors C1, C2, C3, C4 are in the series connection, the switch group 62 is turned on, and when the capacitors C1, C2, C3, C4 are in the parallel connection, the switch group 62 is turned off. The switch 80 corresponds to the output switching unit 8 of FIG. 29.

A series-and-parallel switching control unit 5D corresponds to the series-and-parallel switching control unit 5B for switching two capacitors illustrated in FIG. 29. When multiple capacitors are cascode-connected in series in multiple stages as illustrated in FIG. 18, the series-and-parallel switching control unit 5D includes a master-and-slave switching circuit 55 for switching the master-side and the slave-side.

With the master-and-slave switching circuit 55 being provided, multiple ICs are configured to be cascode-connected as slave ICs, and the output voltage Vout output of each of the multiple ICs is configured to be connected to the four-series-and-parallel switching master IC so as to achieve the multi-stage connection.

In the manner as described above, when the multi-stage connection is made in this manner, the multi-stage connection is controlled by controlling the multiple ICs according to the master/slave scheme. Accordingly, capacitors can be connected in a larger number of stages, and a still higher efficiency can be achieved.

### Fifth Modified Embodiment

Subsequently, a power storage system 200f according to the fifth modified embodiment is explained.

<Configuration Example of Power Storage System 200f>

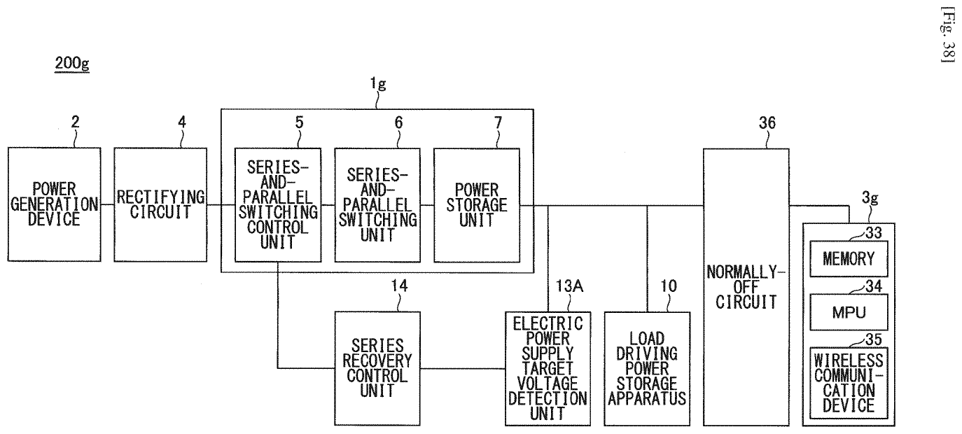

The configuration of the power storage system 200f is explained with reference to FIG. 37. FIG. 37 is a block diagram illustrating an example of configuration of the power storage system 200f according to a fifth modified embodiment of the third embodiment. As illustrated in FIG. 37, the power storage system 200f includes an electric power supply target 3f. The electric power supply target 3f includes a second power storage unit 10f.

The rectifying circuit 4 rectifies the electric power generated by the power generation device 2, and the power storage system 200f, the capacitors C1, C2 connected in series in the power storage unit 7 store the rectified electric power. Thereafter, when the voltage of the stored electric power attains the first voltage value, the capacitors C1, C2 are switched to the parallel connection. Accordingly, the capacitors C1, C2 connected in parallel supply electric power in parallel to both of a second power storage unit 10f and an electric power supply target circuit 3′.

The second power storage unit 10f includes electric double layer capacitors, lithium ion capacitors, and the like. Alternatively, the second power storage unit 10f may be constituted by various power storage devices such as lithium-ion batteries, lead-acid batteries, and the like. The second power storage unit 10f is an apparatus capable of storing electric power and supplying electric power. The second power storage unit 10f supplies the electric power for energizing the electric power supply target circuit 3′ to the electric power supply target circuit 3′.

The method of controlling the power supply to the electric power supply target circuit 3′ by the second power storage unit 10f is not particularly limited. For example, the control may be performed based on a control signal given from an external apparatus. Alternatively, for example, the second power storage unit 10f may be provided with a timer, and may perform control to supply the electric power to the electric power supply target circuit 3′ with a predetermined or given time interval based on the time measured by the timer.

As described above, when the voltage of the electric power stored in the capacitors C1, C2 connected in series attains the first voltage value, the series-and-parallel switching unit 6 is activated to connect the capacitors C1, C2 in parallel. Then, the electric power stored in the capacitors C1, C2 is supplied to and stored in the second power storage unit 10f, so that Vin=V_{C1}=V_{C2}=V_{och} is satisfied, and in addition, the electric power stored in the capacitors C1, C2 is supplied to the electric power supply target circuit 3′. In this case, V_{och} denotes the voltage of the electric power stored in the second power storage unit 10f .

However, in a case where an activation voltage of the electric power supply target circuit 3′ is set, the electric power is supplied to only the second power storage unit 10f when the voltage of the stored electric power V_{och} is less than the activation voltage of the electric power supply target circuit 3′, and the electric power is supplied to both of the second power storage unit 10f and the electric power supply target circuit 3′ when the voltage of the stored electric power V_{och} is equal to or more than the activation voltage of the electric power supply target circuit 3′.

Thereafter, when the voltage of the electric power stored in the power storage unit 7 attains the second voltage value or less, the series-and-parallel switching unit 6 operates under the control of the series-and-parallel switching control unit 5 to switch the capacitors C1, C2 to the series connection. The capacitors C1, C2 connected in series store the electric power generated by the power generation device 2.

The electric power supply target voltage detection unit 13A detects the voltage of the electric power supply target 3′ supplied from the power storage unit 7, and outputs the detection value to the series recovery control unit 14. When the detection value detected by the electric power supply target voltage detection unit 13A attains a threshold voltage value or more, the series recovery control unit 14 changes the parallel-to-series switching threshold voltage value from the second voltage value to the fourth voltage value with the series-and-parallel switching control unit 5. Thereafter, when the voltage of the capacitors C1, C2 in parallel attains the fourth voltage value or less, the series-and-parallel switching control unit 5 activates the series-and-parallel switching unit 6 to switch the connection of the capacitors C1, C2 from the parallel connection to the series connection. The capacitors C1, C2 connected in series store the electric power generated by the power generation device 2.

Even when the power storage system 200f cannot supply electric power to the electric power supply target circuit 3′ because the power storage system 200f is storing electric power, the electric power stored in the second power storage unit 10f can be supplied to the electric power supply target circuit 3′. Therefore, the electric power supply target circuit 3′ can operate continuously.

<Actions and Effects of Power Storage System 200f>

As hereinabove explained, in the fifth modified embodiment, even when the second power storage unit 10f and the electric power supply target circuit 3′ are connected, the power storage system 200f can operate within the operation voltage range of the second power storage unit 10f and the electric power supply target circuit 3′ and/or the working voltage range based on safety and degradation, by detecting the supplied voltage to the electric power supply target 3f.

In addition, the electric power can be supplied to the electric power supply target 3f while the multiple capacitors are connected in series, so that the power supply efficiency can be improved.

In the fifth modified embodiment, an example where the power storage apparatus 201 includes the two capacitors C1, C2 has been shown. However, the number of capacitors is not limited thereto. The number of capacitors may be further increased. When the number of capacitors is increased, the electric power supply target 3 can operate continuously without depending on the timing at which the power generation device 2 generates power.

### Sixth Modified Embodiment

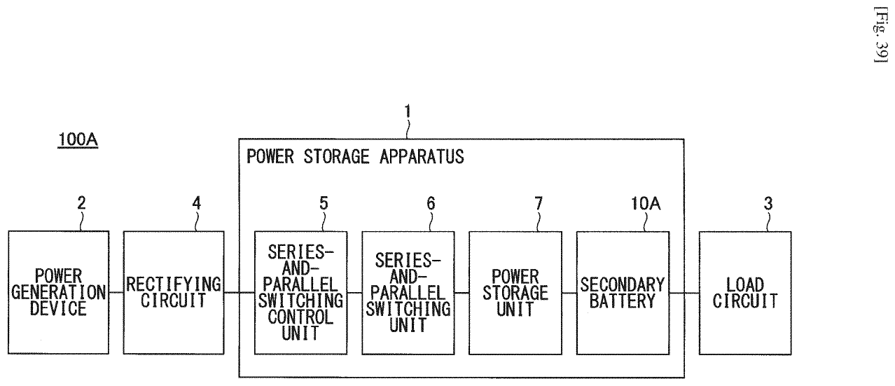

Subsequently, a power storage system 200g according to the sixth modified embodiment is explained with reference to FIG. 38.

FIG. 38 is a block diagram illustrating an example of configuration of a power storage system according to a sixth modified embodiment of the third embodiment. As illustrated in FIG. 38, the power storage system 200g includes an electric power supply target 3g and a normally-off circuit 36. The electric power supply target 3g includes memory 33, an MPU (Micro Processing Unit) 34, and a wireless communication device 35. An example of the electric power supply target 3g includes an IoT device and the like.

The memory 33 stores various information such as various programs and data, measurement data acquired by an IoT device, images, and the like. The memory 33 is constituted by a storage device such as volatile or non-volatile semiconductor memory. It should be noted that the memory 33 includes ROM (Read Only Memory) and/or RAM (Random Access Memory).

The MPU 34 is constituted by a processor and the like, and controls operation of each unit and the entire operation of the electric power supply target 3g.

The wireless communication device 35 is connected to another device or device and functions as an interface for transmitting and receiving information. The wireless communication device 35 may include a USB connector or the like.

The normally-off circuit 36 is an electric circuit that shuts off the power supply from the power storage apparatus 1g and the load driving power storage apparatus 10 to the electric power supply target 3g in normal circumstances, and causes the power storage apparatus 1g and the load driving power storage apparatus 10 to supply electric power to the electric power supply target 3g at any given timing when the electric power supply target 3g requires power. The normally-off circuit 36 is configured to include a MOSFET and the like.

With the configuration of the power storage system 200g, the supply of the electric power is shut off in normal circumstances, and the electric power is supplied at any given timing when the electric power supply target 3g requires power, so that the electric power consumption can be reduced. The power storage system 200g according to a third modified embodiment is particularly suitable for IoT devices and the like that often shut off the power supply in normal circumstances and perform data acquisition and data transmission only with a predetermined or given cycle or under a predetermined or given condition.

In the above embodiments, as an example, the first voltage value is set to 10 V, the second voltage value is set to 3.5 V, the threshold voltage value is set to 2.8 V, the fourth voltage value is set to 3.0 V, and the fifth voltage value is set to 8 V. However, the embodiments are not limited thereto, and these values can be changed as appropriate.

For example, batteries such as lithium-ion secondary batteries may protect over-charge and over-discharge by monitoring the charge voltage or may alleviate degradation by managing the state of charge (SoC) according to the charge voltage. In such case, the first to fifth voltage values may be calculated and set in advance from the amount of electric power generated by the power generation device 2 and the amount of electric power consumed by the electric power supply target 3, and the SoC may be managed by detecting the supplied voltage Vsup.

The embodiments also include a control apparatus. For example, the control apparatus is a control apparatus for controlling a power storage apparatus including a power storage unit including a plurality of power storage devices storing electric power, a series-and-parallel switching unit configured to switch connection of the plurality of power storage devices into a series connection or a parallel connection, and a series-and-parallel switching control unit configured to control the switching performed by the series-and-parallel switching unit, the control apparatus including a series recovery control unit configured to cause the power storage apparatus to switch the connection of the multiple power storage devices from the parallel connection to the series connection, on the basis of a supplied voltage supplied from the power storage unit to an electric power supply target when the plurality of the power storage devices are connected in parallel. According to such a control apparatus, effects similar to the effects of the power storage apparatus explained above can be obtained.

### Fourth Embodiment

A power storage apparatus according to the fourth embodiment is a power storage apparatus that is connected to a load circuit, and includes a power storage unit including a plurality of power storage devices storing charge, a series-and-parallel switching unit configured to switch connection of the plurality of power storage devices into a series connection or a parallel connection, and a series-and-parallel switching control unit configured to control the switching performed by the series-and-parallel switching unit.

In the fourth embodiment, a secondary battery for storing charge that is output from the power storage unit, and the secondary battery outputs a voltage to a load circuit to provide electric power to the load circuit. The secondary battery has a characteristic having an output voltage that does not change greatly according to an SoC (State Of Charge) and the like indicating the remaining battery level. Therefore, by supplying the electric power of the power storage unit by way of the secondary battery to the load circuit, the change in the output voltage from the power storage apparatus to the load circuit is alleviated.

First, a power storage system 100 including a power storage apparatus 1 according to the fourth embodiment is explained. In the explanation about the power storage system 100 including the power storage apparatus 1 according to the fourth embodiment, the constituent elements having configurations similar to the power storage system 100 including the power storage apparatus 1 according to the first embodiment are explained with similar reference numerals by referring to the drawings of the first embodiment.

<Configuration Example Oo Power Storage System 100A>

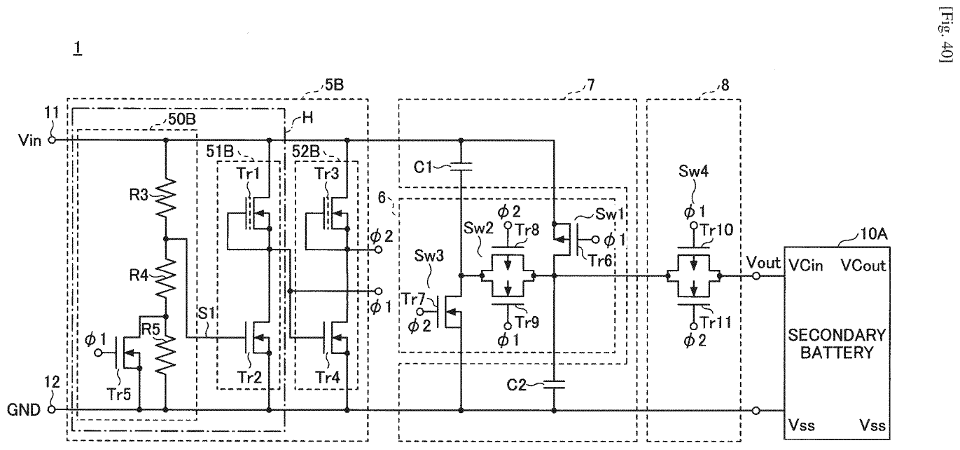

FIG. 39 is a block diagram illustrating an example of configuration of a power storage system (i.e., an energy storage system) 10 according to the fourth embodiment. As illustrated in FIG. 39, the power storage system 100A includes a power storage apparatus 1, a power generation device 2, a load circuit 3, and a rectifying circuit 4.

The power storage system 100A is a system for causing the rectifying circuit 4 (an example of a rectifying unit) to rectify the electric power generated by the power generation device 2, thereafter storing the rectified electric power in the power storage apparatus 1, and supplying the stored electric power to the load circuit 3.

The power generation device 2 is a device for generating charge with an external stimulus by using power generation rubber, a piezoelectric element, or electrostatic induction. The power generation device 2 generates high-voltage and low-current electric power. This power generation device 2 is explained later with reference to FIG. 3 in detail.

The power storage apparatus 1 includes a series-and-parallel switching control unit 5, a series-and-parallel switching unit 6, a power storage unit 7, and a secondary battery 10A. Among them, the series-and-parallel switching control unit 5 is an electric circuit for controlling the series-and-parallel switching unit 6. The series-and-parallel switching unit 6 is an electric circuit for switching the connection state of the capacitors C1, C2 included in the power storage unit 7 to either from the series connection to the parallel or from the parallel connection to the series connection. The capacitors C1, C2 are an example of a plurality of power storage devices.

The electric power received from the rectifying circuit 4 is stored to the capacitors C1, C2 connected in series in the power storage unit 7. Then, the electric power stored in the power storage unit 7 is supplied to the secondary battery 10A from the capacitors C1, C2 switched to the parallel connection by the series-and-parallel switching unit 6.

The secondary battery 10A is a device capable of storing electric power and supplying electric power, such as, for example, a lithium-ion battery, a lead-acid battery, and the like. The secondary battery 10A stores electric power supplied from the power storage unit 7 and outputs a driving voltage for driving the load circuit 3 to the load circuit 3.

The load circuit 3 is a load such as, for example, an LED (Light Emitting Diode), an IC (Integrated Circuit) having a function of a CPU (Central Processing Unit), a sensor, a wireless transmission IC, an IoT device, and the like.

The power storage system 100A stores electric power in a state in which the capacitors C1, C2 are connected in series, and when the voltage of the electric power while the electric power is being stored attains the first voltage value, the series-and-parallel switching control unit 5 controls the series-and-parallel switching unit 6 to switch the capacitors C1, C2 to the parallel connection. The capacitors C1, C2 connected in parallel supply the electric power to the secondary battery 10A.

Thereafter, when the voltage of the capacitors C1, C2 attains the second voltage value or less while the capacitors C1, C2 are supplying the electric power, the series-and-parallel switching control unit 5 controls the series-and-parallel switching unit 6 to switch the capacitors C1, C2 to the series connection. Thereafter, with the capacitors C1, C2 being connected in series, the capacitors C1, C2 store the electric power generated by the power generation device 2 again.

The power storage system 100A switches the connection state of the capacitors C1, C2 between storing of electric power and supplying of electric power in the manner as described above, the power storage efficiency can be improved.

<Example of Operation of Power Generation Device >

Subsequently, the operation of the power generation device 2 is explained. The power generation device 2 is a device constituted by power generation rubber and the like to generate power by generating charge in response to separating force, frictional force, vibration force, deformation force, pressure, or the like being applied to the power generation device 2. The amount of electric power generated by the power generation device 2 is of a voltage of 10 to 1000 V (for example, 40 V), a current of 50 nA to 100 μA (for example, 6μA), and the like.

In this case, FIG. 2 is a figure for explaining an example of the operation of the power generation device 2. The power generation device 2 outputs a current with a predetermined or given charge with a high resistance. Therefore, as illustrated in FIG. 2, the power generation device 2 may be represented by a current source 21 and an internal resistance 22. The resistance value of the internal resistance 22 is 1 to 100 MΩ (mega ohm) (for example, 10 MΩ).

Hereinafter, a capacitor and a load resistance connected to the power generation device 2 are explained with reference to FIGS. 4A, 4B, and FIG. 5.

FIG. 4A is a circuit diagram illustrating an equivalent circuit including the capacitor connected to the power generation device 2 when the capacitor stores electric power generated by the power generation device 2. FIG. 4B is a graph illustrating an example of power storage efficiency according to a condition for storing electric power to the capacitor.

In FIG. 4B, a solid line represents a change in a rate (%) of the energy, which is generated by the power generation device 2 and stored in the capacitor, according to the capacitance of the capacitor with respect to the maximum stored energy being defined as 100%.

In a case where the capacitance of the capacitor is set to a capacitance indicated by a white arrow in FIG. 4B, the impedance match is attained between the capacitor and the power generation device 2 (output side) including the constant current source and the internal resistance, and accordingly, the power can be stored with the highest efficiency.

FIG. 5A a circuit diagram illustrating an equivalent circuit of a load resistance (i.e., the load circuit 3) connected to the power generation device 2 when the power generation device 2 supplies electric power to the load resistance. FIG. 5B is a graph illustrating an example of power storage efficiency according to a condition for storing electric power to the load resistance.

In FIG. 5B, a solid line represents a change in a rate (%) of the electric power, which is generated by the power generation device 2 and stored in the capacitor, according to the resistance value of the load resistance with respect to the maximum supplied electric power being defined as 100%.

When the resistance value of the load resistance is set to a resistance value indicated by a white arrow in FIG. 5B, the load resistance and the internal resistance of the power generation device 2 are the same as each other. Specifically, when the internal resistance is equal to the resistance value of the load resistance, the impedance match with the load circuit 3 (output side) is attained, so that the power can be stored with the highest efficiency.

<Example of Connection of Capacitors>

Subsequently, an example of the connection of the capacitors C1, C2 in the power storage unit 7 is explained with reference to FIGS. 6 and 7. FIG. 6 is a circuit diagram illustrating an example of the capacitors C1, C2 connected in series. FIG. 7 is a circuit diagram illustrating an example of capacitors C1, C2 connected in parallel.

As illustrated in FIG. 6, the series-and-parallel switching unit 6 includes three switches Sw1, Sw2, Sw3. The power storage unit 7 includes two capacitors C1, C2. As illustrated in FIG. 6, when the switch Sw2 of the series-and-parallel switching unit 6 is in the ON state (i.e., connected state), and the switches Sw1 and Sw3 are in the OFF state (i.e., disconnected state), the capacitors C1, C2 of the power storage unit 7 are connected in series.

As illustrated in FIG. 7, when the switches Swl and Sw3 of the series-and-parallel switching unit 6 are in the ON state, and the switch Sw2 is in the OFF state, the capacitors C1, C2 of the power storage unit 7 are in the parallel connection state.

<Configuration Example of Series-and-Parallel Switching Control Unit 5>

Subsequently, the configuration of the series-and-parallel switching control unit 5 is explained with reference to FIGS. 8 and 9.

FIG. 8 is a circuit diagram illustrating a first configuration example of the series-and-parallel switching control unit 5. As illustrated in FIG. 8, the series-and-parallel switching control unit 5 includes a series-and-parallel selector switch control unit 50, two resistances R1, R2, and two switches Sw4, Sw5.

The series-and-parallel selector switch control unit 50 functions as a voltage monitoring circuit (an example of a voltage monitoring unit) for monitoring an input voltage Vin which is a reference for switching series or parallel connection, and outputting a control signal 51. Specifically, the series-and-parallel selector switch control unit 50 generates the control signal S1 in accordance with a detection result of the input voltage Vin to the terminal 11, and controls the switch Sw4 and the switch Sw5 with the generated control signal S1.

In the series-and-parallel switching control unit 5, the resistance R1 and the switch

Sw4 constitute an inverter 51 driven with a high impedance, and the resistance R2 and the switch Sw5 constitute an inverter 52 driven with a high impedance. For example, the switches Sw4, Sw5 may be N-ch (N channel) transistors such as an FET (Field Effect Transistor).

The series-and-parallel switching control unit 5 generates the control signal φ1 for controlling the series-and-parallel switching unit 6, and outputs the control signal φ1 through a terminal 53. Also, the series-and-parallel switching control unit 5 generates the control signal γ2 for controlling the series-and-parallel switching unit 6, and outputs the control signal γ2 through a terminal 54.

In the series-and-parallel switching control unit 5, the series-and-parallel selector switch control unit 50 and the inverter 51 function as a hysteresis generation circuit H. The hysteresis generation circuit H has a hysteresis (difference) in a switching threshold value so as to quickly detect a change in the input voltage Vin and prevent a signal once switched from low level to high level (alternatively, from high level to low level) from unstably switching again.

In the fourth embodiment, when the input voltage Vin rises to a predetermined or given first voltage value, the hysteresis generation circuit H switches the control signal p1 from high level to low level. When the input voltage Vin drops from the first voltage value to a predetermined or given second voltage value, the hysteresis generation circuit H switches the control signal φ1 from low level to high level.

In the fourth embodiment, the inverter 51 has the resistance R1 of a high impedance, and the inverter 52 has the resistance R2 of a high impedance, so that even the power generation device 2 of high impedance output that generates high-voltage and low-current electric power with a piezoelectric element or electrostatic induction can drive the circuit of the power storage apparatus 1. For example, the resistance value of each of the resistances R1, R2 is 1 MΩ to 500 MΩ.

<Example of Circuit Configuration of Power Storage Apparatus 1>

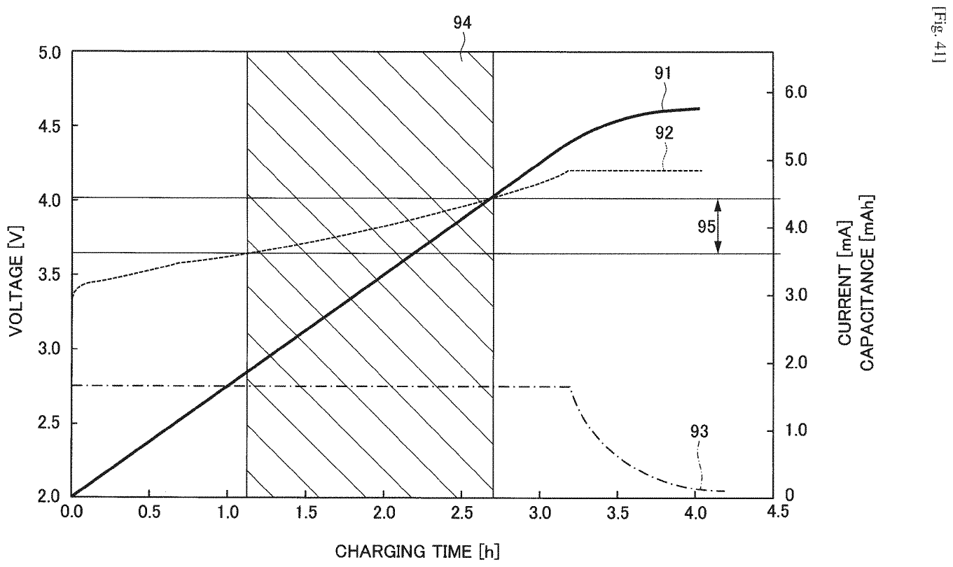

Subsequently, a circuit configuration of the power storage apparatus 1 is hereinafter explained. FIG. 40 is a circuit diagram illustrating an example of circuit configuration of a power storage apparatus according to the fourth embodiment.

As illustrated in FIG. 40, the power storage apparatus 1 includes a series-and-parallel switching control unit 5B, a series-and-parallel switching unit 6, a power storage unit 7, and an output switching unit 8. It should be noted that the power storage apparatus 1 may be configured as a single power storage IC in which the functions of multiple ICs are integrated.

The series-and-parallel switching control unit 5B includes a series-and-parallel selector switch control unit 50B, two depletion transistors Tr1, Tr3, and two N-ch transistor Tr2, Tr4.

In the fourth embodiment, the series-and-parallel selector switch control unit 50B includes an N-ch transistor Tr5 and three resistances R3, R4, R5. The three resistances R3, R4, R5 are resistors of high impedance having high resistance values (high impedances). The N-ch transistor Tr5 is a hysteresis generation switch, which may receive a signal representing the state of the load circuit 3.

The series-and-parallel selector switch control unit 50B monitors the input voltage Vin for switching the series connection to the parallel connection, and outputs the control signal S1.

The series-and-parallel switching control unit 5B have two inverters 51B, 52B, which are controlled by a control signal (S1) generated by the series-and-parallel selector switch control unit 50B.

The inverter 51B includes the depletion transistor Tr1 and the N-ch transistor Tr2. The control signal φ1 from the inverter 51B is retrieved through the terminal 53.

The series-and-parallel selector switch control unit 50B and the inverter 51B constitute the hysteresis generation circuit H. The inverter 52B includes the depletion transistor Tr3 and the N-ch transistor Tr4. The control signal γ2 from the inverter 52B is retrieved through the output terminal. Alternatively, each of the inverters 51B, 52B may be configured to include an N-ch transistor and a resistor.

While the electric power is stored to the capacitors C1, C2, the series-and-parallel switching control unit 5B outputs the control signal φ1 of the high level and the control signal γ2 of the low level to connect the multiple capacitors C1, C2 in series. Then, when the input voltage Vin attains a predetermined or given first voltage value, the series-and-parallel switching control unit 5B outputs the control signal φ1 of the low level and the control signal γ2 of the high level so as to connect the capacitors C1, C2 in parallel.

Thereafter, when the load circuit 3 consumes electric power, and accordingly, the voltage Vin drops to less than a predetermined or given second voltage value, the series-and-parallel switching control unit 5B outputs the control signal φ1 of the high level and the control signal γ2 of the low level to connect the capacitors C1, C2 in series.

The series-and-parallel switching unit 6 includes a P-ch (P channel) transistor Tr6, an N-ch transistor Tr7, and analog switches Tr8, Tr9.

In the series-and-parallel switching unit 6, the P-ch transistor Tr6 corresponds to the switch Swl of FIG. 6, FIG. 7, and the N-ch transistor Tr7 corresponds to the switch Sw3 of FIG. 6, FIG. 7. The switch Sw2 is constituted by an analog switch including two transistors Tr8, Tr9.

When the series-and-parallel switching unit 6 and the output switching unit 8 are constituted by transistors which are analog switches, voltage loss (potential difference) does not occur. In contrast, if the switch is constituted by a diode, voltage loss occurs. Because the series-and-parallel switching unit 6 and the output switching unit 8 are constituted by transistors which are analog switches, the switches can be operated without any potential difference.

In the series-and-parallel switching unit 6, the P-ch transistor Tr6 and the N-ch transistor Tr7 may be replaced with diodes. Specifically, to replace the P-ch transistor Tr6 with a diode, the cathode of the diode is connected to Vin line, and the anode of the diode is connected is to a terminal of the analog switch. To replace the N-ch transistor Tr7 with a diode, the cathode of the diode is connected to a terminal of the analog switch, and the anode of the diode is connected to the GND line.

Also, in the series-and-parallel switching unit 6, diodes may be connected in parallel with the P-ch transistor Tr6 and the N-ch transistor Tr7. Specifically, in parallel with the P-ch transistor Tr6, the cathode of the diode is connected to Vin line, and the anode of the diode is connected to a terminal of the analog switch. In parallel with the N-ch transistor Tr7, the cathode of the diode is connected to a terminal of the analog switch, and the anode of the diode is connected to the GND line.

Although not illustrated in FIG. 39 explained above, the power storage apparatus 1 may have, as illustrated in FIG. 40, the output switching unit 8 for supplying electric power to the secondary battery 10A only when the capacitors C1, C2 are connected in parallel. The output switching unit 8 is constituted by an analog switch including a P-ch transistor Tr10 and an N-ch transistor Tr11.

In the power storage apparatus 1, the output switching unit 8 for supplying electric power to the secondary battery 10A only when the capacitors C1, C2 are connected in parallel may be constituted by only the P-ch transistor Tr10.

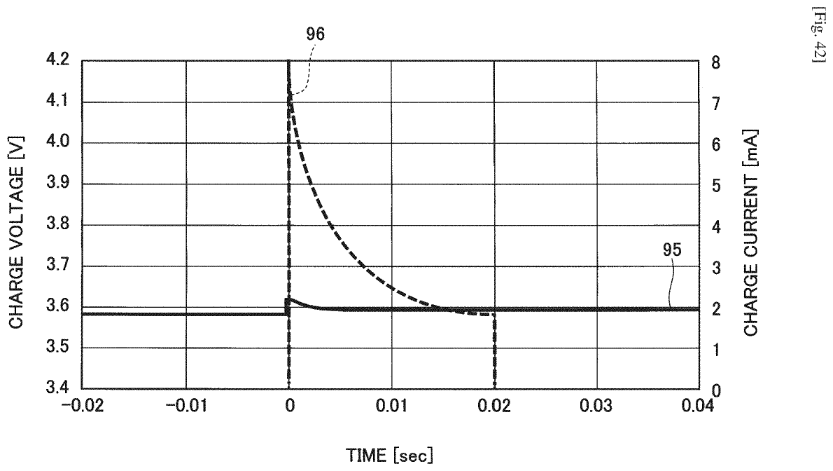

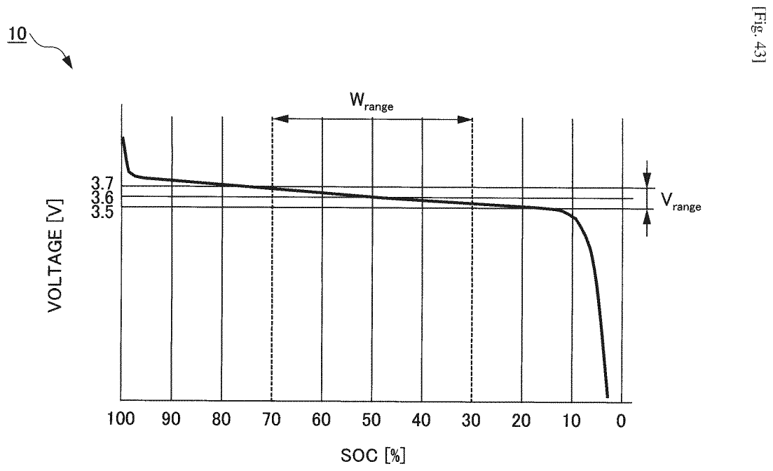

The secondary battery 10A stores the electric power supplied from the power storage unit 7 via the output switching unit 8, and supplies the stored electric power to the load circuit 3. The operation of the secondary battery 10A is explained later with reference to FIG. 41 and subsequent drawings.

In the power storage apparatus 1, the resistors having high resistances and the constant current transistors have high resistances, and therefore, the series-and-parallel switching control unit 5B has a high resistance value (high impedance). Therefore, the power storage apparatus 1 can be driven by a current (for example, 60 nA) that is lower than the high-voltage and low-current electric power (for example, 400 V, 6μA) generated by the power generation device 2.

In the configuration of FIG. 40, the summation of the impedances of the devices constituting the series-and-parallel switching control unit 5B, the series-and-parallel switching unit 6, and the output switching unit 8 can be set to an impedance equal to or more than the internal impedance of the power generation device 2. Therefore, the electric power consumed to drive series-and-parallel switching operation of the power storage apparatus 1 can be reduced, and the power storage efficiency can be increased.

The series-and-parallel switching unit 6 and the output switching unit 8 are MOS (Metal Oxide semiconductor) transistors. Therefore, the series-and-parallel switching unit 6 and the output switching unit 8 controlled by the series-and-parallel switching control unit 5B consume only the electric power for driving the gates of the MOS transistors when turning on or off the switching units. Therefore, the power storage efficiency can be increased.

Furthermore, the impedance of the power storage apparatus 1 for storing electric power is higher than the impedance of the power storage apparatus 1 for supplying electric power. Therefore, the power storage apparatus 1 can store high-voltage and low-current electric power, so that the power storage efficiency can be increased. For example, the voltage of the electric power supplied by the power storage apparatus 1 is 3 V, and therefore, the power storage apparatus 1 can drive an electric device such as a CPU that consumes a current of several milliamperes.

In FIG. 40, the inverters 51B, 52B constituted by the depletion transistors and the N-ch transistors have two-stage configuration, but the number of stages of inverters may be increased in a similar manner when a higher gain is desired. In that case, it is preferable that the timing of change of the control signal φ1 output from the inverter 51B and the timing of change of the control signal γ2 output from the inverter 52B are adjusted in line with the switching timing of the series-and-parallel switching unit 6.

<Actions of Secondary Battery 10A>

Subsequently, the actions of the secondary battery 10A is explained.

The secondary battery has a characteristic having an output voltage that does not change greatly according to the SoC and the like. In the fourth embodiment, by making use of this characteristic, the secondary battery 10A outputs a voltage to the load circuit 3, so that the change in the output voltage from the power storage apparatus 1 supplied to the load circuit 3 is alleviated.

FIG. 41 is a graph illustrating an example of change of a capacitance, a voltage, and a current according to the charge time of the secondary battery 10A (i.e., a time it takes to store electric power). In the graph of FIG. 41, a solid line 91 indicates the capacitance of the secondary battery 10A, a broken line 92 indicates the output voltage, and a long dashed short dashed line 93 indicates the charge current. In the axes of FIG. 41, a left-hand side axis denotes a voltage (V), and a right-hand side axis denotes a current (mA) and a capacitance (mAh). It should be noted that the capacitance is equivalent to the energy stored in the secondary battery 10A.

As indicated by the solid line 91, the capacitance of the secondary battery 10A increases ac the charge time increases. However, as indicated by the broken line 92, the voltage of the secondary battery 10A does not change greatly even when the charge time increases and the capacitance increases.

By making use of the characteristic that the output voltage of the secondary battery 10A does not change greatly, an electric power usage range in which the load circuit 3 uses the electric power stored in the power storage apparatus 1 is defined in advance. Therefore, the change in the output voltage of the secondary battery 10A supplied to the load circuit 3 can be reduced to within a desired range.

For example, when a range of capacitance in an area 94 indicated by hatching in FIG. 41 is defined as the electric power usage range, the change in the output voltage of the secondary battery 10A supplied to the load circuit 3 can be reduced to 0.5 V or less (see a voltage change range 95 in FIG. 41).

Subsequently, FIG. 41 is a graph illustrating an example of chronological change in the voltage and the current that occur in response to a single external stimulus applied to the power generation device 2.

With respect to the charge voltage and the charge current for charging the power storage apparatus 1 in response to a single external stimulus to the power generation device 2, a voltage change range 95 represents the charge voltage, and a broken line 96 represents the charge current as illustrated in FIG. 41.

As illustrated in FIG. 41, the charge current may increase sharply at the moment when an external stimulus is given to the power generation device 2, but the charge current does not increase sharply in such a manner. Therefore, a sharp change in the output voltage can be alleviated by outputting a voltage to the load circuit 3 with the power storage apparatus 1.

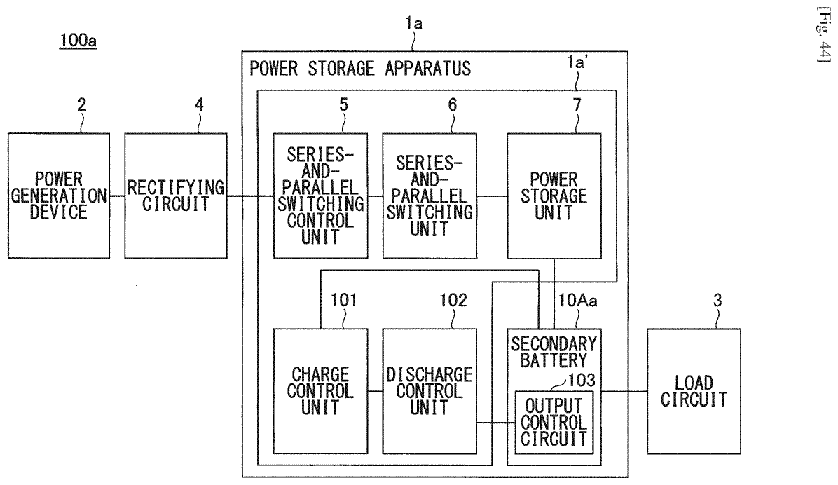

Subsequently, FIG. 43 is a graph illustrating an example of a voltage output characteristic of the secondary battery 10A. In FIG. 43, a horizontal axis indicates the SoC of the secondary battery 10A, and the vertical axis indicates the output voltage of the secondary battery 10A.

In FIG. 43, an electric power usage range W_{range} is a range in which the load circuit 3 uses the electric power supplied by the secondary battery 10A to the load circuit 3. An voltage usage range V_{range} is a range of the output voltage corresponding to the electric power usage range W_{range}.

As illustrated in FIG. 43, in the voltage output characteristic of the secondary battery 10A, there is a flat range in which the inclination of the voltage change according to the SoC is small. For example, in the example of FIG. 43, this flat range is a range where the SoC is 10% or more and 90% or less, i.e., a range in which the inclination of the voltage change according to the SoC is small.

This flat range, i.e., the range where the SoC is 10% or more and 90% or less, is defined in advance as the electric power usage range W_{range} in which the load circuit 3 uses the electric power. Accordingly, the voltage change range V_{range} can be reduced to a narrow range, i.e., 3.5 V or more and 3.7 V or less. Therefore, the change in the output voltage according to the SoC can be alleviated. In this case, the “range where the SoC is 10% or more and 90% or less” is an example of a “predetermined or given range”.

<Effects of Power Storage Apparatus 1>

In general, in a case where a power storage apparatus using capacitors and the like provides electric power, the output voltage of the power storage apparatus may change according to the SoC and the like of the power storage apparatus. For example, when the power storage apparatus 1 is configured to directly output a voltage from the output switching unit 8 to the load circuit 3, the output voltage of the power storage apparatus 1 may change according to the SoC. When the drive voltage for driving the load circuit 3 change according to such a change in the output voltage, the operation of the load circuit 3 may become unstable.

When a DC-to-DC (Direct Current to Direct Current) conversion circuit is provided to apply the voltage converted by the DC-to-DC conversion circuit to the load circuit 3 in order to alleviate the change in the drive voltage, the power consumption increases due to the DC-to-DC conversion circuit, and furthermore, the complexity, the size, and the cost of the power storage apparatus increase.

In contrast, in the fourth embodiment, the voltage is output via the secondary battery 10A to the load circuit 3. The secondary battery 10A has the characteristic having an output voltage that does not change greatly according to the SoC, and therefore, the change in the output voltage from the power storage apparatus 1 supplied to the load circuit 3 can be alleviated by making use of this characteristic. In the four the embodiment, the voltage can be applied to the load circuit 3 without using the DC-to-DC conversion circuit and the like, the increase in the power consumption due to the DC-to-DC conversion circuit can be alleviated, and furthermore, the increase in the complexity, the size, and the cost of the power storage apparatus can be alleviated.

In the fourth embodiment, the electric power usage range W_{range} in which the inclination of the voltage change according to the SoC is small is defined in advance as the electric power usage range in which the load circuit 3 uses the electric power from the secondary battery 10A. When the electric power is used in the electric power usage range W_{range}, the change in the output voltage according to the SoC and the like is reduced, and the load circuit 3 can operate stably.

For example, the electric power usage range W_{range} in which the load circuit 3 uses the electric power is defined in a range where the SoC is 10% or more and 90% or less, so that the voltage change range V_{range} is reduced to a narrow range, i.e., 3.5 V or more and 3.7 V or less, and the change in the output voltage according to the SoC can be alleviated.

In addition, the secondary battery 10A according to the fourth embodiment can stably supply electric power at an output voltage to the load circuit 3 and can store electric power by accumulating charge. Therefore, the secondary battery 10A can also be used as a power source. With the use of the electric power stored in the secondary battery 10A, the electric power can be supplied to the load circuit 3 immediately after the power storage system 100A is activated.

In addition, the secondary battery 10A has a small output impedance, and therefore, the secondary battery 10A can handle a case where the load current of the load circuit 3 sharply changes. Still more, he secondary battery 10A can support wireless communication based on BLE (Bluetooth Low Energy), i.e., a low power consumption specification of Bluetooth (registered trademark).

### First Modified Embodiment

Subsequently, a power storage system 100a according to the first modified embodiment is explained.

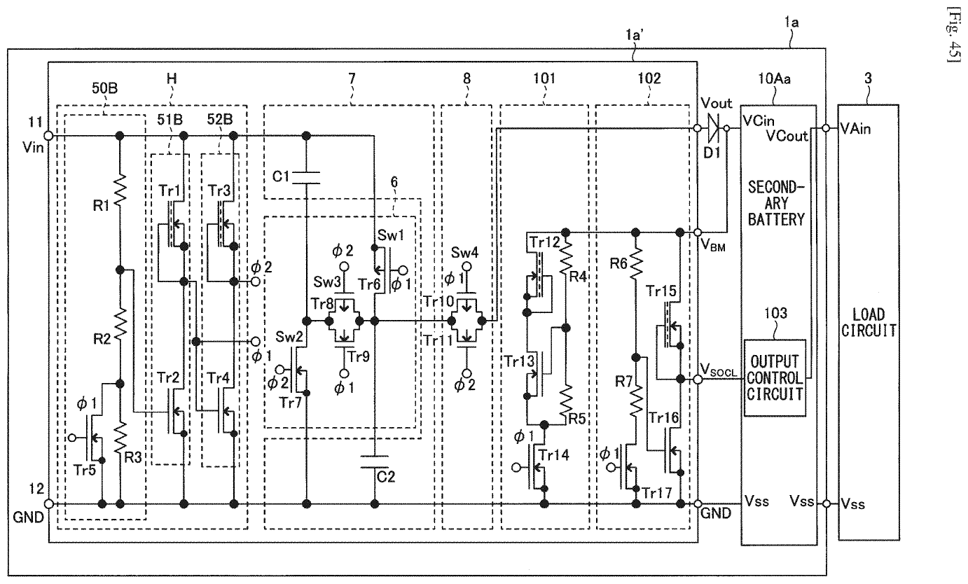

FIG. 44 is a block diagram illustrating an example of configuration of the power storage system 100a according to a first modified embodiment of the fourth embodiment. As illustrated in FIG. 44, the power storage system 100a includes a power storage apparatus 1a. The power storage apparatus 1a includes a power storage apparatus 1a′ and a secondary battery 10Aa. Further, the power storage apparatus 1a′ includes a charge control unit 101 for controlling the amount of charge in the secondary battery 10Aa and a discharge control unit 102 for controlling the amount of discharge from the secondary battery 10Aa.

The secondary battery 10Aa includes an output control circuit 103. The discharge control unit 102 and the output control circuit 103 are electrically connected, and the discharge control unit 102 can control the amount of discharge from the secondary battery 10Aa by controlling the output control circuit 103. This output control circuit 103 is an example of “output control unit”.

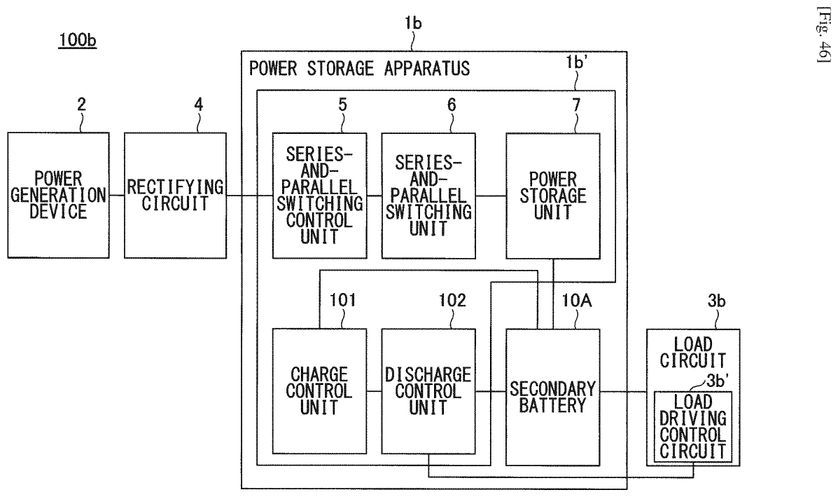

Subsequently, FIG. 45 is a circuit diagram illustrating an example of circuit configuration of a power storage apparatus according to the first modified embodiment.

As illustrated in FIG. 45, the charge control unit 101 includes an N-ch depletion transistor Tr12, an N-ch enhancement transistor Tr13, an N-ch transistor Tr14, a resistance R4, and a resistance R5, and controls the charge of the secondary battery 10Aa on the basis of a voltage VCin of the secondary battery 10Aa.

Specifically, the charge control unit 101 controls the amount of charge stored in the secondary battery 10Aa so that the amount of charge stored in the secondary battery 10Aa does not exceed a charge upper limit value defined in advance on the basis of the voltage VCin of the secondary battery 10Aa. The voltage VCin is an example of “battery input voltage”.

When the connection state of the capacitors C1, C2 is switched from the parallel connection to the serial connection by the series-and-parallel switching unit 6, the input signal φ1 of the N-ch transistor Tr14 changes from the low level to the high level, and the N-ch transistor Tr14 is turned on. When the N-ch transistor Tr14 is turned on, currents flow through the resistances R4, R5. When the voltage VCin attains the predetermined or given upper limit voltage value or more, the N-ch enhancement transistor Tr13 is turned on, and currents flow through the N-ch depletion transistor Tr12 and the N-ch enhancement transistor Tr13.

In this case, the upper limit voltage value is a voltage value when the SoC attains the charge upper limit value. For example, when the charge upper limit value is 90%, the upper limit voltage value becomes 3.7 V (see FIG. 43).

The sizes of the N-ch depletion transistor Tr12 and the N-ch enhancement transistor Tr13 are adjusted in advance, so that current values of currents flowing through the N-ch depletion transistor Tr12 and the N-ch enhancement transistor Tr13 become a discharge current of the secondary battery 10Aa. Accordingly, the increase in the voltage of the secondary battery 10Aa can be limited. Specifically, the voltage of the secondary battery 10Aa can be limited to, for example, the charge upper limit value or less.

The power storage apparatus 1a′ may be configured such that the connection terminal of the N-ch depletion transistor Tr12 and the N-ch enhancement transistor Tr13 is adopted as a signal output terminal, so that currents passed to the discharge resistance and the constant current transistor are controlled, and the voltage of the secondary battery 10Aa can be limited to, for example, the charge upper limit value or less.

Also, the discharge control unit 102 includes an N-ch depletion transistor Tr15, an N-ch enhancement transistor Tr16, a resistance R6, and a resistance R7, and controls the discharge of the secondary battery 10Aa on the basis of the voltage VCin of the secondary battery 10Aa.

Specifically, the discharge control unit 102 controls the amount of charge stored in the secondary battery 10Aa so that the amount of charge stored in the secondary battery 10Aa does not fall below a charge lower limit value defined in advance on the basis of the voltage VCin of the secondary battery 10Aa.

When the connection state of the capacitors C1, C2 is switched from the parallel connection to the series connection by the series-and-parallel switching unit 6, the input signal φ1 of the N-ch transistor Tr17 changes from the low level to the high level, and the N-ch transistor Tr17 is turned on. When the voltage VCin of the secondary battery 10Aa becomes the predetermined or given lower limit voltage value or less, the N-ch enhancement transistor Tr16 is turned off, and the voltage VSOCL changes from the low level to the high level. When the connection state of the capacitors C1, C2 is changed to the parallel connection by the series-and-parallel switching unit 6, the N-ch transistor Tr17 is turned off. Accordingly, the terminal voltage across the connection points of the resistances R6, R7 becomes a voltage VBM. Then, the N-ch enhancement transistor Tr16 is turned on, and the voltage VSOCL is at the low level.

Therefore, the connection state of the capacitors C1, C2 is changed to the series connection by the series-and-parallel switching unit 6, and only when the voltage VCin of the secondary battery 10Aa is at a predetermined or given second voltage or less, the voltage VSOCL attains the high level.

In the manner as described above, with the use of the voltage VSOCL of the power storage apparatus 1a′, the supply of the electric power to the load circuit 3 can be stopped by driving the output control circuit 103 of the secondary battery 10Aa, and the decrease in the voltage of the secondary battery 10Aa can be controlled.

In this case, the lower limit voltage value is a voltage value when the SoC attains the charge lower limit value. For example, when the charge lower limit value is 10%, the lower limit voltage value becomes 3.5 V (see FIG. 43).

<Actions and Effects of Power Storage Apparatus 1a>

In the manner as described above, the power storage apparatus 1 according to the first embodiment can alleviate the change in the output voltage of the power storage apparatus 1 according to the SoC of the secondary battery 10. However, the change in the output voltage cannot be completely eliminated, and as illustrated in FIG. 43, as the SoC approaches 100%, the output voltage gradually increases, and in the over-charge state where the SoC is almost 100%, the output voltage greatly increases. Also, as the SoC approaches 0%, the output voltage gradually decreases, and in the over-discharge state where the SoC is close to 0%, the output voltage greatly decreases. When the SoC exceeds the upper limit value and falls below the lower limit value, the operation of the load circuit 3 receiving the drive voltage from the power storage apparatus 1 may become unstable. In the over-charge state or the over-discharge state, the secondary battery 10 may degrade.

In contrast, the power storage apparatus 1a′ according to the first modified embodiment includes the charge control unit 101 and the discharge control unit 102, and the amount of charge stored in the secondary battery 10Aa is controlled to become equal to or more than the charge lower limit value and equal to or less than the charge upper limit value, on the basis of the voltage VCin. Accordingly, the output voltage of the secondary battery 10Aa can be kept in a range equal to or more than the charge lower limit value and equal to or less than the charge upper limit value. The operation of the load circuit 3 can be stabilized by reducing the change in the output voltage from the power storage apparatus 1a supplied to the load circuit 3. In addition, the secondary battery 10Aa is controlled against the over-charge or over-discharge, and the degradation of the secondary battery 10Aa can be alleviated.

The effects similar to the effects explained in the fourth embodiment can also be obtained in this first modified embodiment.

### Second Modified Embodiment

Subsequently, a power storage system 100b according to the second modified embodiment is explained.

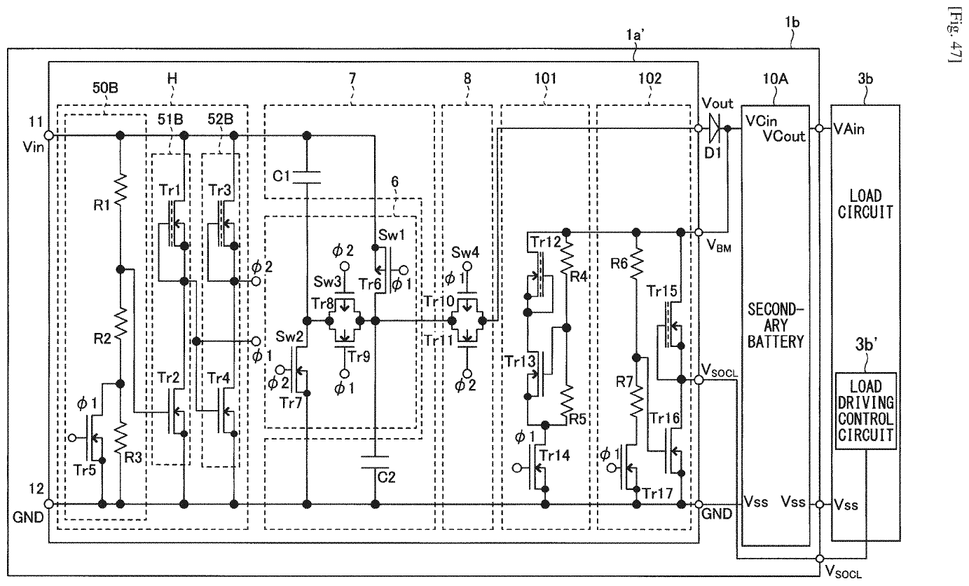

FIG. 46 is a block diagram illustrating an example of configuration of the power storage system 100b according to a second modified embodiment of the fourth embodiment. As illustrated in FIG. 14, the power storage system 100b includes a power storage apparatus 1b and a load circuit 3b.

The power storage apparatus 1b includes a power storage apparatus 1b′. The power storage apparatus 1b′ includes a charge control unit 101 for controlling the amount of charge in the secondary battery 10 and a discharge control unit 102 for controlling the amount of discharge in the secondary battery 10.

The load circuit 3b includes a load driving control circuit 3b′ for controlling operation of the load circuit 3b. The discharge control unit 102 and the load driving control circuit 3b′ are electrically connected, and the discharge control unit 102 controls the load driving control circuit 3b′ to control the amount of discharge from the secondary battery 10. The load driving control circuit 3b′ is an example of “load driving control unit”.

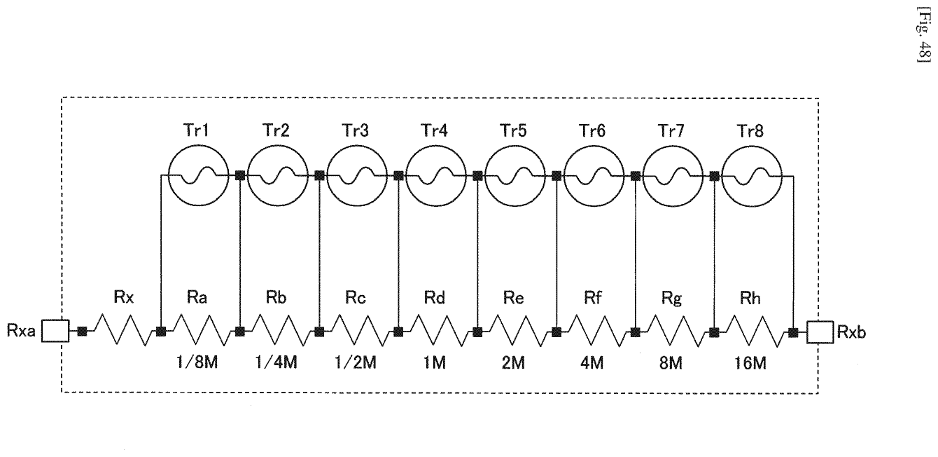

Subsequently, FIG. 47 is a circuit diagram illustrating an example of circuit configuration of the power storage apparatus 1b and the load circuit 3b according to the second modified embodiment. As illustrated in FIG. 47, the power storage apparatus lb is configured so that the voltage VSOCL output from the discharge control unit 102 is input to the load driving control circuit 3b′.

The load driving control circuit 3b′ stops the load circuit 3b on the basis of the voltage VCin of the secondary battery 10. Specifically, the load driving control circuit 3b′ can stop the load circuit 3b until the voltage VCin fails within a range equal to or more than the lower limit voltage value. Accordingly, the discharge of the secondary battery 10 can be stopped, and the SoC can be maintained at, for example, 10% or more, so that the output voltage of the secondary battery 10 can be maintained in a voltage range in which the load circuit 3b can operate stably.

The circuit of the power storage apparatus 1b may be configured so that the resistances R1 to R7 according to the first and second modified embodiments can be adjusted through trimming and the like in advance. In this case, FIG. 48 is a circuit diagram illustrating an example of circuit configuration capable of adjusting the resistance values of the resistances R1 to R7 by trimming. The circuit as illustrated in FIG. 48 is configured so that the resistance values between a terminal Rxa and a terminal Rxb can be adjusted by a combination of Rx+Ra to Rh. For example, the transistors Trl to Tr8 of FIG. 48 are devices that can be trimmed by laser.

The effects similar to the effects explained in the fourth embodiment and the first modified embodiment of the fourth embodiment can also be obtained in this second modified embodiment.

### Fifth Embodiment

Subsequently, a power storage system 100a according to the fifth embodiment is explained. The power storage system 100a according to the fifth embodiment is configured in a manner similar to the power storage system 100a according to the second embodiment as illustrated in FIGS. 19 to 23 and the like. Accordingly, corresponding constituent elements are denoted with the same reference numerals as the reference numerals of the power storage system 100a according to the second embodiment, and detailed explanation about the power storage system 100a according to the fifth embodiment is omitted here. The power storage system 100a according to the fifth embodiment is different from the power storage system 100a according to the second embodiment in that the power storage system 100a according to the fifth embodiment additionally includes an electric power supply target voltage detection unit 13A as illustrated in FIG. 28 and the like of the third embodiment. Accordingly, the series recovery control unit 14 performs control based on not only the detection result from the output current detection unit 13 but also the detection result from the electric power supply target voltage detection unit 13A. The series recovery control unit 14 operates in a manner similar to the series recovery control unit 14 of the second embodiment and the third embodiment as described above. With the combination of the output current detection unit 13 and the electric power supply target voltage detection unit 13A, the power storage efficiency and the power supply efficiency of the electric power can be improved more greatly with the improvement in the safety. In addition, the effects similar to the effects explained in the second and third embodiments can also be obtained in this fifth embodiment.

### Sixth Embodiment

Subsequently, a power storage system 100a according to the sixth embodiment is explained. The power storage system 100a according to the fifth embodiment is configured in a manner similar to the power storage system 100a according to the second embodiment as illustrated in FIGS. 19 to 23 and the like. Accordingly, corresponding constituent elements are denoted with the same reference numerals as the reference numerals of the power storage system 100a according to the second embodiment, and detailed explanation about the power storage system 100a according to the sixth embodiment is omitted here. The power storage system 100a according to the sixth embodiment is different from the power storage system 100a according to the second embodiment in that the power storage system 100a according to the sixth embodiment additionally includes a secondary battery 10A as illustrated in FIG. 39 of the fourth embodiment. With the output current detection unit 13, the power storage efficiency and the power supply efficiency of the electric power can be improved, and in addition, with the secondary battery 10A, the change in the output voltage from the power storage apparatus 1 to the load circuit 3 is alleviated. The effects similar to the effects explained in the second and fourth embodiments can also be obtained in this sixth embodiment.

### Seventh Embodiment

Subsequently, a power storage system 100a according to the seventh embodiment is explained. The power storage system 100a according to the seventh embodiment is configured in a manner similar to the power storage system 100a according to the third embodiment as illustrated in FIG. 28 and the like. Accordingly, corresponding constituent elements are denoted with the same reference numerals as the reference numerals of the power storage system 100a according to the third embodiment, and detailed explanation about the power storage system 100a according to the seventh embodiment is omitted here. The power storage system 100a according to the seventh embodiment is different from the power storage system 100a according to the third embodiment in that the power storage system 100a according to the seventh embodiment additionally includes a secondary battery 10A as illustrated in FIG. 39 in the fourth embodiment. With the electric power supply target voltage detection unit 13A of the third embodiment, the power storage efficiency and the power supply efficiency of the electric power can be improved with the improvement in the safety, and in addition, with the secondary battery 10A, the change in the output voltage from the power storage apparatus 1 to the load circuit 3 is alleviated. The effects similar to the effects explained in the third and fourth embodiments can also be obtained in this seventh embodiment.

Hereinabove, although preferred embodiments of the present invention have been described in detail, the present invention is not limited to particular embodiments, and various modifications and changes can be made within the gist of the embodiments of the present invention described in the claims. Further, it is to be understood that a person skilled in the art would understand that, within the gist of the present invention, all or some of the embodiments and the modified embodiments described above can be combined with each other.

In the above embodiments, all the constituent elements are implemented by hardware such as an electric circuit, but some or all of the functions described in the above embodiments may be implemented by software.

### REFERENCE SIGNS LIST

1, 1a power storage apparatus

2 power generation device

3 load circuit

31 load driving control circuit (an example of a load driving control unit)

33 memory

34 MPU

35 wireless communication device

4 rectifying circuit (an example of a rectifying unit)

5, 5B series-and-parallel switching control unit

50, 50B series-and-parallel selector switch control unit (an example of a voltage monitoring unit)

51, 52 inverter

55 master-and-slave switching circuit

6 series-and-parallel switching unit

60 series-and-parallel selector switching unit

61, 62, 63 switch group

7 power storage unit

8 output switching unit (an example of an output unit)

9 series-and-parallel switching IC

91 master IC

92, 93, 94, 95 slave IC

10 load driving power storage apparatus

10A secondary battery

13 output current detection unit

13A electric power supply target voltage detection unit

14 series recovery control unit

15 output current series recovery control apparatus

15A load voltage series recovery control apparatus

31 communication module

32 sensor

100, 100C, 100a, 100e, 100f power storage system

101 charge control unit

102 discharge control unit

103 output control circuit (an example of output control unit)

C1, C2, C3, C4 capacitor (power storage device)

H hysteresis generation circuit

Tr1, Tr3 depletion transistor

Tr2, Tr4 N-ch transistor

Vin input voltage

VCin voltage (an example of battery input voltage)

Vsup supplied voltage

V_{acc} voltage of the stored electric power

φ1, φ2 control signal

φ3 output signal

φ4 series recovery signal

W_{range} electric power usage range

V_{range} voltage change range

### CITATION LIST

### Patent Literature

[PTL 1] Japanese Patent Application Laid-Open No. 2013-236506

[PTL 2] Japanese Patent Application Laid-Open No. 2019-161975

The present application is based on and claims the benefit of priorities of Japanese Priority Application No. 2019-148392 filed on Aug. 13, 2019, Japanese Priority Application No. 2020-011864 filed on Jan. 28, 2020, and Japanese Priority Application No. 2019-164759 filed on Sep. 10, 2019, the contents of which are incorporated herein by reference.

1. A power storage apparatus comprising:
a power storage unit including a plurality of power storage devices storing electric power;
a series-and-parallel switching unit configured to switch connection of the plurality of power storage devices into a series connection or a parallel connection; and
a series-and-parallel switching control unit configured to control the switching performed by the series-and-parallel switching unit,
wherein the series-and-parallel switching control unit controls timing of the switching with hysteresis.

2. The power storage apparatus according to claim 1, wherein the series-and-parallel switching control unit includes a hysteresis generation circuit to achieve the hysteresis.

3. The power storage apparatus according to claim 2, wherein the hysteresis generation circuit includes a resistance, an inverter, and a transistor.

4. The power storage apparatus according to claim 3, wherein the inverter is constituted by a series circuit including a resistance and an N channel transistor.

5. The power storage apparatus according to claim 3, wherein the inverter is constituted by a series circuit including a depletion transistor and an N channel transistor.

6. The power storage apparatus according to claim 1, wherein the series-and-parallel switching unit includes an analog switch.

7. The power storage apparatus according claim 1, further comprising an output unit configured output an output voltage to a load circuit,
wherein a summation of impedances of the series-and-parallel switching unit, the series-and-parallel switching control unit, and the output unit is equal to or more than an internal impedance of a power generation device.

8. The power storage apparatus according to claim 1, further comprising a series recovery control unit configured to control the series-and-parallel switching control unit to switch connection of the plurality of power storage devices from the parallel connection to the series connection, on the basis of an output current from the power storage unit.

9. The power storage apparatus according to claim 8, wherein in a case where the output current becomes equal to or less than a first current value with the plurality of power storage devices being connected in parallel, the series recovery control unit causes the series-and-parallel switching control unit to switch the connection of the plurality of power storage devices from the parallel connection to the series connection.

10. The power storage apparatus according to claim 1, further comprising a series recovery control unit configured to control the series-and-parallel switching control unit to switch the connection of the plurality of power storage devices from the parallel connection to the series connection, on the basis of a supplied voltage supplied from the power storage unit to an electric power supply target when the plurality of power storage devices are connected in parallel.

11. The power storage apparatus according to claim 10, wherein in a case where an input voltage to the plurality of power storage devices becomes equal to or less than a second voltage value lower than a first voltage value when the plurality of power storage devices are connected in parallel, the series-and-parallel switching unit switches the connection of the plurality of power storage devices from the parallel connection to the series connection,
wherein in a case where the supplied voltage becomes equal to or more than a threshold voltage value when the plurality of power storage devices are connected in parallel, the series recovery control unit changes the second voltage value to a given voltage value.

12. The power storage apparatus according to claim 1, further comprising a secondary battery configured to be charged with the electric power from the power storage unit, and output a voltage to a load circuit connected to the power storage apparatus.

13. The power storage apparatus according to claim 12, wherein a range in which the load circuit uses the electric power charged in the secondary battery is set to a given range on the basis of a voltage value that the secondary battery outputs to the load circuit.

14. The power storage apparatus according to claim 13, further comprising a charge control unit configured to control charging of the secondary battery.

15. A power storage system comprising:
a power generation device generating electric power;
a rectifying unit connected to the power generation device;
the power storage apparatus according to claim 1 connected downstream of the rectifying unit; and
a load circuit.
